(19) United States
(12) Patent Application Publication
(10) Pub. No.: US 2024/0276831 A1
(43) Pub. Date: Aug. 15, 2024

(54) DISPLAY APPARATUS AND METHOD FOR MANUFACTURING DISPLAY APPARATUS

(71) Applicant: SEMICONDUCTOR ENERGY LABORATORY CO., LTD., Atsugi-shi, Kanagawa-ken (JP)

(72) Inventors: Daisuke KUBOTA, Atsugi, Kanagawa (JP); Kenichi OKAZAKI, Atsugi, Kanagawa (JP); Koji KUSUNOKI, Isehara, Kanagawa (JP)

(21) Appl. No.: 18/562,086

(22) PCT Filed: May 17, 2022
(86) PCT No.: PCT/IB2022/054552

§ 371 Date: Nov. 17, 2023

(30) Foreign Application Priority Data
May 27, 2021 (JP) 2021-089308

(51) Int. Cl. H10K 59/65; G06V 40/13; H10K 59/38; H10K 71/60

(52) U.S. Cl. CPC H10K 59/65; G06V 40/1318; H10K 59/38; H10K 71/60

(57) ABSTRACT

A display apparatus having an image capturing function is provided. A display apparatus with a high aperture ratio is provided. The display apparatus includes a first light-emitting element, a light-receiving element, and a first coloring layer; the first light-emitting element includes a first pixel electrode, a first organic layer over the first pixel electrode, and a common electrode over the first organic layer; the light-receiving element includes a second pixel electrode, a second organic layer over the second pixel electrode, and the common electrode over the second organic layer; the first organic layer includes a first light-emitting layer; the second organic layer includes a photoelectric conversion layer; the first coloring layer is positioned to overlap with first light-emitting element; and the photoelectric conversion layer has sensitivity in a wavelength range of light passing through the first coloring layer.

### TECHNICAL FIELD

One embodiment of the present invention relates to a display apparatus. One embodiment of the present invention relates to an image capturing device. One embodiment of the present invention relates to a display apparatus having an image capturing function.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, display apparatuses have been required to have higher resolution in order to display high-definition images. In addition, display apparatuses used in information terminal devices such as smartphones, tablet terminals, or laptop PCs (personal computers) have been required to have lower power consumption as well as higher resolution. Furthermore, display apparatuses have been required to have a variety of functions such as a touch panel function and a function of capturing images of fingerprints for authentication, in addition to a function of displaying images.

Light-emitting apparatuses including light-emitting elements have been developed, for example, as display apparatuses. Light-emitting elements (also referred to as EL elements) utilizing an electroluminescence (hereinafter referred to as EL) phenomenon have features such as ease of reduction in thickness and weight, high-speed response to an input signal, and driving with a direct-constant voltage source, and have been used in display apparatuses. For example, Patent Document 1 discloses a flexible light-emitting apparatus including an organic EL element.

### [Reference]

### [Patent Document]

[Patent Document 1] Japanese Published Patent Application No. 2014-197522

### SUMMARY OF THE INVENTION

### Problems to be Solved by the Invention

An object of one embodiment of the present invention is to provide a display apparatus having an image capturing function. Another object is to provide an image capturing device or a display apparatus with high resolution. Another object is to provide a display apparatus or an image capturing device with a high aperture ratio. Another object is to provide an image capturing device or a display apparatus capable of image capturing with high sensitivity. Another object is to provide an image capturing device or a display apparatus with high display quality. Another object is to provide a display apparatus capable of obtaining biological information such as fingerprints. Another object is to provide a display apparatus that functions as a touch panel. Another object is to provide a method for manufacturing the display apparatus with high productivity.

An object of one embodiment of the present invention is to provide a highly reliable display apparatus, a highly reliable image capturing device, or a highly reliable electronic device. An object of one embodiment of the present invention is to provide a display apparatus, an image capturing device, an electronic device, or the like that has a novel structure. An object of one embodiment of the present invention is to at least reduce at least one of problems of the conventional technique.

Note that the description of these objects does not preclude the existence of other objects. One embodiment of the present invention does not have to achieve all of these objects. Note that objects other than these can be derived from the descriptions of the specification, the drawings, the claims, and the like.

### Means for Solving the Problems

One embodiment of the present invention is a display apparatus including a first light-emitting element, a light-receiving element, and a first coloring layer. The first light-emitting element includes a first pixel electrode, a first organic layer over the first pixel electrode, and a common electrode over the first organic layer. The light-receiving element includes a second pixel electrode, a second organic layer over the second pixel electrode, and the common electrode over the second organic layer. The first organic layer includes a first light-emitting layer. The second organic layer includes a photoelectric conversion layer. The first coloring layer is positioned to overlap with the first light-emitting element. The photoelectric conversion layer has sensitivity in a wavelength range of light passing through the first coloring layer.

In the above, a region in which a distance between the first organic layer and the second organic layer is less than or equal to 8 μm is preferably included.

In the above, it is preferable that a resin layer be preferably included, the resin layer be positioned in a region between the first light-emitting element and the light-receiving element, and a side surface of the first organic layer and a side surface of the second organic layer be opposite to each other with the resin layer therebetween.

In the above, an insulating layer is preferably included, the insulating layer is preferably positioned between the first light-emitting element and the light-receiving element, and the insulating layer is preferably in contact with the side surface of the first organic layer and the side surface of the second organic layer.

In the above, a second light-emitting element and a second coloring layer is preferably included: the second light-emitting element preferably includes a third pixel electrode, a third organic layer over the third pixel electrode, and the common electrode over the third organic layer: the third organic layer preferably includes a second light-emitting layer: the second coloring layer is preferably positioned to overlap with the second light-emitting element; and a wavelength range of light passing through the second coloring layer is preferably different from a wavelength range of light passing through the first coloring layer. In the above, the first light-emitting layer preferably contains a material identical to a material of the second light-emitting layer.

In the above, the first organic layer preferably includes a first light-emitting unit over the first pixel electrode, a first charge-generation layer over the first light-emitting unit, and a second light-emitting unit over the first charge-generation layer; and the third organic layer preferably includes a third light-emitting unit over the third pixel electrode, a second charge-generation layer over the third light-emitting unit, and a fourth light-emitting unit over the second charge-generation layer.

In the above, the first light-emitting unit preferably contains a material identical to a material of the third light-emitting unit, the first charge-generation layer preferably contains a material identical to a material of the second charge-generation layer, and the second light-emitting unit preferably contains a material identical to a material of the fourth light-emitting unit.

Another embodiment of the present invention is a method for manufacturing a display apparatus, including the steps of: forming a first pixel electrode and a second pixel electrode: forming a first organic film to cover the first pixel electrode and the second pixel electrode: forming a first sacrificial film over the first organic film: forming a first resist mask over the first sacrificial film to overlap with the first pixel electrode: processing the first sacrificial film into a first sacrificial layer having an island shape using the first resist mask: processing the first organic film into a first organic layer having an island shape using the first sacrificial layer as a mask: forming a second organic film to cover the first organic layer and the second pixel electrode: forming a second sacrificial film over the second organic film: forming a second resist mask over the second sacrificial film to overlap with the second pixel electrode: processing the second sacrificial film into a second sacrificial layer having an island shape using the second resist mask: and processing the second organic film into a second organic layer having an island shape using the second sacrificial layer as a mask. A coloring layer is positioned to overlap with the first organic layer, the first organic layer contains a light-emitting organic compound, and the second organic layer contains a photoelectric conversion material.

Another embodiment of the present invention is a method for manufacturing a display apparatus, including the steps of: forming a first pixel electrode and a second pixel electrode: forming a first organic film to cover the first pixel electrode and the second pixel electrode: forming a first sacrificial film over the first organic film: forming a first resist mask over the first sacrificial film to overlap with the first pixel electrode: processing the first sacrificial film into a first sacrificial layer having an island shape using the first resist mask: processing the first organic film into a first organic layer having an island shape using the first sacrificial layer as a mask: forming a second organic film to cover the first organic layer and the second pixel electrode: forming a second sacrificial film over the second organic film: forming a second resist mask over the second sacrificial film to overlap with the second pixel electrode: processing the second sacrificial film into a second sacrificial layer having an island shape using the second resist mask; and processing the second organic film into a second organic layer having an island shape using the second sacrificial layer as a mask. A coloring layer is positioned to overlap with the second organic layer, the first organic layer contains a photoelectric conversion material, and the second organic layer contains a light-emitting organic compound.

In the above, an insulating film is preferably formed to cover the first organic layer and the second organic layer after the second organic layer is formed. In the above, the insulating film is preferably formed by an atomic layer deposition method.

In the above, a resin layer is preferably formed over the insulating film in a region between the first organic layer and the second organic layer. In the above, a photosensitive organic resin is preferably used for the resin layer.

### Effect of the Invention

According to one embodiment of the present invention, a display apparatus having an image capturing function can be provided. An image capturing device or a display apparatus with high resolution can be provided. A display apparatus or an image capturing device with a high aperture ratio can be provided. An image capturing device or a display apparatus capable of image capturing with high sensitivity can be provided. An image capturing device or a display apparatus with high display quality can be provided. A display apparatus capable of obtaining biological information such as fingerprints can be provided. A display apparatus functioning as a touch panel can be provided. A method for manufacturing the display apparatus with high productivity can be provided.

According to one embodiment of the present invention, a highly reliable display apparatus, a highly reliable image capturing device, or a highly reliable electronic device can be provided. A display apparatus, an image capturing device, an electronic device, or the like having a novel structure can be provided. At least one of problems of the conventional technique can be at least reduced.

Note that the description of these effects does not preclude the existence of other effects. One embodiment of the present invention does not need to have all of these effects. Note that effects other than these can be derived from the descriptions of the specification, the drawings, the claims, and the like.

### BRIEF DESCRIPTION OF THE DRAWINGS

FIG. 1A to FIG. 1C are diagrams illustrating a structure example of a display apparatus.

FIG. 2A to FIG. 2C are diagrams illustrating structure examples of a display apparatus.

FIG. 3A and FIG. 3B are diagrams illustrating a structure example of a display apparatus.

FIG. 4A and FIG. 4B are diagrams illustrating a structure example of a display apparatus.

FIG. 5A and FIG. 5B are diagrams illustrating a structure example of a display apparatus.

FIG. 6A and FIG. 6B are diagrams illustrating a structure example of a display apparatus.

FIG. 7A and FIG. 7B are diagrams illustrating a structure example of a display apparatus.

FIG. 8A to FIG. 8C are diagrams illustrating an example of a method for manufacturing a display apparatus.

FIG. 9A to FIG. 9C are diagrams illustrating an example of a method for manufacturing a display apparatus.

FIG. 10A to FIG. 10C are diagrams illustrating an example of a method for manufacturing a display apparatus.

FIG. 11A to FIG. 11C are diagrams illustrating an example of a method for manufacturing a display apparatus.

FIG. 12A to FIG. 12C are diagrams illustrating an example of a method for manufacturing a display apparatus.

FIG. 13A to FIG. 13C are diagrams illustrating an example of a method for manufacturing a display apparatus.

FIG. 14A to FIG. 14C are diagrams illustrating an example of a method for manufacturing a display apparatus.

FIG. 15A to FIG. 15C are diagrams illustrating an example of a method for manufacturing a display apparatus.

FIG. 16A to FIG. 16C are diagrams illustrating an example of a method for manufacturing a display apparatus.

FIG. 17 is a diagram illustrating a structure example of a display apparatus.

FIG. 18A is a diagram illustrating a structure example of a display apparatus. FIG. 18B is a diagram illustrating a structure example of a transistor.

FIG. 19 is a diagram illustrating a structure example of a display apparatus.

FIG. 20A and FIG. 20B are diagrams illustrating a structure example of a display apparatus.

FIG. 21 is a diagram illustrating a structure example of a display apparatus.

FIG. 22 is a diagram illustrating a structure example of a display apparatus.

FIG. 23 is a diagram illustrating a structure example of a display apparatus.

FIG. 24 is a diagram illustrating a structure example of a display apparatus.

FIG. 25 is a diagram illustrating a structure example of a display apparatus.

FIG. 26A, FIG. 26B, and FIG. 26D are cross-sectional views illustrating examples of a display apparatus. FIG. 26C and FIG. 26E are diagrams illustrating examples of images. FIG. 26F to FIG. 26H are top views illustrating examples of a pixel.

FIG. 27A and FIG. 27B are cross-sectional views illustrating examples of a display apparatus.

FIG. 28A and FIG. 28B are cross-sectional views illustrating examples of a display apparatus.

FIG. 29A to FIG. 29E are cross-sectional views illustrating examples of a display apparatus.

FIG. 30A to FIG. 30C are diagrams illustrating examples of a pixel. FIG. 30D and FIG. 30E are diagrams illustrating examples of pixel circuit diagrams.

FIG. 31A to FIG. 31J are diagrams illustrating structure examples of a display apparatus.

FIG. 32A and FIG. 32B are diagrams illustrating an example of an electronic device.

FIG. 33A to FIG. 33D are diagrams illustrating examples of electronic devices.

FIG. 34A to FIG. 34F are diagrams illustrating examples of electronic devices.

FIG. 35A to FIG. 35F are diagrams illustrating examples of electronic devices.

### MODE FOR CARRYING OUT THE INVENTION

Hereinafter, embodiments are described with reference to the drawings. Note that the embodiments can be implemented in many different modes, and it is readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that in this specification and the like, the ordinal numbers such as “first” and “second” are used in order to avoid confusion among components and do not limit the number.

Hereinafter, the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or formation order) of a stack or the like is described, even in the case where a surface on which the stack is provided (e.g., a formation surface, a support surface, an adhesion surface, or a planar surface) is positioned above the stack in the drawings, the direction and the opposite direction are expressed using “under” and “over”, respectively, in some cases.

In this specification and the like, the term “film” and the term “layer” can be interchanged with each other. For example, in some cases, the term “conductive layer” and the term “insulating layer” can be interchanged with the term “conductive film” and the term “insulating film”, respectively.

Note that in this specification, an EL layer means a layer containing at least a light-emitting substance (also referred to as a light-emitting layer) or a stack including the light-emitting layer provided between a pair of electrodes of a light-emitting element.

In this specification and the like, a display panel that is one embodiment of a display apparatus has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC (Integrated Circuit) is mounted by a COG (Chip On Glass) method or the like is referred to as a display panel module, a display module, or simply a display panel or the like in some cases.

### Embodiment 1

In this embodiment, a structure example of a display apparatus of one embodiment of the present invention and an example of a method for manufacturing the display apparatus will be described.

One embodiment of the present invention is a display apparatus including a light-emitting element (also referred to as a light-emitting device) and a light-receiving element (also referred to as a light-receiving device). The light-emitting element includes a pair of electrodes and an EL layer between them. The light-receiving element includes a pair of electrodes and an active layer between them. The light-emitting element is preferably an organic EL element (an organic electroluminescent element) emitting white light. The light-receiving element is preferably an organic photodiode (an organic photoelectric conversion element).

In addition, the display apparatus includes a light-emitting element emitting white light and a coloring layer overlapping with the light-emitting element in each pixel. When coloring layers which transmit visible light of different colors are used in subpixels provided in pixels, the display apparatus can perform full-color display. Furthermore, the light-emitting elements used in the pixels can be formed using the same materials: thus, the manufacturing step can be simplified and the manufacturing cost can be reduced.

One embodiment of the present invention is capable of image capturing by a plurality of light-receiving elements and thus functions as an image capturing device. In this case, the light-emitting elements can be used as a light source for image capturing. Moreover, one embodiment of the present invention is capable of displaying an image with the plurality of light-emitting elements and thus functions as a display apparatus. Accordingly, one embodiment of the present invention can be regarded as a display apparatus that has an image capturing function or an image capturing device that has a display function.

For example, in the display apparatus of one embodiment of the present invention, light-emitting elements are arranged in a matrix in a display portion, and light-receiving elements are also arranged in a matrix in the display portion. Hence, the display portion has a function of displaying an image and a function of a light-receiving portion. An image can be captured by the plurality of light-receiving elements provided in the display portion, so that the display apparatus can function as an image sensor, a touch panel, or the like. That is, the display portion can capture an image or detect approach or contact of an object, for example. Furthermore, since the light-emitting elements provided in the display portion can be used as a light source at the time of receiving light, a light source does not need to be provided separately from the display apparatus: thus, a highly functional display apparatus can be provided without increasing the number of electronic components.

In one embodiment of the present invention, when an object reflects light that is emitted from the light-emitting element and passes through the coloring layer, the light-receiving element can detect the reflected light: thus, image capturing, touch (including non-contact touch) detection, or the like can be performed even in a dark environment.

Furthermore, when a finger, a palm, or the like touches the display portion of the display apparatus of one embodiment of the present invention, an image of the fingerprint, the palm print, or the like can be captured. Thus, an electronic device including the display apparatus of one embodiment of the present invention can perform personal authentication by using the captured image of the fingerprint, the palm print, or the like. Accordingly, an image capturing device for the fingerprint authentication, the palm print authentication, or the like does not need to be additionally provided, and the number of components of the electronic device can be reduced. Since the light-receiving elements are arranged in a matrix in the display portion, an image of a fingerprint, a palm print, or the like can be captured in any position in the display portion, which can provide a highly convenient electronic device.

Here, in the case where the light-emitting element of each pixel is formed using an organic EL element that emits white light, separate formation of light-emitting layers in the pixels is not necessary. Thus, a layer other than a pixel electrode included in the light-emitting element (e.g., a light-emitting layer) can be shared by pixels. However, some layers included in the light-emitting element have relatively high conductivity: when a layer having high conductivity is shared by pixels, a leakage current (also referred to as a side leakage or a side leakage current) might be generated between the pixels. Particularly when the increase in resolution or aperture ratio of a display apparatus reduces the distance between the pixels, the leakage current might become too large to ignore. This causes luminance decrease, contrast decrease, and the like to degrade display quality. Furthermore, the leakage current adversely affects electric power efficiency, power consumption, and the like.

In addition, in the case where the leakage current is also generated between the light-emitting element and the light-receiving element, the leakage current is a factor of noise in image capturing by the light-receiving element: thus, the sensitivity of the image capturing (e.g., a signal-noise ratio (S/N ratio)) might be reduced.

In view of the above, in one embodiment of the present invention, at least part of the light-emitting element is processed in each pixel by a photolithography method, and at least part of the light-receiving element is processed into an island shape in each pixel. Note that a structure may be employed in which at least part of the light-receiving element is processed into an island shape first, and then at least part of the light-emitting element is processed. Here, a portion where the light-emitting element is formed into an island shape includes a layer containing a light-emitting compound in the light-emitting element (also referred to as a light-emitting layer). In addition, a portion where the light-receiving element is formed into an island shape includes a layer containing a photoelectric conversion material in the light-receiving element (also referred to as an active layer or a photoelectric conversion layer).

Such a structure enables a current leakage path (a leakage path) between the light-emitting element and the light-receiving element to be cut. Thus, the leakage current between the light-emitting element and the light-receiving element is inhibited, whereby high-accuracy image capturing with a high signal-noise ratio (S/N ratio) can be performed. Therefore, a clear image can be captured even with weak light. Thus, the luminance of the light-emitting element used as a light source can be reduced in image capturing, leading to a reduction in power consumption.

Furthermore, a current leakage path between two adjacent light-emitting elements can be cut, whereby the leakage current can be inhibited. Accordingly, a higher luminance, a higher contrast, higher display quality, higher power efficiency, lower power consumption, or the like can be achieved.

Furthermore, an insulating layer is preferably formed to protect the side surfaces of the stacked organic film that are exposed by the etching. This increases the reliability of the display apparatus.

It is known that in the case where light-emitting layers are separately formed for light-emitting elements of different colors, the light-emitting layers are formed by an evaporation method using a shadow mask such as a metal mask or an FMM (a fine metal mask or a high-resolution metal mask). Note that in this specification and the like, a device formed using a metal mask or an FMM is sometimes referred to as a device having an MM (metal mask) structure.

As described above, in one embodiment of the present invention, fine patterning of the organic layer including the light-emitting layer and the organic layer including the active layer is performed by a photolithography method without a shadow mask such as a metal mask. Note that in this specification and the like, a device manufactured without using a metal mask or an FMM is sometimes referred to as a device having an MML (metal maskless) structure. With the use of the MML structure, a display apparatus with a high resolution and a high aperture ratio, which has been difficult to achieve, can be obtained.

Although it is difficult to set the distance between the pixels to be less than 10 μm by a formation method using a metal mask, for example, the above method can shorten the distance to be less than or equal to 8 μm, less than or equal to 3 μm, less than or equal to 2 μm, or less than or equal to 1 μm. Here, the distance between the pixels can be determined by the distance between facing end portions of adjacent pixel electrodes. Alternatively, the distance between the pixels can be determined by the distance between facing end portions of the organic layer including the light-emitting layer and the organic layer including the active layer, which are adjacent to each other.

By reducing the distance between the pixels as described above, the area of a non-light-emitting region that may exist between two light-emitting elements can be significantly reduced, and the aperture ratio can be close to 100%. For example, the aperture ratio is higher than or equal to 50%, higher than or equal to 60%, higher than or equal to 70%, higher than or equal to 80%, or higher than or equal to 90%: that is, an aperture ratio lower than 100% can be achieved.

Hereinafter, structure examples and manufacturing method examples of a display apparatus of one embodiment of the present invention will be described with reference to drawings.

### Structure Example 1

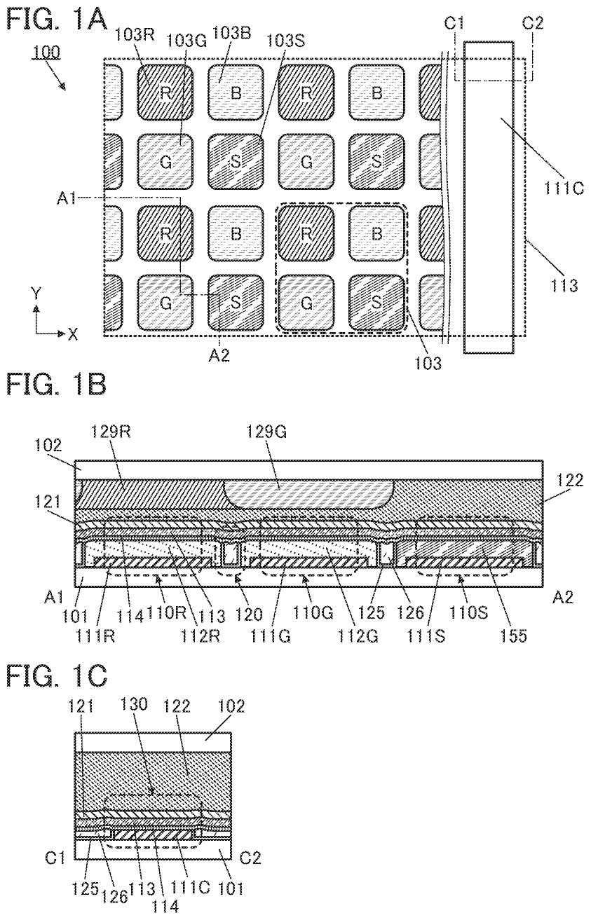

FIG. 1A is a schematic top view of a display apparatus 100. FIG. 1B and FIG. 1C are each a cross-sectional schematic view taken along the dashed-dotted line A1-A2 and the dashed-dotted line C1-C2 in FIG. 1A, respectively. The display apparatus 100 includes a pixel portion in which a plurality of pixels 103 are arranged in a matrix.

The pixel 103 illustrated in FIG. 1A employs a matrix arrangement. The pixel 103 illustrated in FIG. 1A is composed of four subpixels of subpixels 103R, 103G, 103B, and 103S. Note that in FIG. 1A, regions of the subpixels are denoted by R, G, B, and S to easily differentiate the subpixels.

The subpixels 103R, 103G, and 103B respectively include light-emitting elements 110R, 110G, and 110B (hereinafter collectively referred to as a “light-emitting element 110” in some cases) which emit white light. Coloring layers 129R, 129G, and 129B (hereinafter collectively referred to as a “coloring layer 129” in some cases) are provided to overlap with the light-emitting elements 110R, 110G, and 110B, respectively, whereby the subpixels emit light of different colors. Note that although not illustrated in FIG. 1B, the coloring layer 129B is also provided in a manner similar to those of the coloring layers 129R and 129G. As the subpixels 103R, 103G, and 103B, subpixels of three colors of red (R), green (G), and blue (B) may be provided. In addition, without limitation to this, subpixels of three colors of yellow (Y), cyan (C), and magenta (M) may be provided as the subpixels.

FIG. 1A illustrates a structure in which two subpixels are alternately arranged in one direction. Note that the arrangement method of the subpixels is not limited thereto: another arrangement method such as a stripe arrangement, an S stripe arrangement, a delta arrangement, a Bayer arrangement, or a zigzag arrangement may be used, or a PenTile arrangement, a diamond arrangement, or the like may also be used.

As the light-emitting elements 110R, 110G, and 110B, an EL element such as an OLED (Organic Light Emitting Diode) is preferably used. As examples of a light-emitting substance contained in the EL element, a substance that emits fluorescent light (a fluorescent material), a substance that emits phosphorescent light (a phosphorescent material), an inorganic compound (e.g., a quantum dot material), a substance exhibiting thermally activated delayed fluorescence (a thermally activated delayed fluorescent (TADF) material), and the like can be given.

The subpixel 103S includes a light-receiving element 110S. As the light-receiving element 110S, a pn photodiode or a pin photodiode can be used, for example. The light-receiving element 110S functions as a photoelectric conversion element that detects light incident on the light-receiving element 110S and generates charge. The amount of generated charge in the photoelectric conversion element is determined depending on the amount of incident light. It is particularly preferable to use an organic photodiode including a layer containing an organic compound as the light-receiving element 110S. An organic photodiode, which is easily made thin, lightweight, and large in area and has a high degree of freedom for shape and design, can be used in a variety of devices.

FIG. 1A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged. In FIG. 1A, the common electrode 113 is denoted by the dashed line.

The connection electrode 111C can be provided along the outer periphery of the display region. For example, the connection electrode 111C may be provided along one side of the outer periphery of the display region or two or more sides of the outer periphery of the display region. That is, in the case where the display region has a rectangular top surface shape, a top surface shape of the connection electrode 111C can have a band shape, an L shape, a U shape (a square bracket shape), a quadrangular shape, or the like.

As illustrated in FIG. 1B, in the display apparatus 100, the light-emitting element 110R, the light-emitting element 110G, the light-emitting element 110B (not illustrated), and the light-receiving element 110S are provided over a substrate 101, and a protective layer 121 is provided to cover them. Here, it is preferable that a wiring, a transistor, an electrode, or the like (not illustrated) be provided over the substrate 101, and an insulating layer be formed in the uppermost portion. Note that although the subpixel 103B is not illustrated in FIG. 1B, components included in the subpixel 103B can be provided in a manner similar to those of components included in the subpixel 103R and the subpixel 103G. A resin layer 122 is provided over the protective layer 121. A substrate 102 is attached thereover with the resin layer 122. The substrate 102 is provided with the coloring layer 129R, the coloring layer 129G, and the coloring layer 129B (not illustrated). In a region between a light-emitting element and a light-receiving element which are adjacent to each other, an insulating layer 125 and a resin layer 126 over the insulating layer 125 are provided.

The light-emitting element 110R includes a pixel electrode 111R, an organic layer 112R over the pixel electrode 111R, an organic layer 114 over the organic layer 112R, and the common electrode 113 over the organic layer 114. The light-emitting element 110G includes a pixel electrode 111G, an organic layer 112G over the pixel electrode 111G, the organic layer 114 over the organic layer 112G, and the common electrode 113 over the organic layer 114. The light-receiving element 110S includes a pixel electrode 111S, an organic layer 155 over the pixel electrode 111S, the organic layer 114 over the organic layer 155, and the common electrode 113 over the organic layer 114. The light-emitting elements 110R, 110G, and 110B and the light-receiving element 110S are preferably patterned to have an island shape. The organic layer 114 and the common electrode 113 are each provided as a film shared by the light-emitting element 110R, the light-emitting element 110G, the light-receiving element 110S, and the light-emitting element 110B. The organic layer 114 can also be referred to as a common layer.

The organic layer 112R, the organic layer 112G, and an organic layer 112B (not illustrated) preferably emit light of white (W). The organic layer 112R, the organic layer 112G, and the organic layer 112B each include at least a light-emitting layer. The coloring layer 129R. the coloring layer 129G, and the coloring layer 129B (not illustrated) which transmit light of different colors are respectively provided over the organic layer 112R, the organic layer 112G, and the organic layer 112B, whereby the subpixel 103R, the subpixel 103G, and the subpixel 103B which emit light of different colors can be formed. Note that there is no particular limitation on the structure of the light-emitting element in this embodiment, and either a single structure or a tandem structure can be employed. Note that a structure example of the light-emitting element will be described later.

The organic layer 155 included in the light-receiving element 110S contains a photoelectric conversion material that has sensitivity in a wavelength range of visible light or infrared light. In a wavelength range in which the photoelectric conversion material contained in the organic layer 155 preferably include one or more of a wavelength of light passing through the coloring layer 129R, a wavelength of light passing through the coloring layer 129G, and a wavelength of light passing through the coloring layer 129B. The organic layer 155 can also be referred to as an active layer or a photoelectric conversion layer.

Hereafter, in the description common to the light-emitting element 110R, the light-emitting element 110G, and the light-emitting element 110B, the term “light-emitting element 110” is used in some cases. In the same manner, in the description common to the components that are distinguished by alphabets, such as the organic layer 112R, the organic layer 112G, and the organic layer 112B, reference numerals without alphabets are sometimes used.

Note that as illustrated in FIG. 1B, the organic layers 112 and the organic layer 155 preferably cover the pixel electrodes 111. In this case, the end portions of the side surfaces of the organic layers 112 and the organic layer 155 are positioned outward from the end portions of the side surfaces of the pixel electrodes 111. In addition, regions of the organic layers 112 and the organic layer 155 which do not overlap with the pixel electrodes 111 are in contact with the top surface of the substrate 101. Thus, the formation step of the organic layers 112 and the organic layer 155, for example, can be performed without the pixel electrodes 111 being exposed. Accordingly, damage to the pixel electrodes 111 can be reduced in the step, thereby achieving higher yield of the light-emitting elements 110 and the light-receiving element 110S, higher display quality of the light-emitting elements 110, and image capturing with high sensitivity with the light-receiving element 110S.

In each light-emitting element, a stacked film positioned between the pixel electrode and the common electrode 113 can be referred to as an EL (Electroluminescence) layer. In other words, the organic layer 112 and the organic layer 114 can be collectively referred to as an EL layer. In addition, in the light-receiving element 110S, a stacked film positioned between the pixel electrode 111S and the common electrode 113 can be referred to as a PD (Photodiode) layer. In other words, the organic layer 155 and the organic layer 114 can be collectively referred to as a PD layer.

In addition to the light-emitting layer and the light-receiving layer, the organic layer 112, the organic layer 155, and the organic layer 114 can each independently include one or more of an electron-injection layer, an electron-transport layer, an electron-blocking layer, a hole-blocking layer, a hole-injection layer, and a hole-transport layer. For example, it is possible to employ a structure in which the organic layer 112 has a stacked-layer structure of a hole-injection layer and a hole-transport layer from the pixel electrode 111 side, an electron-transport layer is included over the light-emitting layer or the light-receiving layer, and the organic layer 114 includes an electron-injection layer. Alternatively, it is possible to employ a structure in which the organic layer 112 has a stacked-layer structure of an electron-injection layer and an electron-transport layer from the pixel electrode 111 side, a hole-transport layer is included over the light-emitting layer or the light-receiving layer, and the organic layer 114 includes a hole-injection layer.

Note that as for a layer positioned between a pair of electrodes of the light-emitting element or the light-receiving element 110S, such as the organic layer 112, the organic layer 114, or the organic layer 155, the name “organic layer” implies a “layer that constitutes an organic EL element or an organic photoelectric conversion element” and does not necessarily mean that an organic layer contains an organic compound. For example, a film not containing an organic compound but containing only an inorganic compound or an inorganic substance can be used for the organic layer 112, the organic layer 114, and the organic layer 155.

The pixel electrode 111R, the pixel electrode 111G, and a pixel electrode 111B (not illustrated) are provided for the respective light-emitting elements. The common electrode 113 and the organic layer 114 are provided as continuous layers shared by the light-emitting elements and the light-receiving element 110S. A conductive film having a light-transmitting property with respect to visible light is used for either the respective pixel electrodes or the common electrode 113, and a conductive film having a reflective property is used for the other. When the pixel electrodes are light-transmitting electrodes and the common electrode 113 is a reflective electrode, a bottom-emission display apparatus can be obtained: in contrast, when the respective pixel electrodes are reflective electrodes and the common electrode 113 is a light-transmitting electrode, a top-emission display apparatus can be obtained. Note that when both the pixel electrodes and the common electrode 113 have a light-transmitting property, a dual emission display apparatus can be obtained.

The protective layer 121 is provided over the common electrode 113 so as to cover the light-emitting element 110R, the light-emitting element 110G, the light-receiving element 110S, and the light-emitting element 110B (not illustrated). The protective layer 121 has a function of preventing diffusion of impurities such as water into the light-emitting elements from above.

A slit 120 is provided between the light-emitting element and the light-receiving element 110S adjacent to each other and between two adjacent light-emitting elements. The slit 120 corresponds to a portion where the organic layer 112 or the organic layer 155 positioned between the light-emitting element and the light-receiving element 110S adjacent to each other or between two adjacent light-emitting elements are etched.

Here, by processing the organic layers 112 and the organic layer 155 by a photolithography method, the distance between the pixels isolated by the slit 120 can be shortened to be less than or equal to 8 μm, less than or equal to 3 μm, less than or equal to 2 μm, or less than or equal to 1 μm. Here, the distance between the pixels can be determined by the distance between facing end portions of the organic layers 112, the distance between facing end portions of the organic layer 112 and the organic layer 155, and the distance between facing end portions of the organic layers 155, for example. Alternatively, the distance between the pixels can be determined by the distance between facing end portions of the adjacent pixel electrodes 111. The distance between the pixels is shortened in this manner, whereby a display apparatus with high resolution and a high aperture ratio can be provided.

Moreover, the organic layer 112 and the organic layer 155 adjacent to each other are isolated by the slit 120, in which case a current leakage path between the organic layer 112 and the organic layer 155 can be cut. Accordingly, the leakage current between the organic layer 112 and the organic layer 155 is inhibited, whereby high-accuracy image capturing with a high signal-noise ratio (S/N ratio) can be performed. Therefore, a clear image can be captured even with weak light. Thus, the luminance of the light-emitting element used as a light source can be reduced in image capturing, leading to a reduction in power consumption.

Furthermore, the adjacent organic layers 112 are isolated by the slit 120, in which case the current leakage path between the adjacent organic layers 112 can be cut, whereby the leakage current can be inhibited. Accordingly, a higher luminance, a higher contrast, higher display quality, higher power efficiency, lower power consumption, or the like can be achieved in the light-emitting element.

In the slit 120, the insulating layer 125 and the resin layer 126 are provided. The insulating layer 125 is provided along a sidewall and a bottom surface of the slit 120. Thus, the insulating layer 125 is in contact with the side surface of the organic layer 112 and the side surface of the organic layer 155. The resin layer 126 is provided over the insulating layer 125 and fills a depressed portion positioned in the slit 120. Thus, the resin layer 126 is positioned between the side surfaces of the organic layers 112 or between the side surface of the organic layer 112 and the side surface of the organic layer 155. In other words, the side surfaces of the organic layers 112 or the side surface of the organic layer 112 and the side surface of the organic layer 155 face each other with the resin layer 126 therebetween. The resin layer 126 has a function of planarizing the top surface by filling the depressed portion positioned in the slit 120. The planarization for the depressed portion in the slit 120 by the resin layer 126 can improve coverage with the organic layer 114, the common electrode 113, and the protective layer 121.

The slit 120 can be formed at the same time as the formation of an opening portion for an external connection terminal such as the connection electrode 111C: thus, they can be formed without increasing the number of steps. Since the slit 120 includes the insulating layer 125 and the resin layer 126, an effect of preventing a short circuit between the pixel electrode 111 and the common electrode 113 is produced. The resin layer 126 has an effect of improving adhesion of the organic layer 114. That is, providing the resin layer 126 improves adhesion of the organic layer 114, so that film separation of the organic layer 114 can be inhibited.

The insulating layer 125 is provided in contact with the side surface of the organic layer (e.g., the organic layer 112 or the organic layer 155): thus, a structure where the organic layer and the resin layer 126 are not in contact with each other can be obtained. When the organic layer and the resin layer 126 are in contact with each other, the organic layer might be dissolved by an organic solvent or the like included in the resin layer 126. In view of this, the insulating layer 125 is provided between the organic layer and the resin layer 126 as described in this embodiment, the side surface of the organic layer can be protected. Note that the slit 120 can have a structure that allows division of at least any one or more of a hole-injection layer, a hole-transport layer, an electron-blocking layer, a light-emitting layer, an active layer, a hole-blocking layer, an electron-transport layer, and an electron-injection layer.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, a metal oxide film such as an aluminum oxide film or a hafnium oxide film or an inorganic insulating film such as a silicon oxide film, which is formed by an atomic layer deposition (ALD) method, is used for the insulating layer 125, whereby the insulating layer 125 can have few pinholes and an excellent function of protecting the EL layer.

Note that in this specification and the like, oxynitride refers to a material that contains 25 more oxygen than nitrogen, and nitride oxide refers to a material that contains more nitrogen than oxygen. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 125 can be formed by a sputtering method, a CVD (Chemical Vapor Deposition) method, a PLD (Pulsed Laser Deposition) method, an ALD method, or the like. The insulating layer 125 is preferably formed by an ALD method with favorable coverage.

As the resin layer 126, an insulating layer containing an organic material can be suitably used. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

A photosensitive resin can also be used for the resin layer 126. A photoresist may be used for the photosensitive resin. As the photosensitive resin, a positive photosensitive material or a negative photosensitive material can be used.

The resin layer 126 may be formed using a colored material (e.g., a material containing a black pigment) to have a function of blocking stray light from adjacent pixels and inhibiting color mixture.

A reflective film (e.g., a metal film containing one or more selected from silver, palladium, copper, titanium, aluminum, and the like) may be provided between the insulating layer 125 and the resin layer 126 so that light emitted from the light-emitting layer is reflected by the reflective film; hence, a function of increasing the light extraction efficiency may be added.

Although the top surface of the resin layer 126 is preferably as flat as possible, its surface has a gently curved surface shape in some cases. FIG. 1B and the like illustrate an example in which the top surface of the resin layer 126 has a wave shape with a depressed portion and a projected portion: however, one embodiment of the present invention is not limited thereto. For example, the top surface of the resin layer 126 may be a convex surface, a concave surface, or a flat surface.

The protective layer 121 can have, for example, a single-layer structure or a stacked-layer structure including at least an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide may be used for the protective layer 121.

FIG. 1C illustrates a connection portion 130 in which the connection electrode 111C is electrically connected to the common electrode 113. In the connection portion 130, the common electrode 113 is provided over the connection electrode 111C with the organic layer 114 therebetween. The insulating layer 125 is provided in contact with the side surface of the connection electrode 111C, and the resin layer 126 is provided over the insulating layer 125.

Note that the organic layer 114 is not necessarily provided in the connection portion 130. In this case, in the connection portion 130, the common electrode 113 is provided over and in contact with the connection electrode 111C and the protective layer 121 is provided to cover the common electrode 113.

As the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. With this, the top surface of the organic insulating film can be flat, and accordingly, coverage with the inorganic insulating film thereover is improved, leading to an improvement in barrier properties. Moreover, the top surface of the protective layer 121 is flat: therefore, when a component (e.g., a color filter, an electrode of a touch sensor, a lens, a lens array, or the like) is provided above the protective layer 121, the component can be less affected by an uneven shape caused by the lower structure.

The resin layer 122 is provided over the protective layer 121. For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet or the like may be used.

The coloring layer 129 (the coloring layer 129R, the coloring layer 129G, and the coloring layer 129B (not illustrated)) is provided between the resin layer 122 and the substrate 102. The coloring layer 129R has a region overlapping with the light-emitting element 110R, the coloring layer 129G has a region overlapping with the light-emitting element 110G, and the coloring layer 129B has a region overlapping with the light-emitting element 110B (not illustrated). The coloring layers 129R, 129G, and 129B each include a region overlapping with at least the light-emitting layer included in the corresponding light-emitting element 110.

The coloring layer 129R, the coloring layer 129G, and the coloring layer 129B have functions of transmitting light in different wavelength ranges. For example, the coloring layer 129R has a function of transmitting light with intensity in a red wavelength range, the coloring layer 129G has a function of transmitting light with intensity in a green wavelength range, and the coloring layer 129B has a function of transmitting light with intensity in a blue wavelength range. Thus, the display apparatus 100 can perform full-color display. Note that the coloring layer 129 may have a function of transmitting light of any of cyan, magenta, and yellow.

Here, the adjacent coloring layers 129 preferably include an overlapping region. Specifically, the adjacent coloring layers 129 preferably include the overlapping region in a region not overlapping with the light-emitting element 110. When the coloring layers 129 that transmit light of different colors overlap with each other, the coloring layers 129 in the region where the coloring layers 129 overlap with each other can function as light-blocking layers. Thus, light emitted from the light-emitting element 110 can be inhibited from leaking to an adjacent subpixel. For example, light emitted from the light-emitting element 110R overlapping with the coloring layer 129R can be inhibited from entering the coloring layer 129G. Consequently, the contrast of images displayed on the display apparatus can be increased, and the display apparatus can have high display quality.

Note that the adjacent coloring layers 129 may include no overlapping region. In this case, a light-blocking layer is preferably provided in a region not overlapping with the light-emitting elements 110. The light-blocking layer can be provided on a surface of the substrate 102 on the resin layer 122 side, for example.

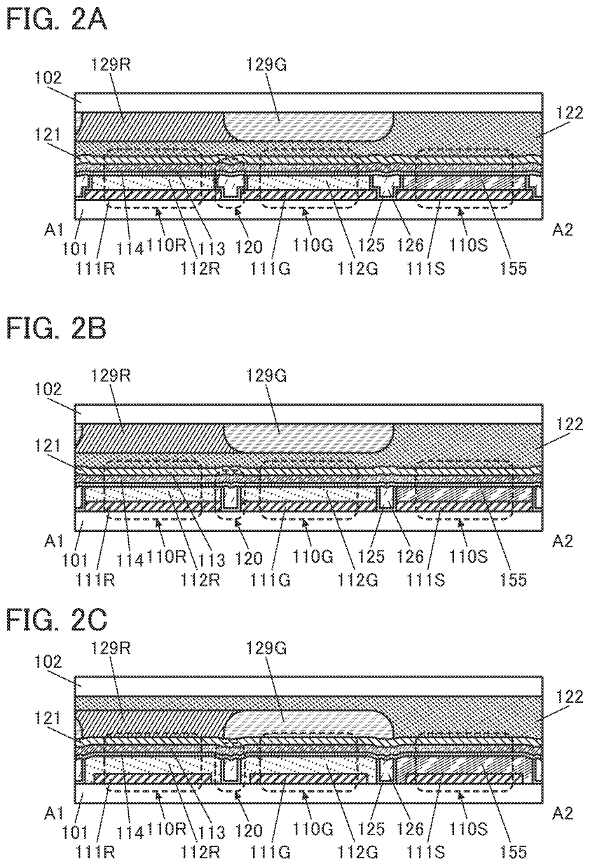

Note that although the structure in which the organic layers 112 and the organic layer 155 cover the pixel electrodes 111 is described above, the present invention is not limited thereto. As illustrated in FIG. 2A, a structure may be employed in which the organic layers 112 and the organic layer 155 are formed only over flat portions of the pixel electrodes 111 and not formed beyond the end portions of the pixel electrodes 111. Here, FIG. 2A is a schematic cross-sectional view taken along the dashed-dotted line A1-A2 in FIG. 1A. Such a structure can inhibit generation of disconnection of the organic layers 112 and the organic layer 155 due to steps of the pixel electrodes 111. Furthermore, the disconnection can be prevented from generating additional disconnection of the organic layer 114 and the common electrode 113.

As illustrated in FIG. 2B, a structure may be employed in which the side surfaces of the organic layers 112 and the organic layer 155 are substantially aligned with the side surfaces of the pixel electrodes 111. Here, FIG. 2B is a schematic cross-sectional view taken along the dashed-dotted line A1-A2 in FIG. 1A.

As illustrated in FIG. 2C, a structure may be employed in which the coloring layers 129 are provided in contact with the top surface of the protective layer 121. In that case, the resin layer 122 is provided to cover the coloring layers 129 and the protective layer 121. The coloring layers 129 are formed over the protective layer 121, whereby positional alignment of the light-emitting elements with the coloring layers 129 becomes easy and the display apparatus with extremely high resolution can be obtained.

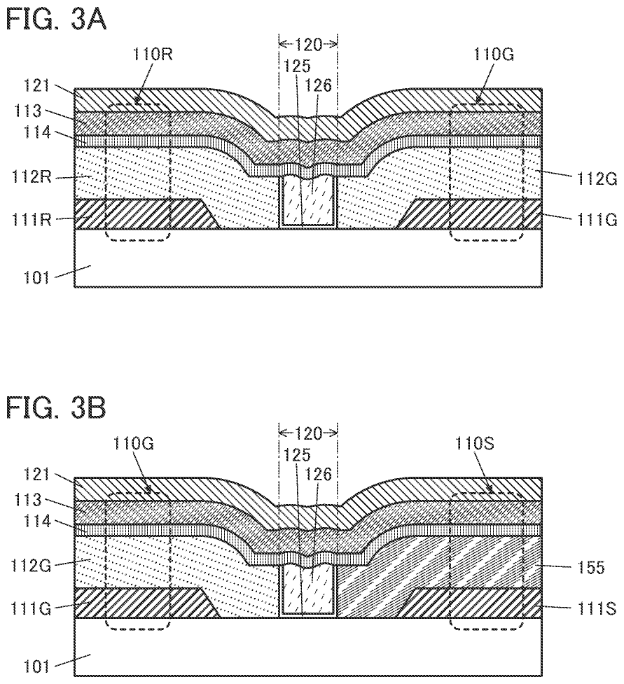

Next, a preferable structure of the slit 120 and its vicinity is described in detail. FIG. 3A is a schematic cross-sectional view including part of the light-emitting element 110R, part of the light-emitting element 110G, and a region therebetween in FIG. 1B.

As illustrated in FIG. 3A, the end portion of the pixel electrode 111 preferably has a tapered shape. This can improve the step coverage with the organic layer 112. Note that in this specification and the like, the end portion of an object having a tapered shape indicates that the end portion of the object has a cross-sectional shape in which the angle between a surface of the object and a surface on which the object is formed is greater than 0° and less than 90° in a region of the end portion, and the thickness continuously increases from the end portion. The pixel electrode 111R and the like illustrated here have a single-layer structure but may include a plurality of layers stacked.

The organic layer 112R is provided to cover the pixel electrode 111R. The organic layer 112G is provided to cover the pixel electrode 111G. These organic layers 112 are formed by dividing a continuous film with the slit 120.

The insulating layer 125 is provided inside the slit 120 and in contact with the side surface of the organic layer 112R and the side surface of the organic layer 112G. The insulating layer 125 is provided to cover the top surface of the substrate 101.

The resin layer 126 is provided in contact with the top and side surfaces of the insulating layer 125. The resin layer 126 has a function of filling a depressed portion of the formation surface of the organic layer 114 for planarization.

The organic layer 114, the common electrode 113, and the protective layer 121 are formed in this order to cover the top surfaces of the organic layer 112R, the organic layer 112G, the insulating layer 125, and the resin layer 126. Note that the organic layer 114 is not necessarily provided when not needed.

FIG. 3B is a schematic cross-sectional view of part of the light-emitting element 110G, part of the light-receiving element 110S, and the slit 120 positioned therebetween.

The organic layer 112G is provided to cover the pixel electrode 111G. The organic layer 155 is provided to cover the pixel electrode 111S. The organic layer 112G and the organic layer 155 are divided by the slit 120.

In the enlarged views illustrated in FIG. 3A and FIG. 3B, the region between the light-emitting element 110R and the light-emitting element 110G and the region between the light-emitting element 110G and the light-receiving element 110S are described: however, a region between the light-emitting element 110R and the light-emitting element 110B, a region between the light-emitting element 110G and the light-emitting element 110B, a region between the light-emitting element 110R and the light-receiving element 110S, and a region between the light-emitting element 110B and the light-receiving element 110S also have a similar structure.

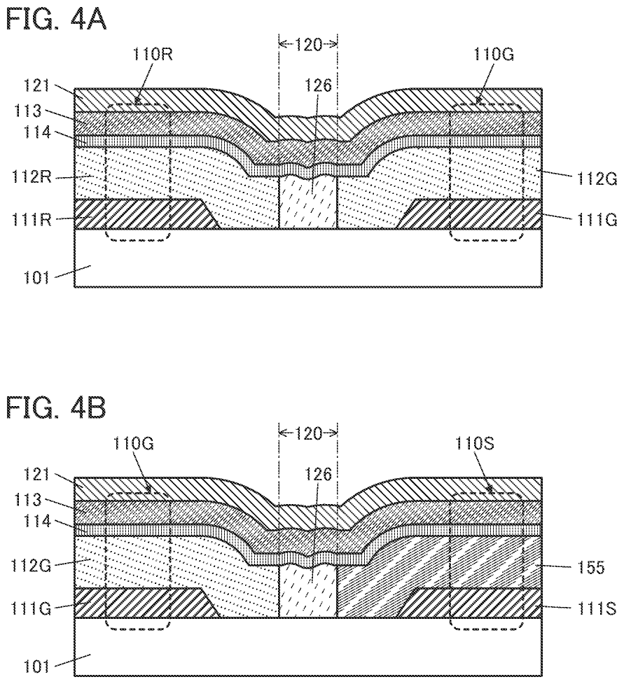

FIG. 4A and FIG. 4B are schematic cross-sectional views not including the insulating layer 125. In FIG. 4A, the resin layer 126 is provided in contact with the side surface of the organic layer 112R and the side surface of the organic layer 112G. In FIG. 4B, the resin layer 126 is provided in contact with the side surface of the organic layer 155 and the side surface of the organic layer 112G.

In this case, part of the EL layer or part of the PD layer is dissolved by a solvent used for forming a film to be the resin layer 126 in some cases. Therefore, water or alcohol such as ethyl alcohol, methyl alcohol, isopropyl alcohol (IPA), or glycerin is preferably used as the solvent for the resin layer 126 in the case where the insulating layer 125 is not provided. Note that without limitation to this, a solvent that does not dissolve or does not easily dissolve the EL layer and the PD layer may be used.

In this manner, the display apparatus of one embodiment of the present invention can have a structure in which an insulator covering the end portion of the pixel electrode is not provided. In other words, the display apparatus can have a structure in which an insulator is not provided between the pixel electrode and the EL layer. With such a structure, light can be efficiently extracted from the EL layer, leading to extremely low viewing angle dependence. For example, in the display apparatus of one embodiment of the present invention, the viewing angle (the maximum angle with a certain contrast ratio maintained when the screen is seen from an oblique direction) can be greater than or equal to 100° and less than 180°, preferably greater than or equal to 150° and less than or equal to 170°. Note that the viewing angle refers to that in both the vertical direction and the horizontal direction. The display apparatus of one embodiment of the present invention can have improved viewing angle characteristics and high image visibility.

### Modification Example

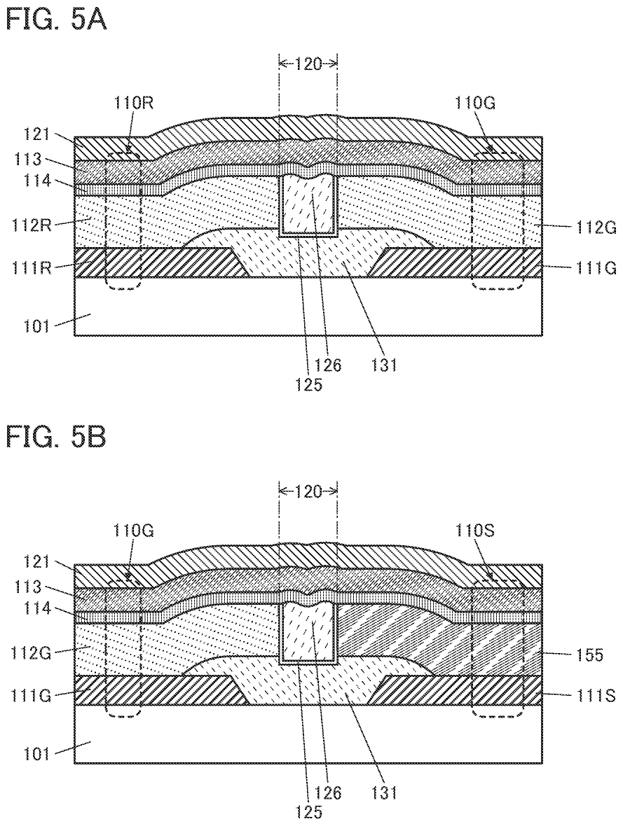

FIG. 5A and FIG. 5B are modification examples of FIG. 3A and FIG. 3B, respectively. FIG. 5A and FIG. 5B illustrate an example where an insulating layer 131 covering the end portions of the pixel electrodes is provided.

The insulating layer 131 has a function of planarizing a formation surface of the organic layer 112. The end portion of the insulating layer 131 preferably has a tapered shape. When an organic resin is used for the insulating layer 131, its surface can be moderately curved. Thus, coverage with a film formed over the insulating layer 131 can be improved. The insulating layer 131 has a function of preventing unintended electrical short circuit between two adjacent pixel electrodes 111.

Examples of materials that can be used for the insulating layer 131 include an acrylic resin, a polyimide resin, an epoxy resin, a polyamide resin, a polyimide-amide resin, a siloxane resin, a benzocyclobutene-based resin, a phenol resin, and precursors of these resins.

As illustrated in FIG. 5A and FIG. 5B, the insulating layer 131 may have a depressed portion in a region overlapping with the slit 120. This depressed portion can be formed by etching of part of an upper portion of the insulating layer 131 at the time of etching for forming the slit 120. Part of the insulating layer 125 is formed to fit in the depressed portion of the insulating layer 131, which can improve the adhesion between them. Here, the slit 120 is provided in a region overlapping with the insulating layer 131.

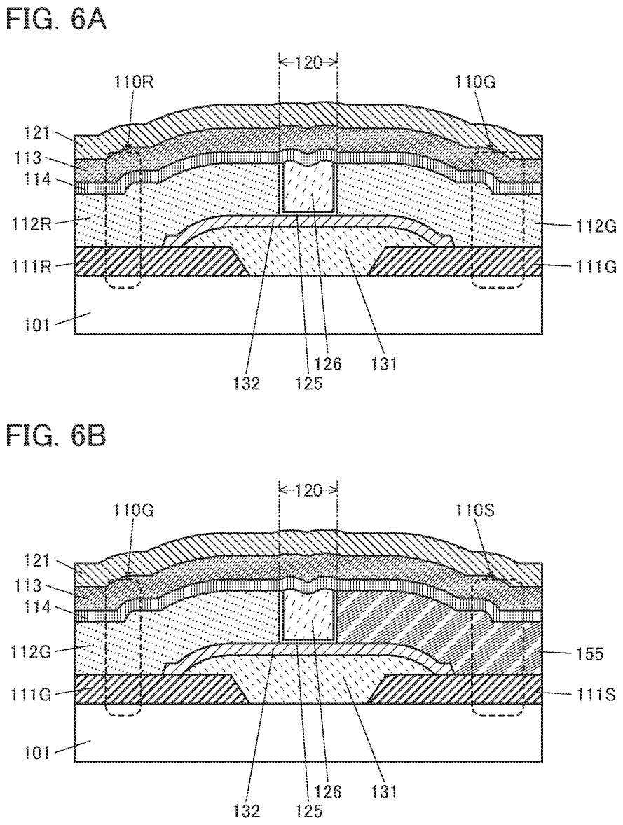

FIG. 6A and FIG. 6B are each an example in which an insulating layer 132 is provided over the insulating layer 131.

The insulating layer 132 overlaps with the end portions of the pixel electrodes 111 with the insulating layer 131 therebetween. The insulating layer 132 is provided to cover the end portion of the insulating layer 131. The insulating layer 132 includes a portion in contact with the top surface of the pixel electrode 111.

The end portion of the insulating layer 132 preferably has a tapered shape. Thus, the step coverage with a film formed over the insulating layer 132, such as the EL layer provided to cover the end portion of the insulating layer 132, can be improved.

It is preferable that the thickness of the insulating layer 132 be smaller than that of the insulating layer 131. When the insulating layer 132 is formed to be thin, the step coverage with a film formed over the insulating layer 132 can be improved.

Examples of inorganic insulating materials that can be used for the insulating layer 132 include oxide and nitride such as silicon oxide, silicon oxynitride, silicon nitride oxide, silicon nitride, aluminum oxide, aluminum oxynitride, and hafnium oxide. In addition, yttrium oxide, zirconium oxide, gallium oxide, tantalum oxide, magnesium oxide, lanthanum oxide, cerium oxide, neodymium oxide, or the like may be used.

Films containing the above inorganic insulating materials may be stacked for the insulating layer 132. For example, a stacked-layer structure in which a silicon oxide film or a silicon oxynitride film is stacked over a silicon nitride film, or a stacked-layer structure in which a silicon oxide film or a silicon oxynitride film is stacked over an aluminum oxide film can be employed. The silicon oxide film and the silicon oxynitride film are films especially not easily etched: hence, it is preferable that the films be placed on the upper side. Furthermore, the silicon nitride film and the aluminum oxide film are films through which water, hydrogen, oxygen, and the like are not easily diffused: hence, the films function as barrier films preventing a gas released from the insulating layer 131 from diffusing into the light-emitting elements when the films are placed on the insulating layer 131 side.

Here, the slit 120 is provided in a region overlapping with the insulating layer 132. Provision of the insulating layer 132 can prevent the top surface of the insulating layer 131 from being etched at the time of forming the slit 120.

### Structure Example 2

More specific structure examples are described below.

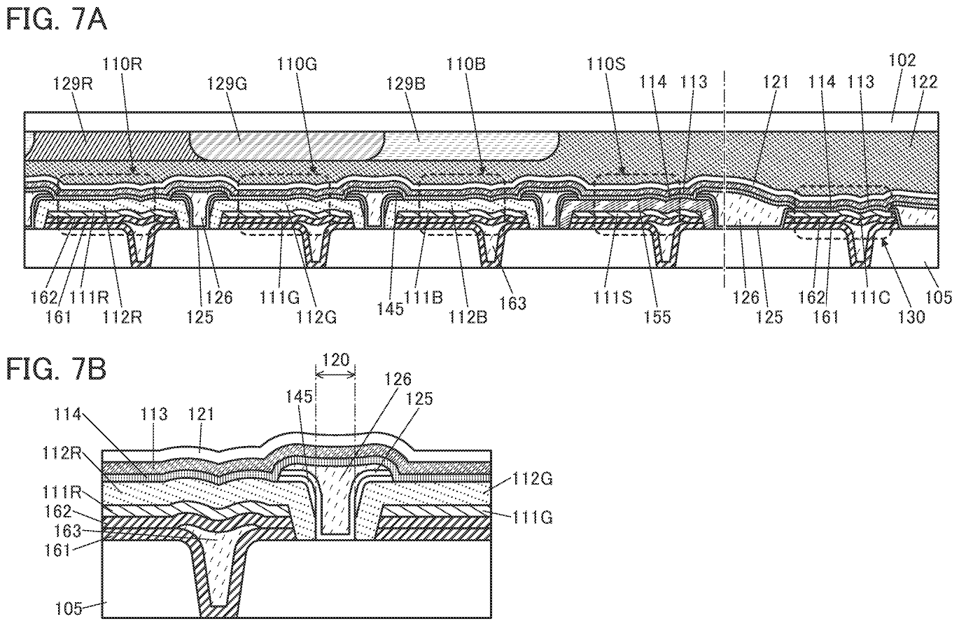

FIG. 7A is a schematic cross-sectional view of a display apparatus described below.

FIG. 7A illustrates a cross section of a region including the light-emitting element 110R, the light-emitting element 110G, the light-emitting element 110B, the light-receiving element 110S, and the connection portion 130. FIG. 7B is an enlarged schematic cross-sectional view of the slit 120 positioned between the light-emitting element 110R and the light-emitting element 110G and its vicinity.

The light-emitting element 110B includes the pixel electrode 111B, the organic layer 112B, the organic layer 114, and the common electrode 113. The coloring layer 129B is provided to overlap with the light-emitting element 110B. The light-emitting element 110R and the light-emitting element 110G also have the same structure as the light-emitting element 110B. A conductive layer 161, a conductive layer 162, and a resin layer 163 are provided below the pixel electrode 111.

The conductive layer 161 is provided over an insulating layer 105. Here, the insulating layer 105 is provided over the substrate 101, and a wiring, a transistor, an electrode, or the like (not illustrated) is provided over the substrate 101. The conductive layer 161 includes a portion penetrating the insulating layer 105 in an opening provided in the insulating layer 105. The conductive layer 161 functions as a wiring or an electrode electrically connecting the wiring, the transistor, the electrode, or the like (not illustrated), which are positioned below the insulating layer 105, to the pixel electrode 111.

A depressed portion is formed in a portion of the conductive layer 161 that is positioned in the opening of the insulating layer 105. The resin layer 163 is provided to fill the depressed portion and functions as a planarization film. Although the top surface of the resin layer 163 is preferably as flat as possible, its surface has a gently curved surface shape in some cases. Although FIG. 7A and the like illustrate an example in which the top surface of the resin layer 163 has a wave shape with a depressed portion and a projected portion: however, one embodiment of the present invention is not limited thereto. For example, the top surface of the resin layer 163 may be a convex surface, a concave surface, or a flat surface.

The conductive layer 162 is provided over the conductive layer 161 and the resin layer 163. The conductive layer 162 has a function as an electrode electrically connecting the conductive layer 161 and the pixel electrode 111.

Here, in the case where the light-emitting element 110 is a top-emission light-emitting element, a film having a reflective property with respect to visible light is used as the conductive layer 162 and a film having a transmitting property with respect to visible light is used as the pixel electrode 111, whereby the conductive layer 162 can serve as a reflective electrode. Furthermore, the conductive layer 162 and the pixel electrode 111 can also be provided over the opening portion (also referred to as a contact portion) of the insulating layer 105 with the resin layer 163 therebetween: thus, a portion overlapping with the contact portion can also be a light-emitting region. Therefore, the aperture ratio can be increased.

Similarly, in the case where the light-receiving element 110S is a photoelectric conversion element that receives light from above, a film having a reflective property can be used as the conductive layer 162 and a film having a transmitting property can be used as the pixel electrode 111. Furthermore, since the contact portion can also function as a light-receiving region, the light-receiving area is increased and the light-receiving sensitivity can be increased.

In addition, the thicknesses of the pixel electrodes 111 may be different. At this time, the pixel electrode 111 can be used as an optical adjustment layer for microcavity. In the case of using microcavity, a film having a transmitting property and a reflective property is used as the common electrode.

FIG. 7A and FIG. 7B illustrate an example in which the shape of the resin layer 126 is different from that in FIG. 1B and the like.

As illustrated in FIG. 7B, an upper portion of the resin layer 126 has a shape having a larger width than the slit 120. As described later, the insulating layer 125 is processed using the resin layer 126 as an etching mask: thus, part of the insulating layer 125 which is a portion covered with the resin layer 126 remains. Moreover, part of a sacrificial layer 145 used in the manufacturing step of the display apparatus remains for the same reason. Specifically, the sacrificial layer 145 is provided over the organic layer 112 in the vicinity of the slit 120. Part of the insulating layer 125 is provided to cover the top surface of the sacrificial layer 145. In addition, the resin layer 126 is provided to cover the sacrificial layer 145 and the insulating layer 125. Note that in this specification and the like, a sacrificial layer may be referred to as a mask layer.

At that time, the end portion of the insulating layer 125 and the end portion of the sacrificial layer 145 each preferably have a tapered shape. This can improve the step coverage with the organic layer 114 and the like.

### Manufacturing Method Example

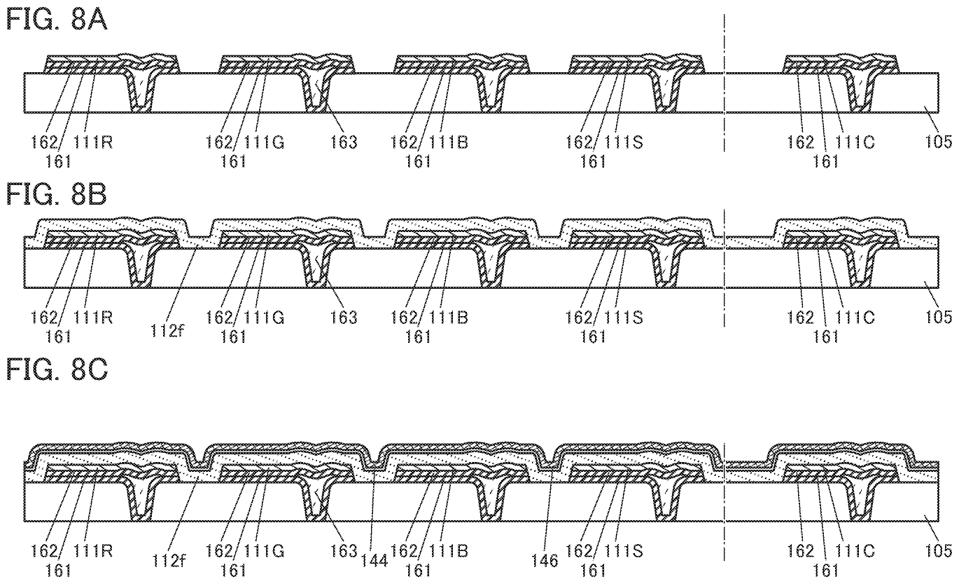

An example of a method for manufacturing the display apparatus of one embodiment of the present invention is described below with reference to drawings. Here, description is made using the display apparatus described in FIG. 7A as an example. FIG. 8A to FIG. 12C are schematic cross-sectional views in steps of the manufacturing method example of the display apparatus described below as an example. In FIG. 8A and the like, the schematic cross-sectional views of the connection portion 130 and the vicinity thereof are also illustrated on the right side.

Note that thin films included in the display apparatus (insulating films, semiconductor films, conductive films, and the like) can be formed by a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD: Plasma Enhanced CVD) method and a thermal CVD method. An example of the thermal CVD method is a metal organic chemical vapor deposition (MOCVD: Metal Organic CVD) method.

Alternatively, thin films included in the display apparatus (insulating films, semiconductor films, conductive films, and the like) can be formed by a method such as spin coating, dipping, spray coating, ink-jetting, dispensing, screen printing, offset printing, a doctor knife method, a slit coater, a roll coater, a curtain coater, and a knife coater.

The thin films included in the display apparatus can be processed by a photolithography method or the like. Besides, a nanoimprinting method, a sandblasting method, a lift-off method, or the like may be used for the processing of the thin films. Alternatively, island-shaped thin films may be directly formed by a film formation method using a shielding mask such as a metal mask.

There are the following two typical methods of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

For light used for light exposure in a photolithography method, for example, it is possible to use light with the i-line (wavelength: 365 nm), light with the g-line (wavelength: 436 nm), light with the h-line (wavelength: 405 nm), or combined light of any of them. Alternatively, ultraviolet light, KrF laser light, ArF laser light, or the like can be used. Light exposure may be performed by liquid immersion exposure technique. For light used for the light exposure, extreme ultraviolet (EUV) light, X-rays, or the like may be used. Furthermore, instead of light used for the light exposure, an electron beam can also be used. It is preferable to use extreme ultraviolet light, X-rays, or an electron beam because extremely minute processing can be performed. Note that a photomask is not necessarily used when light exposure is performed by scanning with a beam such as an electron beam.

For etching of the thin film, a dry etching method, a wet etching method, a sandblast method, or the like can be used.

### [Preparation for Substrate 101]

As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate, an organic resin substrate, or the like can be used. Alternatively, a single crystal semiconductor substrate or a polycrystalline semiconductor substrate using silicon or silicon carbide as a material, a compound semiconductor substrate of silicon germanium or the like, or a semiconductor substrate such as an SOI (Silicon On Insulator) substrate can be used.

As the substrate 101, it is particularly preferable to use the semiconductor substrate or the insulating substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

The insulating layer 105 is provided in the uppermost portion of the substrate 101. The insulating layer 105 includes a plurality of openings reaching a transistor, a wiring, an electrode, and the like provided over the substrate 101. The opening can be formed by a photolithography method.

The insulating layer 105 can be formed using an inorganic insulating material or an organic insulating material.

### [Formation of Conductive Layer 161, Resin Layer 163, Conductive Layer 162, and Pixel Electrode 111]

A conductive film to be the conductive layer 161 is formed over the insulating layer 105. At this time, a depressed portion due to the opening of the insulating layer 105 is formed in the conductive film.

Then, the resin layer 163 is formed in the depressed portion of the conductive film.

It is preferable to use a photosensitive resin for the resin layer 163. At this time, the resin layer 163 can be formed in the following manner: a resin film is formed first, the resin film is exposed to light through a photomask, and then the resin film is subjected to development treatment. After that, in order to adjust the level of the top surface of the resin layer 163, an upper portion of the resin layer 163 may be etched by ashing or the like.

In the case where a non-photosensitive resin is used for the resin layer 163, the resin layer 163 can be formed in the following manner: the resin film is formed, and then an upper portion of the resin film is etched to have an optimum thickness until a surface of the conductive film to be the conductive layer 161 is exposed by ashing or the like.

Next, a conductive film to be the conductive layer 162 over the resin layer 163 and the conductive film to be the conductive layer 161 are formed. Furthermore, a conductive film to be the pixel electrode 111 and the connection electrode 111C is formed over the conductive film to be the conductive layer 162. After that, a resist mask is formed over the three conductive films by a photolithography method, and an unnecessary portion of the conductive film is removed by etching. Then, the resist mask is removed, so that the conductive layer 161, the conductive layer 162, the pixel electrodes 111, and the connection electrode 111C can be formed in the same step (FIG. 8A).

Note that although the conductive layer 161 and the conductive layer 162 are formed using the same photomask in the same step here, the conductive layer 161 and the conductive layer 162 may be separately formed using different photomasks. In this case, it is preferable that the conductive layer 161 and the conductive layer 162 be processed so that the conductive layer 161 is positioned inward from the outline of the conductive layer 162 in a plan view.

The conductive layer 161 and the conductive layer 162 may be formed first, and then, the pixel electrodes 111 and the connection electrode 111C may be formed. In this case, the conductive film to be the pixel electrode 111 and the connection electrode 111C is formed to cover the conductive layer 161 and the conductive layer 162 and part of the conductive film is removed by etching, whereby the pixel electrodes 111 and the connection electrode 111C are formed. Note that at this time, the pixel electrodes 111 and the connection electrode 111C are preferably formed to cover the conductive layer 161 and the conductive layer 162, in which case the conductive layer 161 and the conductive layer 162 are not exposed to an etching atmosphere at the time of the formation of the pixel electrodes 111 and the like.

[Formation of Organic Film 112f]

Next, an organic film 112f is formed to cover the pixel electrodes 111 and the connection electrode 111C (FIG. 8B). The organic film 112f is a film to be processed into the organic layer 112 in a later step and may be formed using the material which can be used for the organic layer 112. The organic film 112f can be suitably formed by a vacuum evaporation method. Without limitation to this, a sputtering method, an inkjet method, or the like can be used for the formation. The above deposition method can be used as appropriate.

Note that although the organic film 112f is provided to cover the connection electrode 111C in FIG. 8B, the present invention is not limited thereto. For example, a mask (also referred to as an area mask, a rough metal mask, or the like to be distinguished from a fine metal mask) may be used for defining a film formation area so that a film formation area of the organic film 112f is limited to the inner side of the connection portion 130 and the organic film 112f does not overlap with the connection electrode 111C. Accordingly, the connection electrode 111C can be prevented from being in contact with the organic film 112f.

The organic film 112f may be formed separately using a fine metal mask. In that case, it is preferable that the organic film 112f only cover the pixel electrodes 111R, 111G, and 111B and do not cover the pixel electrode 111S and the connection electrode 111C. Thus, the pixel electrode 111S and the connection electrode 111C can be prevented from being in contact with the organic film 112f.

### [Formation of Sacrificial Film 144]

Next, a sacrificial film 144 is formed to cover the organic film 112f. Note that in this specification and the like, a sacrificial film may be referred to as a mask film.

As the sacrificial film 144, it is possible to use a film highly resistant to etching treatment performed on the organic layer 112, i.e., a film having high etching selectivity. Moreover, as the sacrificial film 144, it is possible to use a film having high etching selectivity with respect to a sacrificial film such as a sacrificial film 146 described later. Furthermore, as the sacrificial film 144, it is particularly preferable to use a film that can be removed by a wet etching method less likely to cause damage to the organic layer 112.

As the sacrificial film 144, for example, an inorganic film such as a metal film, an alloy film, a metal oxide film, a semiconductor film, or an inorganic insulating film can be suitably used. The sacrificial film 144 can be formed by any of a variety of deposition methods such as a sputtering method, an evaporation method, a CVD method, and an ALD method.

Specifically, the sacrificial film 144, which is directly formed on the organic film 112f, is preferably formed by an ALD method that gives less deposition damage to a formation layer.

For the sacrificial film 144, for example, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver.

Alternatively, for the sacrificial film 144, a metal oxide such as an indium gallium zinc oxide (In—Ga—Zn oxide, also referred to as IGZO) can be used. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon, or the like can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) can be employed instead of gallium.

Alternatively, for the sacrificial film 144, oxide such as aluminum oxide, hafnium oxide, or silicon oxide, nitride such as silicon nitride or aluminum nitride, or oxynitride such as silicon oxynitride can be used. Such an inorganic insulating material can be formed by a deposition method such as a sputtering method, a CVD method, or an ALD method.

An organic material may be used for the sacrificial film 144. For example, as the organic material, a material that can be dissolved in a solvent chemically stable with respect to the organic film 112f may be used. Specifically, a material that can be dissolved in water or alcohol can be suitably used for the sacrificial film 144. In formation of the sacrificial film 144, it is preferable that application of such a material dissolved in a solvent such as water or alcohol be performed by a wet film formation method and then heat treatment for evaporating the solvent be performed. In that case, the heat treatment is preferably performed in a reduced-pressure atmosphere, in which case the solvent can be removed at a low temperature in a short time, so that thermal damage to the EL layer can be reduced.

Examples of the wet film formation methods that can be used for formation of the sacrificial film 144 include spin coating, dipping, spray coating, ink-jetting, dispensing, screen printing, offset printing, a doctor knife method, slit coating, roll coating, curtain coating, and knife coating.

For the sacrificial film 144, an organic resin such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used. For the sacrificial film 144, a fluorine resin such as a perfluoropolymer may be used.

### [Formation of Sacrificial Film 146]

Next, the sacrificial film 146 is formed over the sacrificial film 144 (FIG. 8C).

The sacrificial film 146 is a film used for a hard mask when the sacrificial film 144 is etched later. In a later step of processing the sacrificial film 146, the sacrificial film 144 is exposed. Thus, the combination of films having high etching selectivity therebetween is selected for the sacrificial film 144 and the sacrificial film 146. It is thus possible to select a film that can be used for the sacrificial film 146 depending on an etching condition of the sacrificial film 144 and an etching condition of the sacrificial film 146.

A material of the sacrificial film 146 can be selected from a variety of materials depending on an etching condition of the sacrificial film 144 and an etching condition of the sacrificial film 146. For example, any of the films that can be used for the sacrificial film 144 can be used.

For example, as the sacrificial film 146, an oxide film can be used. Typically, a film of oxide or a film of oxynitride such as silicon oxide, silicon oxynitride, aluminum oxide, aluminum oxynitride, hafnium oxide, or hafnium oxynitride can also be used.

As the sacrificial film 146, a film of nitride can be used, for example. Specifically, it is possible to use nitride such as silicon nitride, aluminum nitride, hafnium nitride, titanium nitride, tantalum nitride, tungsten nitride, gallium nitride, or germanium nitride.

For example, it is preferable that an inorganic insulating material such as aluminum oxide, hafnium oxide, or silicon oxide formed by an ALD method be used for the sacrificial film 144, and a metal oxide containing indium such as IGZO formed by a sputtering method be used for the sacrificial film 146. Alternatively, it is preferable to use a metal such as tungsten, molybdenum, copper, aluminum, titanium, or tantalum or an alloy containing the metal for the sacrificial film 146.

For example, it is possible to use an organic film (e.g., a PVA film) formed by any of an evaporation method and the above-described wet film formation method as the sacrificial film 144, and an inorganic film (e.g., a silicon oxide film or a silicon nitride film) formed by a sputtering method as the sacrificial film 146.

Alternatively, as the sacrificial film 146, an organic film that can be used for the organic layer 112 and the like may be used. For example, the same film as the organic film that is used for the organic layer 112 can be used as the sacrificial film 146. The use of such an organic film is preferable, in which case the deposition apparatus for the sacrificial film 146 can be used for the organic layer 112 and the like. In addition, when the organic layer 112 and the like are etched using a layer to be a sacrificial layer as a mask, the organic film can be removed at the same time, so that the step can be simplified. [Formation of resist mask 143]

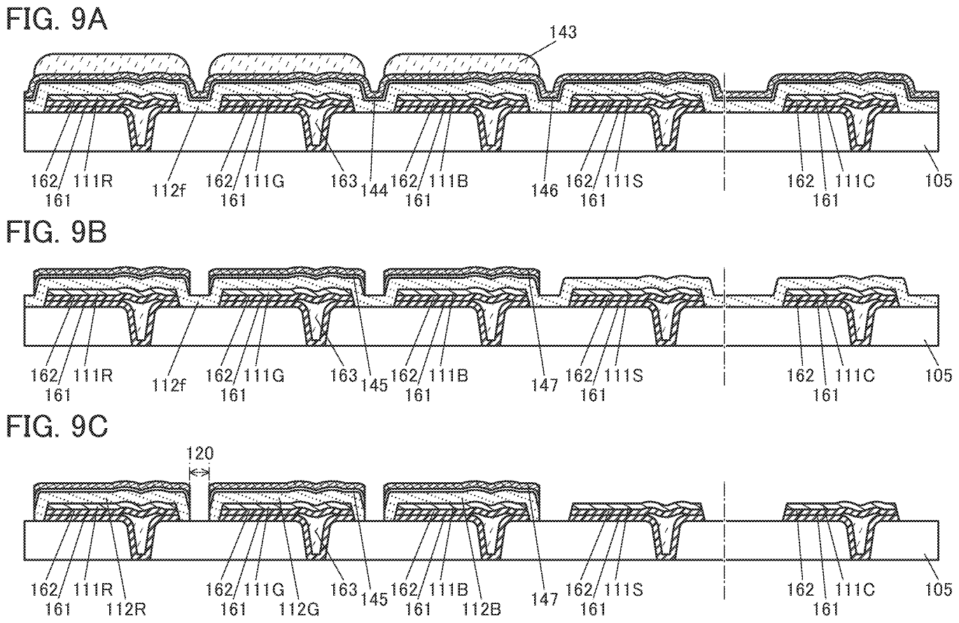

Then, over the sacrificial film 146, a resist mask 143 is formed in positions overlapping with the pixel electrode 111R, the pixel electrode 111G, and the pixel electrode 111B (FIG. 9A). At this time, the resist mask is not formed in positions overlapping with the pixel electrode 111S and the connection electrode 111C.

For the resist mask 143, a resist material containing a photosensitive resin such as a positive type resist material or a negative type resist material can be used.

Here, in the case where the sacrificial film 146 is not provided and the resist mask 143 is formed over the sacrificial film 144, if a defect such as a pinhole exists in the sacrificial film 144, there is a risk of dissolving the organic film 112f and the like due to a solvent of the resist material. Such a defect can be prevented by using the sacrificial film 146.

Note that in the case where a material which does not dissolve the organic film 112f is used for a solvent of the resist material, for example, the resist mask 143 may be formed directly over the sacrificial film 144 without using the sacrificial film 146 in some cases.

[Etching of sacrificial film 146]

Next, part of the sacrificial film 146 that is not covered by the resist mask 143 is removed by etching, so that a sacrificial layer 147 having an island shape is formed.

In the etching of the sacrificial film 146, an etching condition with high selectivity is preferably employed so that the sacrificial film 144 is not removed by the etching. Either wet etching or dry etching can be performed for the etching of the sacrificial film 146; with use of dry etching, a reduction in a pattern of the sacrificial layer 147 can be inhibited.

### [Removal of Resist Mask 143]

Next, the resist mask 143 is removed.

The removal of the resist mask 143 can be performed by wet etching or dry etching. It is particularly preferable to perform dry etching (also referred to as plasma ashing) using an oxygen gas as an etching gas to remove the resist mask 143.

In that case, the removal of the resist mask 143 is performed in a state where the organic film 112f is covered by the sacrificial film 144; thus, the organic film 112f is less likely to be affected by the removal. This is particularly suitable in the case where etching using an oxygen gas, such as plasma ashing, is performed because the electrical characteristics might be adversely affected when the EL film 112f is exposed to oxygen. Even in the case where the resist mask 143 is removed by wet etching, the organic film 112f can be prevented from being dissolved because the organic film 112f is not exposed to a chemical solution.

### [Etching of Sacrificial Film 144]

Next, part of the sacrificial film 144 is removed by etching with use of the sacrificial layer 147 as a hard mask, so that the sacrificial layer 145 having an island shape is formed (FIG. 9B)

Either wet etching or dry etching can be performed for the etching of the sacrificial film 144; the use of dry etching is preferable, in which case a reduction in a pattern can be inhibited.

[Etching of Organic Film 112f]

Then, part of the organic film 112f, which is not covered with the sacrificial layer 145, is removed by etching, so that the organic layer 112R, the organic layer 112G, and the organic layer 112B each having an island shape are formed (FIG. 9C). The slit 120 is formed between the organic layers 112. At that time, the top surfaces of the pixel electrode 111S and the connection electrode 111C are exposed at the same time.

Specifically, for the etching of the organic film 112f, it is preferable to perform dry etching using an etching gas that does not contain oxygen as its main component. This can inhibit the alteration of the organic film 112f to achieve a highly reliable display apparatus. Examples of the etching gas that does not contain oxygen as its main component include CF₄, CAF₈, SF₆, CHF₃, Cl₂, H₂O, BCl₃, H₂, and a noble gas such as He. Alternatively, a mixed gas of the above gas and a dilute gas that does not contain oxygen can be used for the etching gas.

Note that etching of the organic film 112f is not limited to the above and may be performed by dry etching using another gas or wet etching.

In addition, when dry etching using, as an etching gas, an oxygen gas or a mixed gas containing an oxygen gas is used for the etching of the organic film 112f, the etching rate can be increased. Thus, etching under a low-power condition can be performed while the etching rate is kept adequately high: hence, damage due to the etching can be reduced. Furthermore, a defect such as attachment of a reaction product generated at the etching can be inhibited. For example, a mixed gas obtained by adding an oxygen gas to the etching gas not containing oxygen as its main component can be used as the etching gas.

As described above, the organic layer 112 is processed by a photolithography method, whereby the distance between the pixels isolated by the slit 120 can be shortened to be less than or equal to 8 μm, less than or equal to 3 μm, less than or equal to 2 μm, or less than or equal to 1 μm. The distance between the pixels is shortened in this manner, whereby a display apparatus with high resolution and a high aperture ratio can be provided.

Furthermore, the adjacent organic layers 112 are isolated by the slit 120, in which case the current leakage path between the adjacent organic layers 112 can be cut, whereby the leakage current can be inhibited. Accordingly, a higher luminance, a higher contrast, higher display quality, higher power efficiency, lower power consumption, or the like can be achieved in the light-emitting element.

Through the above-described step, the organic layers 112R, 112G, and 112B corresponding to the light-emitting elements 110R, 110G, and 110B, respectively, can be formed at a time. This reduces the number of patterning times of the organic layer to one third compared to the case where the light-emitting elements of red, green, and blue are separately formed. With the use of the above-described method in such a manner, the manufacturing step can be simplified and the productivity of the display apparatus of one embodiment of the present invention can be improved.

The insulating layer 105 is exposed when the organic film 112f is etched. Accordingly, it is preferable to use a film highly resistant to etching of the organic film 112f for the insulating layer 105. Note that at the time of etching of the organic film 112f, an upper portion of the insulating layer 105 is etched and a portion not covered by the organic layer 112 is thinned in some cases.

[Formation of Organic Film 155f]

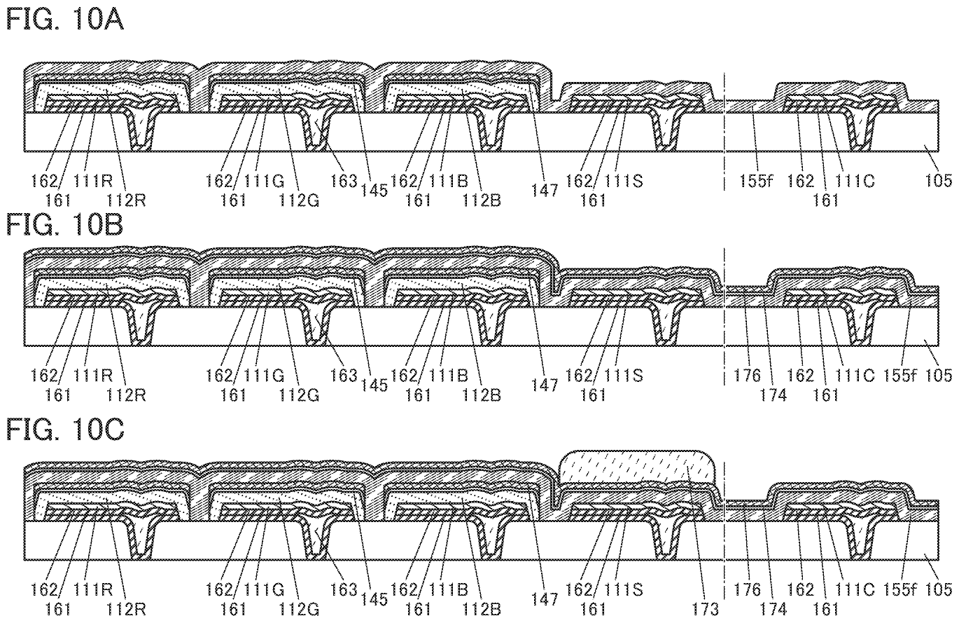

Next, an organic film 155f is formed to cover the pixel electrodes 111 and the connection electrode 111C (FIG. 10A). The organic film 155f is a film to be processed into the organic layer 155 in a later step and may be formed using the material which can be used for the organic layer 155. The organic film 155f can be suitably formed by a vacuum evaporation method. Note that without limitation to this, the organic film 155f can be deposited by a sputtering method, an inkjet method, or the like. The above-described deposition method can be used as appropriate. Here, the sacrificial layer 145 and the sacrificial layer 147 are provided over the organic layer 112, so that the top surface of the organic layer 112 can be prevented from being in contact with the organic film 155f.

Note that an area mask may be used also for the formation of the organic film 155f so that a film formation area of the organic film 155f is limited to the inner side of the connection portion 130 and the organic film 155f does not overlap with the connection electrode 111C. Accordingly, the connection electrode 111C can be prevented from being in contact with the organic film 155f.

### [Formation of Sacrificial Film 174]

Next, a sacrificial film 174 is formed to cover the organic film 155f.

As the sacrificial film 174, it is possible to use a film highly resistant to etching treatment performed on the organic layer 155, i.e., a film having high etching selectivity. Moreover, as the sacrificial film 174, it is possible to use a film having high etching selectivity with respect to a sacrificial film such as a sacrificial film 176 described later. Furthermore, as the sacrificial film 174, it is particularly preferable to use a film that can be removed by a wet etching method less likely to cause damage to the organic layer 155.

For the sacrificial film 174, the above-described materials that can be used for the sacrificial film 144 can be suitably used. The sacrificial film 174 can be formed by any of a variety of deposition methods such as a sputtering method, an evaporation method, a CVD method, and an ALD method. Specifically, the sacrificial film 174, which is directly formed on the organic film 155f, is preferably formed by an ALD method that gives less deposition damage to a formation layer.

### [Formation of Sacrificial Film 176]

Next, the sacrificial film 176 is formed over the sacrificial film 174 (FIG. 10B).

The sacrificial film 176 is a film used for a hard mask when the sacrificial film 174 is etched later. In a later step of processing the sacrificial film 176, the sacrificial film 174 is exposed. Thus, the combination of films having high etching selectivity therebetween is selected for the sacrificial film 174 and the sacrificial film 176. It is thus possible to select a film that can be used for the sacrificial film 176 depending on an etching condition of the sacrificial film 174 and an etching condition of the sacrificial film 176.

A material of the sacrificial film 176 can be selected from a variety of materials depending on an etching condition of the sacrificial film 174 and an etching condition of the sacrificial film 176. For example, any of the films that can be used for the sacrificial film 144 can be used.

For example, it is preferable that an inorganic insulating material such as aluminum oxide, hafnium oxide, or silicon oxide formed by an ALD method be used for the sacrificial film 174, and a metal oxide containing indium such as IGZO formed by a sputtering method be used for the sacrificial film 176. Alternatively, it is preferable to use a metal such as tungsten, molybdenum, copper, aluminum, titanium, or tantalum or an alloy containing the metal for the sacrificial film 176.

### [Formation of Resist Mask 173]

Then, a resist mask 173 is formed over the sacrificial film 176 in a position overlapping with the pixel electrode 111S (FIG. 10C). At this time, the resist mask is not formed in positions overlapping with the pixel electrodes 111R, 111G, and 111B, and the connection electrode 111C.

The resist mask 173 can be formed using the material that can be used for the resist mask 143.

### [Etching of Sacrificial Film 176]

Next, part of the sacrificial film 176 that is not covered with the resist mask 173 is removed by etching, so that a sacrificial layer 177 having an island shape is formed.

In the etching of the sacrificial film 176, an etching condition with high selectivity is preferably employed so that the sacrificial film 174 is not removed by the etching. Either wet etching or dry etching can be performed for the etching of the sacrificial film 176; with use of dry etching, a reduction in a pattern of the sacrificial layer 177 can be inhibited.

### [Removal of Resist Mask 173]

Then, the resist mask 173 is removed. The removal of the resist mask 173 can be performed in a manner similar to the removal of the resist mask 143.

### [Etching of Sacrificial Film 174]

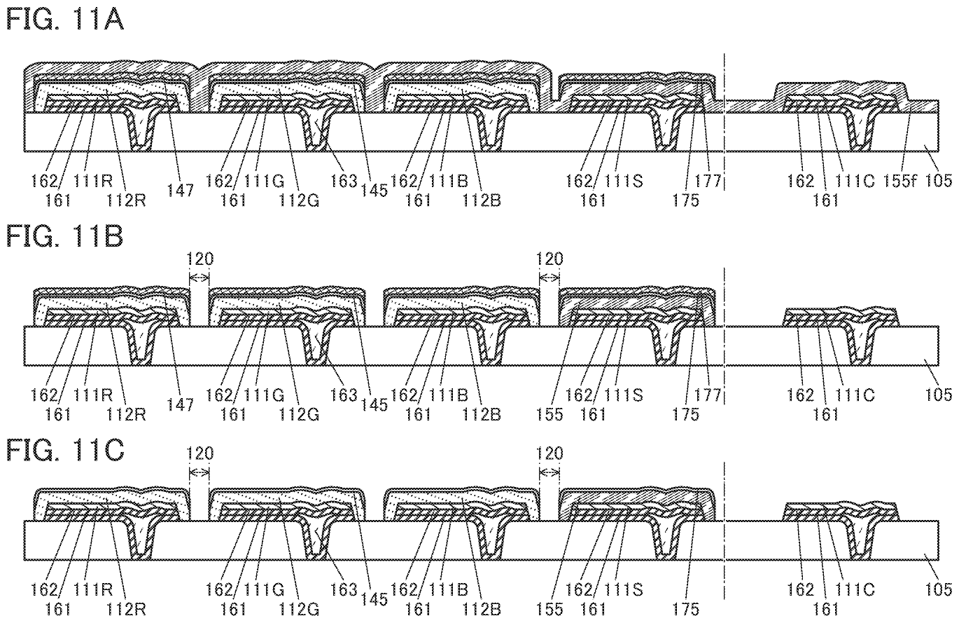

Next, part of the sacrificial film 174 is removed by etching with use of the sacrificial layer 177 as a hard mask, so that a sacrificial layer 175 having an island shape is formed (FIG. 11A).

Either wet etching or dry etching can be performed for the etching of the sacrificial film 174; the use of dry etching is preferable, in which case a reduction in a pattern can be inhibited.

[Etching of Organic Film 155f]

Then, part of the organic film 155f that is not covered with the sacrificial layer 175 is removed by etching, so that the organic layer 155 having an island shape is formed (FIG. 11B). The slit 120 is formed between the organic layer 155 and the organic layer 112. At this time, the top surfaces of the sacrificial layer 147 and the connection electrode 111C are exposed at the same time.

The etching of the organic film 155f can be performed in a manner similar to that of the organic film 112f.

As described above, the organic layers 112 and the organic layer 155 are processed by a photolithography method, whereby the distance between the pixels isolated by the slit 120 can be shortened to be less than or equal to 8 μm, less than or equal to 3 μm, less than or equal to 2 μm, or less than or equal to 1 μm. The distance between the pixels is shortened in this manner, whereby a display apparatus with high resolution and a high aperture ratio can be provided.

Furthermore, the organic layer 112 and the organic layer 155 are isolated by the slit 120, in which case a current leakage path between the organic layer 112 and the organic layer 155 adjacent to each other can be cut. Accordingly, the leakage current between the organic layer 112 and the organic layer 155 is inhibited, whereby high-accuracy image capturing with a high signal-noise ratio (S/N ratio) can be performed. Therefore, a clear image can be captured even with weak light. Thus, the luminance of the light-emitting element used as a light source can be reduced in image capturing, leading to a reduction in power consumption.

Through the above-described step, patterning of the organic layer can be twice in the display apparatus in which the light-emitting element and the light-receiving element are included. With the use of the above-described method in such a manner, the manufacturing step can be simplified and the productivity of the display apparatus of one embodiment of the present invention can be improved.

The insulating layer 105 is exposed when the organic film 155f is etched. Accordingly, it is preferable to use a film highly resistant to etching of the organic film 155f for the insulating layer 105. Note that at the time of etching of the organic film 155f, the upper portion of the insulating layer 105 is etched and a portion not covered by the organic layer 155 is thinned in some cases.

### [Removal of Sacrificial Layer]

Next, the sacrificial layer 147 and the sacrificial layer 177 are removed, so that the top surfaces of the sacrificial layer 145 and the sacrificial layer 175 are exposed (FIG. 11C). At this time, the sacrificial layer 145 and the sacrificial layer 175 preferably remains. Note that the sacrificial layer 147 and the sacrificial layer 177 are not necessarily removed at this time.

[Formation of Insulating Film 125f]

Subsequently, an insulating film 125f is formed to cover the sacrificial layer 145, the sacrificial layer 175, and the slit 120.

The insulating film 125f functions as a barrier layer that prevents diffusion of impurities such as water into the EL layer and the PD layer. The insulating film 125f is preferably formed by an ALD method with excellent step coverage, in which case the side surfaces of the EL layer can be suitably covered.

It is preferable that the insulating film 125f be formed using the same film as the sacrificial layer 145 and the sacrificial layer 175 because they can be etched at the same time in a later step. For example, an inorganic insulating material such as aluminum oxide, hafnium oxide, or silicon oxide, which is formed by an ALD method, is preferably used for the insulating film 125f, the sacrificial layer 145, and the sacrificial layer 175.

Note that the materials that can be used for the insulating film 125f are not limited to this, and the above-described materials that can be used for the sacrificial film 144 can be used as appropriate.

[Formation of resin layer 126]

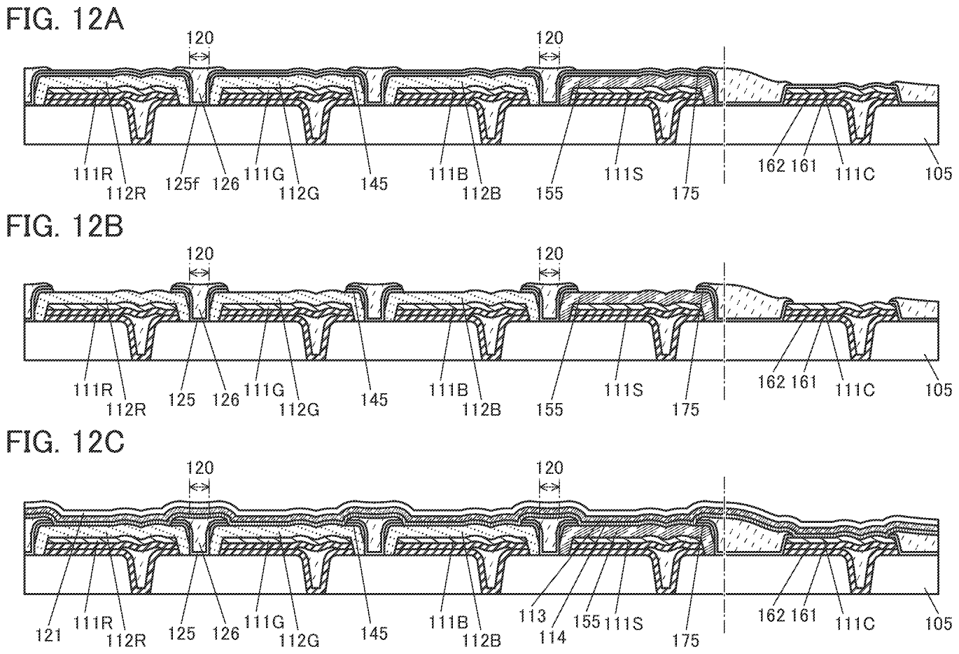

Next, the resin layer 126 is formed in a region overlapping with the slit 120 (FIG. 12A). The resin layer 126 can be formed in a manner similar to that of the resin layer 163. For example, the resin layer 126 can be formed by performing light exposure and development after a photosensitive resin is formed. The resin layer 126 may be formed by etching part of the resin by ashing or the like after the resin is formed over the entire surface.

Here, an example in which the resin layer 126 is formed to have a larger width than the slit 120 is illustrated. Note that the resin layer 126 is provided not to cover the connection electrode 111C.

### [Etching of Insulating Film 125f, Sacrificial Layer 145, and Sacrificial Layer 175]

Next, portions of the insulating film 125f, the sacrificial layer 145, and the sacrificial layer 175 not covered with the resin layer 126 are removed by etching to expose the top surfaces of the organic layers 112 and the top surface of the organic layer 155. In this manner, the insulating layer 125 and the sacrificial layer 145 or the sacrificial layer 175 are formed in a region covered with the resin layer 126 (FIG. 12B).

The etching of the insulating film 125f, the sacrificial layer 145, and the sacrificial layer 175 are preferably performed in the same step. It is particularly preferable that the etching of the sacrificial layer 145 and the sacrificial layer 175 be performed by wet etching that gives less etching damage to the organic layers 112 and the organic layer 155. For example, wet etching using an aqueous solution of tetramethylammonium hydroxide (TMAH), diluted hydrofluoric acid, oxalic acid, phosphoric acid, acetic acid, nitric acid, or a mixed solution of any of these acids is preferably performed.

Alternatively, at least one of the sacrificial film 125f, the sacrificial layer 145, and the sacrificial layer 175 are preferably removed by being dissolved in a solvent such as water or alcohol. For the alcohol in which the sacrificial film 125f, the sacrificial layer 145, and the sacrificial layer 175 can be dissolved, any of various alcohols such as ethyl alcohol, methyl alcohol, isopropyl alcohol (IPA), and glycerin can be used.

After the sacrificial film 125f, the sacrificial layer 145, and the sacrificial layer 175 are removed, drying treatment is preferably performed to remove water contained in the organic layers 112, the organic layer 155, and the like and water adsorbed on the surfaces thereof. For example, heat treatment is preferably performed in an inert gas atmosphere or a reduced-pressure atmosphere. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

The insulating film 125f, the sacrificial layer 145, and the sacrificial layer 175 are removed, so that the top surface of the connection electrode 111C is also exposed.

### [Formation of Organic Layer 114]

Next, the organic layer 114 is formed to cover the organic layers 112, the organic layer 155, the insulating layer 125, the sacrificial layer 145, the sacrificial layer 175, the resin layer 126, and the like.

The organic layer 114 can be formed in a manner similar to that of the organic film 112f or the like. In the case where the organic layer 114 is formed by an evaporation method, the organic layer 114 may be formed using an area mask so as not to be formed over the connection electrode 111C.

### [Formation of Common Electrode 113]

Then, the common electrode 113 is formed to cover the organic layer 114.

The common electrode 113 can be formed by a deposition method such as an evaporation method or a sputtering method. Alternatively, a film formed by an evaporation method and a film formed by a sputtering method may be stacked.

The common electrode 113 is preferably formed so as to cover a region where the organic layer 114 is formed. That is, a structure in which the end portion of the organic layer 114 overlaps with the common electrode 113 can be obtained. The common electrode 113 may be formed using an area mask.

FIG. 12C illustrates an example in which the organic layer 114 is sandwiched between the connection electrode 111C and the common electrode 113 in the connection portion 130. In this case, for the organic layer 114, a material with as low electric resistance as possible is preferably used. Alternatively, it is preferable to form the organic layer 114 as thin as possible, in which case the electric resistance of the organic layer 114 in the thickness direction is reduced. For example, when a material which has an electron-injection property or a hole-injection property and whose thickness is greater than or equal to 1 nm and less than or equal to 5 nm, preferably greater than or equal to 1 nm and less than or equal to 3 nm is used for the organic layer 114, the electric resistance between the connection electrode 111C and the common electrode 113 can be made small enough to be negligible in some cases.

### [Formation of Protective Layer]

Next, the protective layer 121 is formed over the common electrode 113 (FIG. 12C). An inorganic insulating film used for the protective layer 121 is preferably deposited by a sputtering method, a PECVD method, or an ALD method. Specifically, an ALD method is preferable because it provides excellent step coverage and is less likely to cause a defect such as a pinhole. An organic insulating film is preferably deposited by an inkjet method because a uniform film can be formed in a desired area.

### [Formation of Counter Substrate]

Then, the substrate 102 is attached onto the protective layer 121 using the resin layer 122. Here, the substrate 102 is provided with the coloring layers 129R, 129G, and 129B, and attachment is performed such that the coloring layers 129R, 129G, and 129B overlap with the pixel electrodes 111R, 111G, and 111B, respectively.

Each of the coloring layers 129R, 129G, and 129B can be formed in a desired position by an ink-jet method, an etching method using a photolithography method, or the like. Specifically, a different coloring layer 129 (the coloring layer 129R, the coloring layer 129G, or the coloring layer 129B) can be formed for each pixel.

Through the above-described steps, the display apparatus illustrated in FIG. 7A can be manufactured.

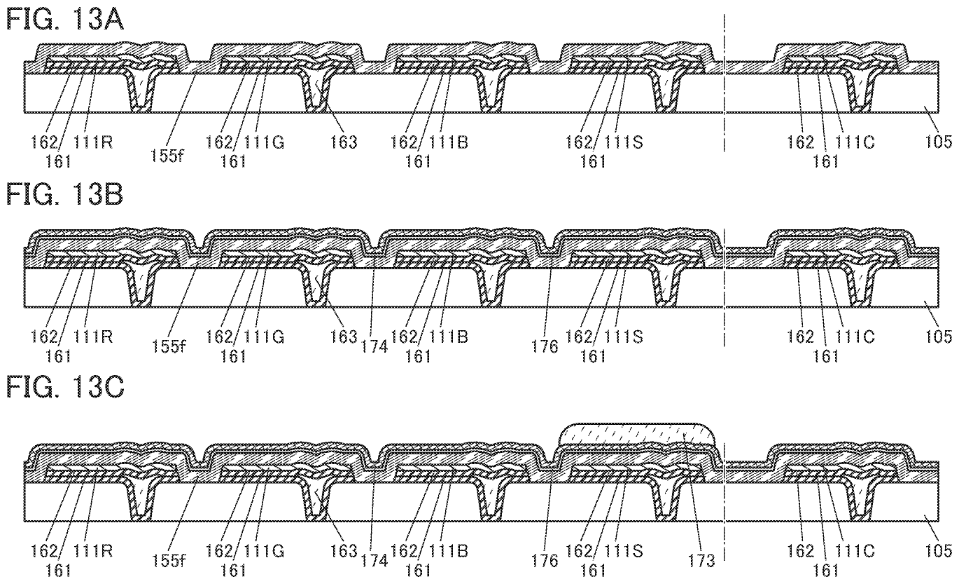

Although the organic layer 112 and the organic layer 155 are formed in this order here, the formation order is not limited thereto. As illustrated in FIG. 13A to FIG. 15C, a structure in which the organic layer 155 and the organic layer 112 are formed in this order may be employed. A method for forming the organic layer 155 and the organic layer 112 in this order is described below.

The pixel electrodes are formed as illustrated in FIG. 8A, and the organic film 155f is formed to cover the pixel electrodes 111R, 111G, 111B, and 111S, and the connection electrode 111C (FIG. 13A). The description of FIG. 10A can be referred to for the formation of the organic film 155f.

Next, the sacrificial film 174 is formed to cover the organic film 155f. After that, the sacrificial film 176 is formed over the sacrificial film 174 (FIG. 13B). The description of FIG. 10B can be referred to for the formation of the sacrificial film 174 and the sacrificial film 176. Then, the resist mask 173 is formed in a position that is over the sacrificial film 176 and overlaps with the pixel electrode 111S (FIG. 13C). The description of FIG. 10C can be referred to for the formation of the resist mask 173.

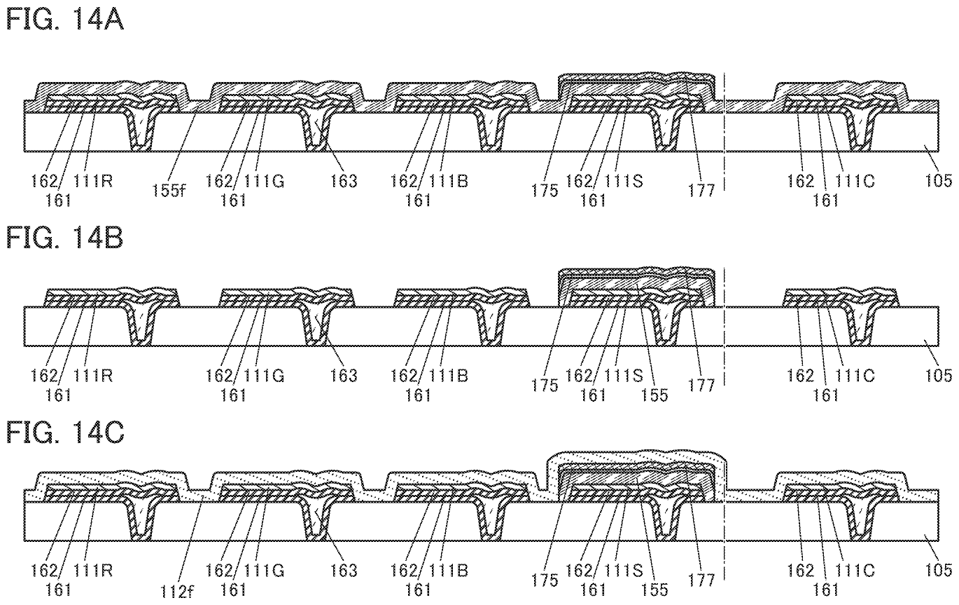

Next, part of the sacrificial film 176 that is not covered with the resist mask 173 is removed by etching, so that the sacrificial layer 177 is formed. Then, the resist mask 173 is removed. After that, part of the sacrificial film 174 is removed by etching with use of the sacrificial layer 177 as a hard mask, so that the sacrificial layer 175 is formed (FIG. 14A). The description of FIG. 11A can be referred to for the formation of the sacrificial layer 177 and the sacrificial layer 175.

Then, part of the organic film 155f that is not covered with the sacrificial layer 175 is removed by etching, so that the organic layer 155 is formed (FIG. 14B). The description of FIG. 11B can be referred to for the formation of the organic layer 155.

Subsequently, the organic film 112f is formed to cover the pixel electrodes 111R, 111G, and 111B, the sacrificial layer 177, and the connection electrode 111C (FIG. 14C). The description of FIG. 8B can be referred to for the formation of the organic film 112f.

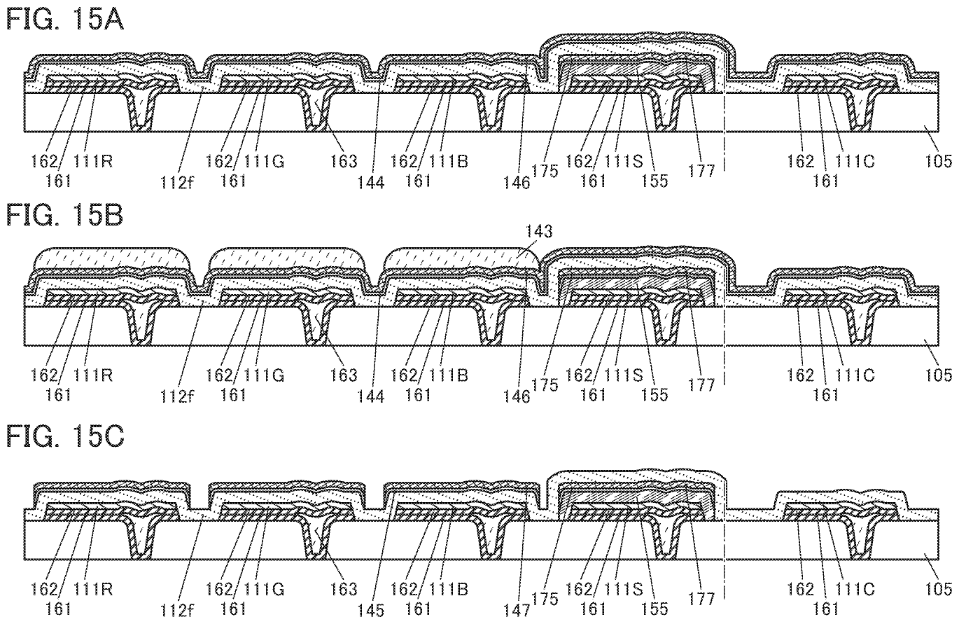

Next, the sacrificial film 144 is formed to cover the organic film 112f. After that, the sacrificial film 146 is formed over the sacrificial film 144 (FIG. 15A). The description of FIG. 10C can be referred to for the formation of the sacrificial film 144 and the sacrificial film 146.

Then, the resist mask 143 is formed in positions that are over the sacrificial film 146 and overlap with the pixel electrodes 111R, 111G, and 111B (FIG. 15B). The description of FIG. 9A can be referred to for the formation of the resist mask 143.

Next, part of the sacrificial film 146 that is not covered with the resist mask 143 is removed by etching, so that the sacrificial layer 147 is formed. Then, the resist mask 143 is removed. After that, part of the sacrificial film 144 is removed by etching with use of the sacrificial layer 147 as a hard mask, so that the sacrificial layer 145 is formed (FIG. 15C). The description of FIG. 9B can be referred to for the formation of the sacrificial layer 147 and the sacrificial layer 145.

Subsequently, part of the organic film 112f which is not covered with the sacrificial layer 145 is removed by etching, so that the organic layers 112R, 112G, and 112B are formed. The description of FIG. 9C can be referred to for the formation of the organic layers 112R, 112G, and 112B. In this manner, a structure similar to the display apparatus illustrated in FIG. 11B can be formed. Hereinafter, a process similar to that in FIG. 11C and the following process is performed, in which case the display apparatus illustrated in FIG. 7A can be manufactured.

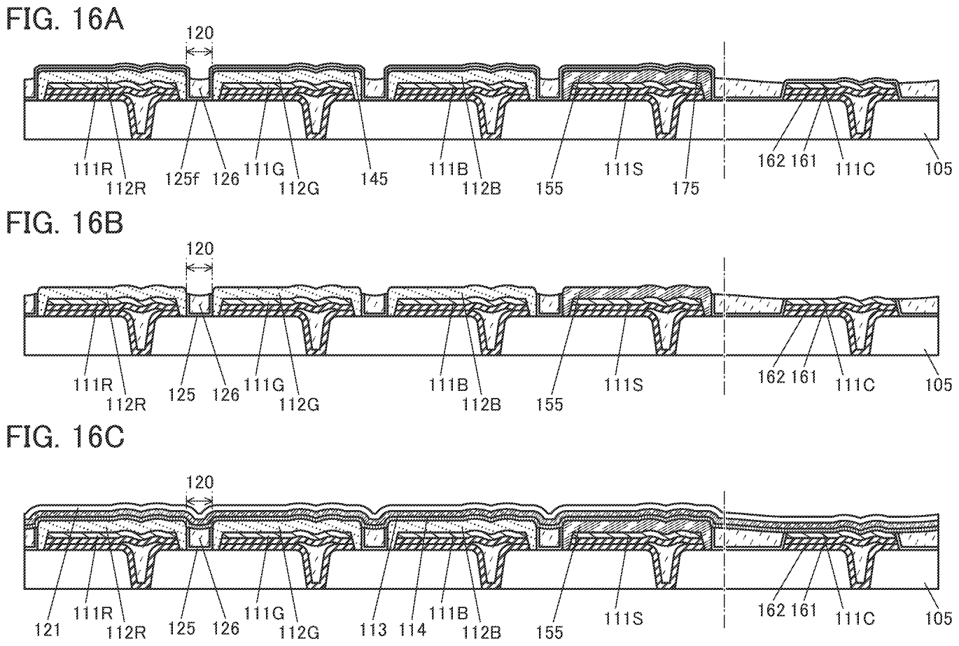

Although the case where the resin layer 126 is formed to have a larger width than the slit 120 is described above, the resin layer 126 may be formed to have the same width as the slit 120. FIG. 16A is a schematic cross-sectional view at the time when the resin layer 126 is formed after the insulating film 125f is formed.

For example, as illustrated in FIG. 12A, the resin layer 126 having a larger width than the slit 120 is formed and then the upper portion of the resin layer 126 is etched by ashing or the like, whereby the resin layer 126 can be formed only inside the slit 120. In that case, it is preferable that the levels of the top surface of the resin layer 126 and the top surface of the adjacent organic layer 112 or organic layer 155 be as close as possible to each other. Accordingly, the steps at both ends of a portion overlapping with the slit 120 can be reduced: thus, the step coverage with the organic layer 112 or the organic layer 155 can be improved.

Subsequently, the insulating film 125f, the sacrificial layer 145, and the sacrificial layer 175 are etched in a manner similar to the above (FIG. 16B). At this time, there is no portion where the sacrificial layer 145 and the sacrificial layer 175 are covered with the resin layer 126; thus, the sacrificial layer 145 and the sacrificial layer 175 are removed without leaving a cut piece.

Then, the organic layer 114, the common electrode 113, and the protective layer 121 are formed in a method similar to the above (FIG. 16C). Furthermore, the substrate 102 is attached thereto by a method similar to the above, whereby the display apparatus can be manufactured.

The above is the description of the example of the method for manufacturing the display apparatus.

At least part of this embodiment can be implemented in combination with the other embodiments described in this specification as appropriate.

### Embodiment 2

In this embodiment, a structure example of a display apparatus of one embodiment of the present invention will be described. Although a display apparatus capable of displaying an image is described here, when a light-emitting element is used as a light source, the display apparatus can be used as a display apparatus.

The display apparatus of this embodiment can be a high-definition display apparatus or a large-sized display apparatus. Accordingly, the display apparatus of this embodiment can also be used for display portions of electronic devices such as a digital camera, a digital video camera, a digital photo frame, a mobile phone, a portable game console, a smart phone, a wristwatch terminal, a tablet terminal, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### [Display Apparatus 400]

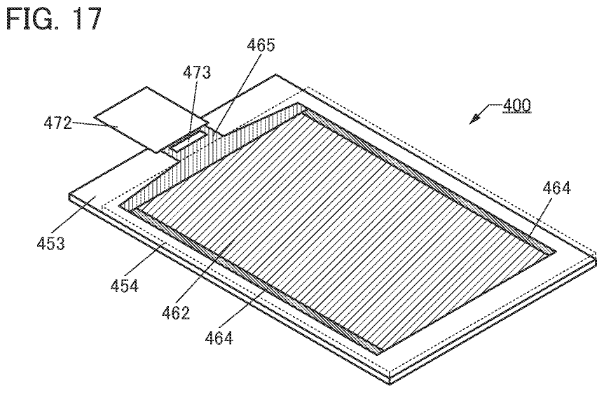

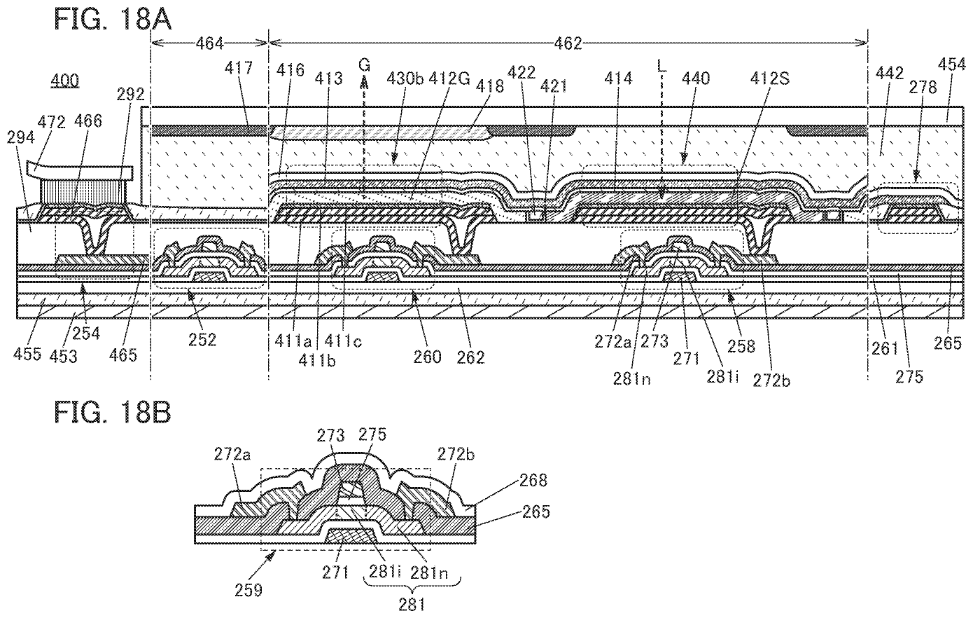

FIG. 17 is a perspective view of a display apparatus 400, and FIG. 18A is a cross-sectional view of the display apparatus 400.

The display apparatus 400 has a structure in which a substrate 454 and a substrate 453 are attached to each other. In FIG. 17, the substrate 454 is denoted by a dashed line.

The display apparatus 400 includes a display portion 462, a circuit 464, a wiring 465, and the like. FIG. 17 illustrates an example in which an IC 473 and an FPC 472 are integrated on the display apparatus 400. Thus, the structure illustrated in FIG. 18 can be regarded as a display module including the display apparatus 400, the IC (integrated circuit), and the FPC.

For the circuit 464, for example, a scan line driver circuit can be used.

The wiring 465 has a function of supplying a signal and electric power to the display portion 462 and the circuit 464. The signal and electric power are input to the wiring 465 from the outside through the FPC 472 or input to the wiring 465 from the IC 473.

FIG. 17 illustrates an example in which the IC 473 is provided over the substrate 453 by a COG (Chip On Glass) method, a COF (Chip On Film) method, or the like. An IC including a scan line driver circuit, a signal line driver circuit, or the like can be used as the IC 473, for example. Note that the display apparatus 400 and the display module are not necessarily provided with an IC. The IC may be mounted on the FPC by a COF method or the like.

FIG. 18A illustrates an example of cross sections of part of a region including the FPC 472, part of the circuit 464, part of the display portion 462, and part of a region including a connection portion in the display apparatus 400. FIG. 18A specifically illustrates an example of a cross section of a region including a light-emitting element 430b that emits green light (G) and a light-receiving element 440 that receives reflected light (L) of the display portion 462.

The display apparatus 400 illustrated in FIG. 18A includes a transistor 252, a transistor 260, a transistor 258, the light-emitting element 430b, a coloring layer 418, the light-receiving element 440, and the like between the substrate 453 and the substrate 454.

Here, the light-emitting element 110G described in Embodiment 1 can be used as the light-emitting element 430b, the coloring layer 129G described in Embodiment 1 can be used as the coloring layer 418, and the light-receiving element 110S described in Embodiment 1 can be used as the light-receiving element 440. Although the light-emitting elements corresponding to the light-emitting elements 110R, 110B, and the like are not illustrated in FIG. 18A, the light-emitting elements can be provided like the light-emitting element 430b. Although the coloring layers corresponding to the coloring layers 129R, 129B, and the like are not illustrated in FIG. 18A, the coloring layers can be provided like the coloring layer 418.

Here, in the case where the pixel of the display apparatus includes three kinds of subpixels including coloring layers that transmit light of different colors, as the three subpixels, subpixels of three colors of red (R), green (G), and blue (B), subpixels of three colors of yellow (Y), cyan (C), and magenta (M) can be given, for example. In the case where four subpixels are included, as the four subpixels, subpixels of four colors of R, G, B, and white (W), subpixels of four colors of R, G, B, and Y can be given, for example.

As the light-receiving element 440, a photoelectric conversion element having sensitivity to light in a red, green, or blue wavelength range or a photoelectric conversion element having sensitivity to light in an infrared wavelength range can be used.

The substrate 454 and a protective layer 416 are attached to each other with an adhesive layer 442. The adhesive layer 442 is provided so as to overlap with each of the light-emitting element 430b and the light-receiving element 440, and the display apparatus 400 employs a solid sealing structure. The substrate 454 is provided with a light-blocking layer 417.

The light-emitting element 430b and the light-receiving element 440 each include a conductive layer 411a, a conductive layer 411b, and a conductive layer 411c as pixel electrodes. The conductive layer 411b has a reflective property with respect to visible light and functions as a reflective electrode. The conductive layer 411c has a transmitting property with respect to visible light and functions as an optical adjustment layer. A common electrode 413 also has a transmitting property with respect to visible light.

The conductive layer 411a included in the light-emitting element 430b is connected to a conductive layer 272b included in the transistor 260 through an opening provided in an insulating layer 294. The transistor 260 has a function of controlling the driving of the light-emitting element. In contrast, the conductive layer 411a included in the light-receiving element 440 is electrically connected to the conductive layer 272b included in the transistor 258. The transistor 258 has a function of controlling the timing of light exposure using the light-receiving element 440.

An EL layer 412G or a PD layer 412S is provided to cover the pixel electrode. An insulating layer 421 is provided in contact with the side surface of the EL layer 412G and the side surface of the PD layer 412S, and a resin layer 422 is provided to fill a depressed portion of the insulating layer 421. An organic layer 414, the common electrode 413, and the protective layer 416 are provided to cover the EL layer 412G and the PD layer 412S. With the protective layer 416 covering the light-emitting element, entry of impurities such as water into the light-emitting element can be inhibited, leading to an increase in the reliability of the light-emitting element.

Light G emitted from the light-emitting element 430b passes through the coloring layer 418 and is emitted toward the substrate 454 side. The light-receiving element 440 receives light L incident through the substrate 454 and converts the light L into an electric signal. Here, the light L also includes light that is the light G reflected outside the substrate 454. For the substrate 454, a material having a high transmitting property with respect to visible light is preferably used.

The transistor 252, the transistor 260, and the transistor 258 are all formed over the substrate 453. These transistors can be manufactured using the same material in the same step.

Note that the transistor 252, the transistor 260, and the transistor 258 may be separately formed to have different structures. For example, it is possible to separately form a transistor having a back gate and a transistor having no back gate, or transistors having semiconductors, gate electrodes, gate insulating layers, source electrodes, and drain electrodes that are formed of different materials and/or have different thicknesses.

The substrate 453 and an insulating layer 262 are attached to each other with an adhesive layer 455.

In a manufacturing method of the display apparatus 400, first, a formation substrate provided with the insulating layer 262, the transistors, the light-emitting elements, the light-receiving element, and the like is attached to the substrate 454 provided with the light-blocking layer 417 with the adhesive layer 442. Then, the substrate 453 is attached to a surface exposed by separation of the formation substrate, whereby the components formed over the formation substrate are transferred onto the substrate 453. The substrate 453 and the substrate 454 preferably have flexibility. This can increase the flexibility of the display apparatus 400.

A connection portion 254 is provided in a region of the substrate 453 that does not overlap with the substrate 454. In the connection portion 254, the wiring 465 is electrically connected to the FPC 472 through a conductive layer 466 and a connection layer 292. The conductive layer 466 can be obtained by processing the same conductive film as the pixel electrode. Thus, the connection portion 254 and the FPC 472 can be electrically connected to each other through the connection layer 292.

Each of the transistor 252, the transistor 260, and the transistor 258 includes a conductive layer 271 functioning as a gate, an insulating layer 261 functioning as a gate insulating layer, a semiconductor layer 281 including a channel formation region 281i and a pair of low-resistance regions 28 In, a conductive layer 272a connected to one of the pair of low-resistance regions 28 In, the conductive layer 272b connected to the other of the pair of low-resistance regions 28 In, an insulating layer 275 functioning as a gate insulating layer, a conductive layer 273 functioning as a gate, and an insulating layer 265 covering the conductive layer 273. The insulating layer 261 is positioned between the conductive layer 271 and the channel formation region 281i. The insulating layer 275 is positioned between the conductive layer 273 and the channel formation region 281i.

The conductive layer 272a and the conductive layer 272b are connected to the corresponding low-resistance regions 281n through openings provided in the insulating layer 265. One of the conductive layer 272a and the conductive layer 272b functions as a source, and the other functions as a drain.

FIG. 18A illustrates an example in which the insulating layer 275 covers the top surface and the side surface of the semiconductor layer. The conductive layer 272a and the conductive layer 272b are connected to the corresponding low-resistance regions 281n through openings provided in the insulating layer 275 and the insulating layer 265.

Meanwhile, in a transistor 259 illustrated in FIG. 18B, the insulating layer 275 overlaps with the channel formation region 281i of the semiconductor layer 281 and does not overlap with the low-resistance regions 281n. The structure illustrated in FIG. 18B can be manufactured by processing the insulating layer 275 using the conductive layer 273 as a mask, for example. In

FIG. 18B, the insulating layer 265 is provided to cover the insulating layer 275 and the conductive layer 273, and the conductive layer 272a and the conductive layer 272b are connected to the low-resistance regions 281n through the openings in the insulating layer 265. Furthermore, an insulating layer 268 covering the transistor may be provided.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer in which a channel is formed.

The structure in which the semiconductor layer where a channel is formed is sandwiched between two gates is used for the transistor 252, the transistor 260, and the transistor 258. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The semiconductor layer of the transistor preferably includes a metal oxide (also referred to as an oxide semiconductor). That is, a transistor including a metal oxide in its channel formation region (hereinafter, an OS transistor) is preferably used for the display apparatus of this embodiment.

The band gap of a metal oxide used for the semiconductor layer of the transistor is preferably 2 eV or more, further preferably 2.5 eV or more. With the use of a metal oxide having a wide band gap, the off-state current of the OS transistor can be reduced.

A metal oxide contains preferably at least indium or zinc and further preferably indium and zinc. A metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and Mis further preferably gallium. Hereinafter, a metal oxide containing indium, M, and zinc is referred to as In-M-Zn oxide in some cases.

When a metal oxide is In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio. By increasing the ratio of the number of indium atoms in the metal oxide, the on-state current, field-effect mobility, or the like of the transistor can be improved.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The atomic ratio of In may be less than the atomic ratio of M in the In-M-Zn oxide. Examples of the atomic ratio of the metal elements in such an In-M-Zn oxide include In:M:Zn=1:3:2 or a composition in the neighborhood thereof, In:M:Zn=1:3:3 or a composition in the neighborhood thereof, and In:M:Zn=1:3:4 or a composition in the neighborhood thereof. By increasing the ratio of the number of M atoms in the metal oxide, the band gap of the In-M-Zn oxide is further increased: thus, the resistance to a negative bias stress test with light irradiation can be improved. Specifically, the amount of change in the threshold voltage or the amount of change in the shift voltage (Vsh) measured in a NBTIS (Negative Bias Temperature Illumination Stress) test of the transistor can be decreased. Note that the shift voltage (Vsh) is defined as Vg at which, in a drain current (Id)-gate voltage (Vg) curve of a transistor, the tangent at a point where the slope of the curve is the steepest intersects the straight line of Id=1 pA.

Alternatively, the semiconductor layer of the transistor may contain silicon. Examples of silicon include amorphous silicon and crystalline silicon (e.g., low-temperature polysilicon (also referred to as LTPS) or single crystal silicon).

In particular, low-temperature polysilicon has relatively high mobility and can be formed over a glass substrate, and thus can be favorably used for a display apparatus. For example, a transistor including low-temperature polysilicon in a semiconductor layer (an LTPS transistor) can be used as the transistor 252 and the like included in the driver circuit, and a transistor including an oxide semiconductor in a semiconductor layer (an OS transistor) can be used as the transistor 260, the transistor 258, and the like provided in the pixel. When both an LTPS transistor and an OS transistor are used, the display apparatus can have low power consumption and high drive capability. A structure where an LTPS transistor and an OS transistor are used in combination is referred to as LTPO in some cases. As a favorable example, it is preferable to use an OS transistor as a transistor or the like functioning as a switch for controlling electrical continuity between wirings and an LTPS transistor as a transistor or the like for controlling current.

Alternatively, a semiconductor layer of a transistor may contain a layered material that functions as a semiconductor. The layered material is a general term of a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a monolayer, that is, high two-dimensional electrical conductivity. When a material that functions as a semiconductor and has high two-dimensional electrical conductivity is used for a channel formation region, a transistor having a high on-state current can be provided.

Examples of the layered materials include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

Note that the display apparatus illustrated in FIG. 18A includes an OS transistor and a common layer which is divided between the light-emitting elements. With this structure, the leakage current that might flow through the transistor and the leakage current that might flow between adjacent light-emitting elements (also referred to as a lateral leakage current, a side leakage current, or the like) can become extremely low. With the structure, a viewer can notice any one or more of the image crispness, the image sharpness, a high chroma, and a high contrast ratio in an image displayed on the display apparatus. With the structure where the leakage current that might flow through the transistor and the lateral leakage current that might flow between light-emitting elements are extremely low; display with little leakage of light at the time of black display (what is called black floating) (such display is also referred to as deep black display) can be achieved.

In particular, in the case where a light-emitting device having an MML structure employs a separate coloring structure (an SBS structure), a layer provided between light-emitting elements (for example, also referred to as an organic layer or a common layer which is commonly used between the light-emitting elements) is disconnected: accordingly, display with no or extremely low side leakage can be achieved.

The transistor included in the circuit 464 and the transistor included in the display portion 462 may have the same structure or different structures. A plurality of transistors included in the circuit 464 may have the same structure or two or more kinds of structures. Similarly, a plurality of transistors included in the display portion 462 may have the same structure or two or more kinds of structures.

A material through which impurities such as water and hydrogen do not easily diffuse is preferably used for at least one of the insulating layers that cover the transistors. This allows the insulating layer to function as a barrier layer. Such a structure can effectively inhibit diffusion of impurities into the transistors from the outside and increase the reliability of the display apparatus.

An inorganic insulating film is preferably used as each of the insulating layer 261, the insulating layer 262, the insulating layer 265, the insulating layer 268, and the insulating layer 275. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above inorganic insulating films may also be used.

An organic insulating film is suitable for the insulating layer 294 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Here, an organic insulating film often has a lower barrier property than an inorganic insulating film. Therefore, the organic insulating film preferably has an opening in the vicinity of the end portion of the display apparatus 400. This can inhibit entry of impurities from the end portion of the display apparatus 400 through the organic insulating film. Alternatively, the organic insulating film may be formed so that the end portion of the organic insulating film is positioned inward from the end portion of the display apparatus 400, to prevent the organic insulating film from being exposed at the end portion of the display apparatus 400.

The light-blocking layer 417 is preferably provided on a surface of the substrate 454 on the substrate 453 side. In addition, the coloring layer 418 or the like may be provided on a surface of the substrate 454 on the substrate 453 side. In FIG. 18A, when the substrate 454 is considered as a reference, the coloring layer 418 is provided to cover part of the light-blocking layer 417.

A variety of optical members can be arranged on the outer side of the substrate 454. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film inhibiting the attachment of stain, a hard coat film inhibiting generation of a scratch caused by the use, a shock absorption layer, or the like may be provided on the outer side of the substrate 454.

FIG. 18A illustrates a connection portion 278. In the connection portion 278, the common electrode 413 is electrically connected to a wiring. FIG. 18A illustrates an example in which the wiring has the same stacked-layer structure as the pixel electrode.

For each of the substrate 453 and the substrate 454, glass, quartz, ceramic, sapphire, a resin, a metal, an alloy, a semiconductor, or the like can be used. The substrate on the side where light from the light-emitting element is extracted is formed using a material that transmits the light. When a flexible material is used for the substrate 453 and the substrate 454, the flexibility of the display apparatus can be increased, so that a flexible display can be achieved. Furthermore, a polarizing plate may be used as the substrate 453 or the substrate 454.

For each of the substrate 453 and the substrate 454, a polyester resin such as polyethylene terephthalate (PET) or polyethylene naphthalate (PEN), a polyacrylonitrile resin, an acrylic resin, a polyimide resin, a polymethyl methacry late resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for one or both of the substrate 453 and the substrate 454.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of a display panel might be changed, e.g., creases are generated. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. An adhesive sheet or the like may be used.

For the connection layer 292, an anisotropic conductive film (ACF), an anisotropic conductive paste (ACP), or the like can be used.

Examples of materials that can be used for a gate, a source, and a drain of a transistor and conductive layers such as a variety of wirings and electrodes included in a display apparatus include metals such as aluminum, titanium, chromium, nickel, copper, yttrium, zirconium, molybdenum, silver, tantalum, or tungsten, and an alloy containing any of these metals as its main component. A film containing any of these materials can be used in a single layer or as a stacked-layer structure.

For a conductive material having a light-transmitting property, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) or the like may be used. Note that in the case of using the metal material or the alloy material (or the nitride thereof), the thickness is preferably set small enough to be able to transmit light. A stacked film of any of the above materials can be used as a conductive layer. For example, a stacked film of indium tin oxide and an alloy of silver and magnesium, or the like is preferably used for increased conductivity. These materials can also be used, for example, for the conductive layers such as a variety of wirings and electrodes included in a display apparatus, and conductive layers (conductive layers functioning as a pixel electrode or a common electrode) included in the light-emitting element.

For an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

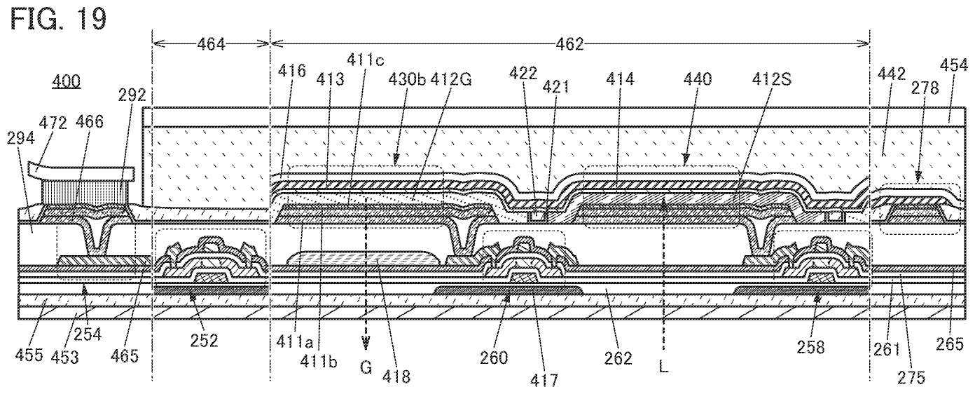

Although FIG. 18A illustrates a top-emission display apparatus, the present invention is not limited thereto. As illustrated in FIG. 19, a bottom-emission display apparatus may be employed. The display apparatus 400 illustrated in FIG. 19 is different from the display apparatus 400 illustrated in FIG. 18A mainly in having a bottom-emission structure. Note that portions similar to those of the display apparatus 400 in FIG. 18A are not described.

The light G emitted from the light-emitting element 430b passes through the coloring layer 418 and is emitted toward the substrate 453 side. The light-receiving element 440 receives the light L incident through the substrate 453 and converts the light L into an electric signal. For the substrate 453, a material having a high visible-light-transmitting property is preferably used. By contrast, there is no limitation on the light-transmitting property of a material used for the substrate 454.

In the display apparatus 400 illustrated in FIG. 19, the conductive layers 411a, 411b, and 411c each contain a material transmitting visible light, and the common electrode 413 contains a material reflecting visible light. Here, the conductive layer 466 and the connection layer 292, which are obtained by processing the same conductive film as the conductive layers 411a and 411b, each also contain a material which transmits visible light.

The light-blocking layer 417 is preferably formed between the substrate 453 and the transistor 260 and between the substrate 453 and the transistor 252. FIG. 19 illustrates an example in which the light-blocking layer 417 is provided over the adhesive layer 455, the insulating layer 262 is provided over the light-blocking layer 417, and the transistors 260, 252, and the like are provided over the insulating layer 262.

Furthermore, the coloring layer 418 is provided between the insulating layer 294 and the insulating layer 265 in the display apparatus 400 illustrated in FIG. 19. The end portion of the coloring layer 418 preferably overlap with the light-blocking layer 417.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 3

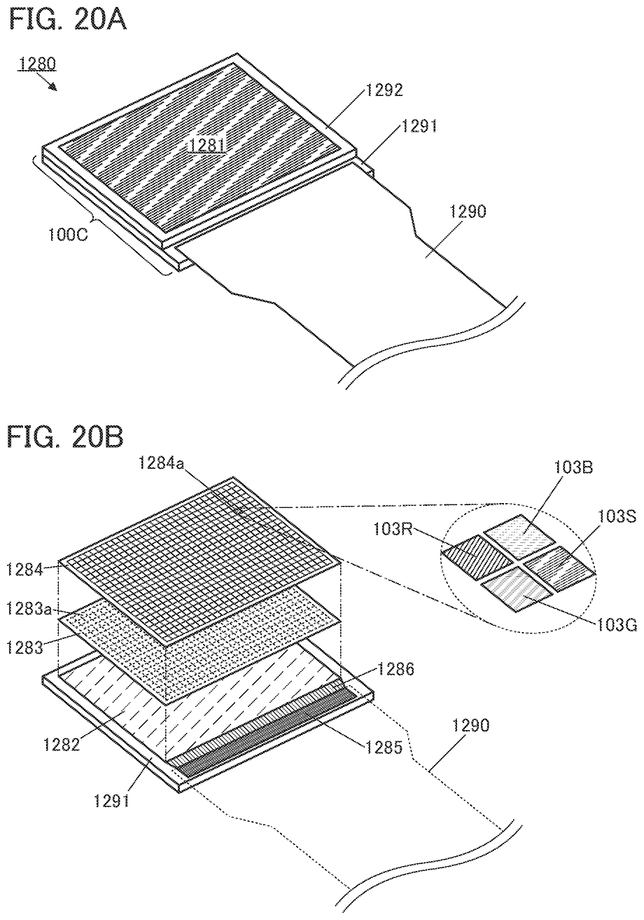

In this embodiment, a display apparatus of one embodiment of the present invention will be described with reference to FIG. 20 to FIG. 25.

The display apparatus in this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on the head, such as a VR (virtual reality) device like a head mounted display and a glasses-type AR (augmented reality) device.

### [Display Module]

FIG. 20A is a perspective view of a display module 1280. The display module 1280 includes a display apparatus 100C and an FPC 1290. Note that the display apparatus included in the display module 1280 is not limited to the display apparatus 100C and may be any of a display apparatus 100D to a display apparatus 100G described later.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 20B is a perspective view schematically illustrating a structure on the substrate 1291 side. Over the substrate 1291, a circuit portion 1282, a pixel circuit portion 1283 over the circuit portion 1282, and the pixel portion 1284 over the pixel circuit portion 1283 are stacked. A terminal portion 1285 to be connected to the FPC 1290 is provided in a portion over the substrate 1291 that is not overlapped by the pixel portion 1284. The terminal portion 1285 and the circuit portion 1282 are electrically connected to each other through a wiring portion 1286 formed of a plurality of wirings.

The pixel portion 1284 includes a plurality of pixels 1284a arranged periodically. An enlarged view of one pixel 1284a is illustrated on the right side of FIG. 20B. The pixel 1284a includes the subpixel 103R, the subpixel 103G, the subpixel 103B, and the subpixel 103S. The above embodiment can be referred to for the structures of the subpixel 103R, the subpixel 103G, the subpixel 103B, the subpixel 103S, and their surroundings. A plurality of subpixels can be arranged in a matrix as illustrated in FIG. 20B. Alternatively, a variety of arrangement methods for subpixels, such as a delta arrangement or a PenTile arrangement, can be employed.

The pixel circuit portion 1283 includes a plurality of pixel circuits 1283a arranged periodically.

One pixel circuit 1283a is a circuit that controls light emission of three light-emitting devices included in one pixel 1284a. One pixel circuit 1283a may be provided with three circuits each of which controls light emission of one light-emitting device. For example, the pixel circuit 1283a can include at least one selection transistor, one current control transistor (driving transistor), and a capacitor for one light-emitting device. In this case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, the circuit portion 1282 preferably includes one or both of a gate line driver circuit and a source line driver circuit. The circuit portion 1282 may also include at least one of an arithmetic circuit, a memory circuit, a power supply circuit, and the like.

The FPC 1290 functions as a wiring for supplying a video signal, a power supply potential, or the like to the circuit portion 1282 from the outside. An IC may be mounted on the FPC 1290.

The display module 1280 can have a structure in which one or both of the pixel circuit portion 1283 and the circuit portion 1282 are stacked below the pixel portion 1284: hence, the aperture ratio (effective display area ratio) of the display portion 1281 can be significantly high. For example, the aperture ratio of the display portion 1281 can be greater than or equal to 40% and less than 100%, preferably greater than or equal to 50% and less than or equal to 95%, further preferably greater than or equal to 60% and less than or equal to 95%. Furthermore, the pixels 1284a can be arranged extremely densely and thus the display portion 1281 can have extremely high resolution. For example, the pixels 1284a are preferably arranged in the display portion 1281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 1280 has extremely high resolution, and thus can be suitably used for a VR device such as a head mounted display or a glasses-type AR device. For example, even with a structure in which the display portion of the display module 1280 is seen through a lens, pixels of the extremely-high-resolution display portion 1281 included in the display module 1280 are prevented from being perceived when the display portion is enlarged by the lens, so that display providing a high sense of immersion can be performed. Without being limited thereto, the display module 1280 can be suitably used for electronic devices including a relatively small display portion. For example, the display module 1280 can be favorably used in a display portion of a wearable electronic device, such as a wrist watch.

### [Display Apparatus 100C]

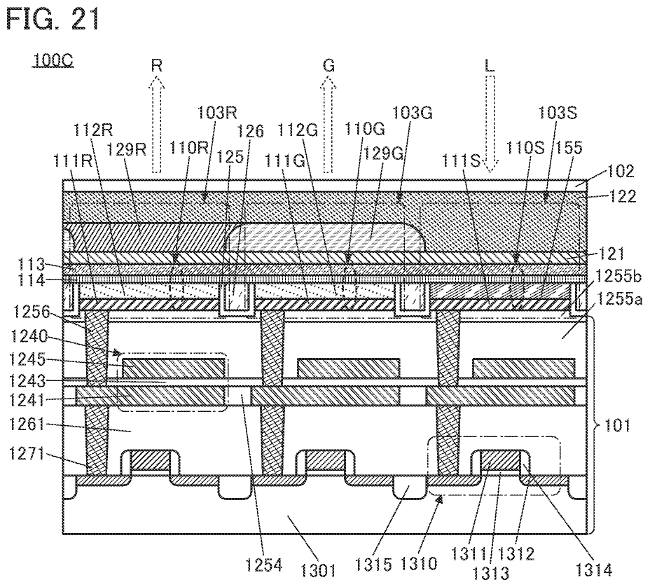

The display apparatus 100C illustrated in FIG. 21 includes a substrate 1301, the subpixels 103R, 103G, and 103S, a capacitor 1240, and a transistor 1310. The subpixel 103R includes the light-emitting element 110R and the coloring layer 129R, the subpixel 103G includes the light-emitting element 110G and the coloring layer 129G, and the subpixel 103S includes the light-receiving element 110S. Note that although the subpixel 103B is not illustrated in FIG. 21, the subpixel 103B can be provided to have the same structure as the subpixel 103R and the subpixel 103G.

The substrate 1301 corresponds to the substrate 1291 in FIG. 20A and FIG. 20B. A stacked-layer structure including the substrate 1301 and the components thereover up to an insulating layer 1255b corresponds to the substrate 101 in Embodiment 1.

The transistor 1310 includes a channel formation region in the substrate 1301. As the substrate 1301, a semiconductor substrate such as a single crystal silicon substrate can be used, for example. The transistor 1310 includes part of the substrate 1301, a conductive layer 1311, low-resistance regions 1312, an insulating layer 1313, and an insulating layer 1314. The conductive layer 1311 functions as a gate electrode. The insulating layer 1313 is positioned between the substrate 1301 and the conductive layer 1311 and functions as a gate insulating layer. The low-resistance regions 1312 are regions where the substrate 1301 is doped with an impurity, and function as one of a source and a drain. The insulating layer 1314 is provided to cover the side surface of the conductive layer 1311.

An element isolation layer 1315 is provided between two adjacent transistors 1310 to be embedded in the substrate 1301.

An insulating layer 1261 is provided to cover the transistor 1310, and the capacitor 1240 is provided over the insulating layer 1261.

The capacitor 1240 includes a conductive layer 1241, a conductive layer 1245, and an insulating layer 1243 between the conductive layer 1241 and the conductive layer 1245. The conductive layer 1241 functions as one electrode of the capacitor 1240, the conductive layer 1245 functions as the other electrode of the capacitor 1240, and the insulating layer 1243 functions as a dielectric of the capacitor 1240.

The conductive layer 1241 is provided over the insulating layer 1261 and is embedded in an insulating layer 1254. The conductive layer 1241 is electrically connected to one of a source and a drain of the transistor 1310 through a plug 1271 embedded in the insulating layer 1261. The insulating layer 1243 is provided to cover the conductive layer 1241. The conductive layer 1245 is provided in a region overlapping with the conductive layer 1241 with the insulating layer 1243 therebetween.

An insulating layer 1255a is provided to cover the capacitor 1240, the insulating layer 1255b is provided over the insulating layer 1255a, and the light-emitting elements 110R and 110G. the light-receiving element 110S, and the like are provided over the insulating layer 1255b. In this embodiment, an example in which the light-emitting elements 110R and 110G and the light-receiving element 110S have a stacked-layer structure illustrated in FIG. 2C is described. Note that the end portions of the pixel electrodes 111 are substantially aligned with the end portions of the organic layers 112 or the end portions of the organic layer 155 as in FIG. 2B. The side surfaces of the pixel electrodes 111R, 111G, and 111S, the organic layers 112R and 112G, and the organic layer 155 are each covered with the insulating layer 125 and the resin layer 126. The organic layer 114 is provided over the organic layers 112R and 112G, the organic layer 155, the insulating layer 125, and the resin layer 126, and the common electrode 113 is provided over the organic layer 114. The protective layer 121 is provided over the light-emitting elements 110R and 110G, and the light-receiving element 110S. The coloring layers 129R and 129G are provided over the protective layer 121. The substrate 102 is attached above the coloring layers 129R and 129G with the resin layer 122. Embodiment 1 can be referred to for details of the light-emitting devices and the components thereover up to the substrate 102. The substrate 102 corresponds to the substrate 1292 in FIG. 20A.

As each of the insulating layers 1255a and 1255b, a variety of inorganic insulating films such as an oxide insulating film, a nitride insulating film, an oxynitride insulating film, and a nitride oxide insulating film can be suitably used. As the insulating layer 1255a, an oxide insulating film or an oxynitride insulating film, such as a silicon oxide film, a silicon oxynitride 30 film, or an aluminum oxide film, is preferably used. As the insulating layer 1255b, a nitride insulating film or a nitride oxide insulating film, such as a silicon nitride film or a silicon nitride oxide film, is preferably used. Specifically, it is preferred that a silicon oxide film be used as the insulating layer 1255a and a silicon nitride film be used as the insulating layer 1255b. The insulating layer 1255b preferably has a function of an etching protective film. Alternatively, a 35 nitride insulating film or a nitride oxide insulating film may be used as the insulating layer 1255a, and an oxide insulating film or an oxynitride insulating film may be used as the insulating layer 1255b. Although this embodiment shows an example in which a depressed portion is provided in the insulating layer 1255b, a depressed portion may not be provided in the insulating layer 1255b.

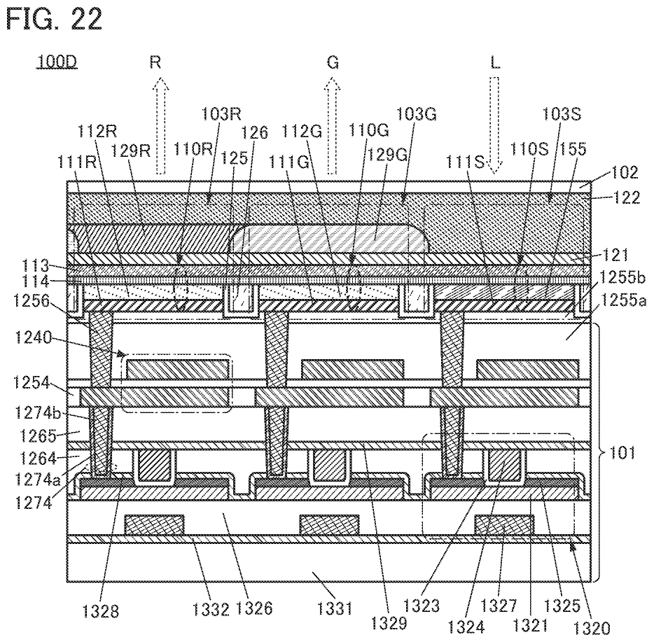

The pixel electrode of the light-emitting device is electrically connected to one of the source and the drain of the transistor 1310 through a plug 1256 embedded in the insulating layers 1255a and 1255b, the conductive layer 1241 embedded in the insulating layer 1254, and the plug 1271 embedded in the insulating layer 1261. The level of the top surface of the insulating layer 1255b is equal to or substantially equal to the level of the top surface of the plug 1256. A variety of conductive materials can be used for the plugs.

[Display apparatus 100D] The display apparatus 100D illustrated in FIG. 22 differs from the display apparatus 100C mainly in a structure of a transistor. Note that portions similar to those in the display apparatus 100C are not described in some cases.

A transistor 1320 is a transistor that contains a metal oxide (also referred to as an oxide semiconductor) in a semiconductor layer where a channel is formed (i.e., an OS transistor).

The transistor 1320 includes a semiconductor layer 1321, an insulating layer 1323, a conductive layer 1324, a pair of conductive layers 1325, an insulating layer 1326, and a conductive layer 1327.

A substrate 1331 corresponds to the substrate 1291 in FIG. 20A and FIG. 20B. A stacked-layer structure including the substrate 1331 and the components thereover up to the insulating layer 1255b corresponds to the substrate 101. As the substrate 1331, an insulating substrate or a semiconductor substrate can be used.

An insulating layer 1332 is provided over the substrate 1331. The insulating layer 1332 functions as a barrier layer that prevents diffusion of impurities such as water or hydrogen from the substrate 1331 into the transistor 1320 and release of oxygen from the semiconductor layer 1321 to the insulating layer 1332 side. As the insulating layer 1332, a film in which hydrogen or oxygen is less likely to diffuse than in a silicon oxide film, such as an aluminum oxide film, a hafnium oxide film, or a silicon nitride film can be used, for example.

The conductive layer 1327 is provided over the insulating layer 1332, and the insulating layer 1326 is provided to cover the conductive layer 1327. The conductive layer 1327 functions as a first gate electrode of the transistor 1320, and part of the insulating layer 1326 functions as a first gate insulating layer. An oxide insulating film such as a silicon oxide film is preferably used as at least part of the insulating layer 1326 that is in contact with the semiconductor layer 1321. The top surface of the insulating layer 1326 is preferably planarized.

The semiconductor layer 1321 is provided over the insulating layer 1326. The semiconductor layer 1321 preferably includes a film of a metal oxide having semiconductor characteristics (also referred to as an oxide semiconductor). A material that can be suitably used for the semiconductor layer 1321 will be described in detail later.

The pair of conductive layers 1325 are provided over and in contact with the semiconductor layer 1321 and function as a source electrode and a drain electrode.

An insulating layer 1328 is provided to cover the top and side surfaces of the pair of conductive layers 1325, the side surface of the semiconductor layer 1321, and the like, and an insulating layer 1264 is provided over the insulating layer 1328. The insulating layer 1328 functions as a barrier layer that prevents diffusion of impurities such as water or hydrogen from the insulating layer 1264 and the like into the semiconductor layer 1321 and release of oxygen from the semiconductor layer 1321. As the insulating layer 1328, an insulating film similar to the insulating layer 1332 can be used.

An opening reaching the semiconductor layer 1321 is provided in the insulating layer 1328 and the insulating layer 1264. The insulating layer 1323 that is in contact with the side surfaces of the insulating layer 1264, the insulating layer 1328, and the conductive layer 1325, and the top surface of the semiconductor layer 1321 and the conductive layer 1324 are embedded in the opening. The conductive layer 1324 functions as a second gate electrode, and the insulating layer 1323 functions as a second gate insulating layer.

The top surface of the conductive layer 1324, the top surface of the insulating layer 1323, and the top surface of the insulating layer 1264 are planarized so that their levels are equal to or substantially equal to each other, and an insulating layer 1329 and an insulating layer 1265 are provided to cover these layers.

The insulating layer 1264 and the insulating layer 1265 each function as an interlayer insulating layer. The insulating layer 1329 functions as a barrier layer that prevents diffusion of impurities such as water or hydrogen from the insulating layer 1265 or the like into the transistor 1320. As the insulating layer 1329, an insulating film similar to the insulating layer 1328 and the insulating layer 1332 can be used.

A plug 1274 electrically connected to one of the pair of conductive layers 1325 is provided to be embedded in the insulating layer 1265, the insulating layer 1329, and the insulating layer 1264. Here, the plug 1274 preferably includes a conductive layer 1274a that covers the side surfaces of openings formed in the insulating layer 1265, the insulating layer 1329, the insulating layer 1264, and the insulating layer 1328 and part of the top surface of the conductive layer 1325, and a conductive layer 1274b in contact with the top surface of the conductive layer 1274a. For the conductive layer 1274a, a conductive material in which hydrogen and oxygen are less likely to diffuse is preferably used.

The structures of the insulating layer 1254 and the components thereover up to the substrate 102 in the display apparatus 100D are similar to those in the display apparatus 100C.

### [Display Apparatus 100E]

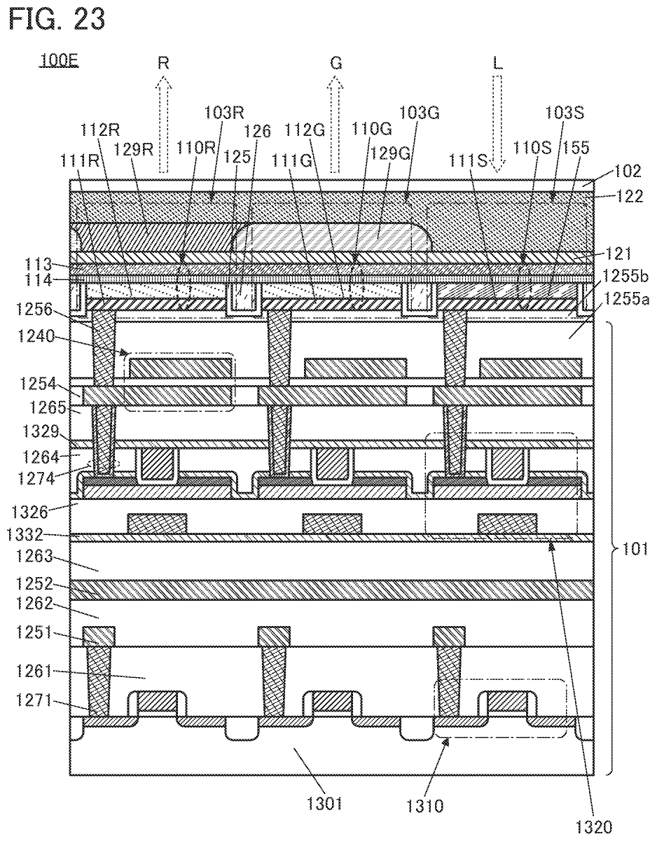

The display apparatus 100E illustrated in FIG. 23 has a structure in which the transistor 1310 whose channel is formed in the substrate 1301 and the transistor 1320 including a metal oxide in the semiconductor layer where the channel is formed are stacked. Note that portions similar to those in the display apparatuses 100C and 100D are not described in some cases.

The insulating layer 1261 is provided to cover the transistor 1310, and a conductive layer 1251 is provided over the insulating layer 1261. An insulating layer 1262 is provided to cover the conductive layer 1251, and a conductive layer 1252 is provided over the insulating layer 1262. The conductive layer 1251 and the conductive layer 1252 each function as a wiring. An insulating layer 1263 and the insulating layer 1332 are provided to cover the conductive layer 1252, and the transistor 1320 is provided over the insulating layer 1332. The insulating layer 1265 is provided to cover the transistor 1320, and the capacitor 1240 is provided over the insulating layer 1265. The capacitor 1240 and the transistor 1320 are electrically connected to each other through the plug 1274.

The transistor 1320 can be used as a transistor included in the pixel circuit. The transistor 1310 can be used as a transistor included in the pixel circuit or a transistor included in a driver circuit for driving the pixel circuit (a gate line driver circuit or a source line driver circuit). The transistor 1310 and the transistor 1320 can also be used as transistors included in a variety of circuits such as an arithmetic circuit and a memory circuit.

With such a structure, not only the pixel circuit but also the driver circuit and the like can be formed directly under the light-emitting devices: thus, the display apparatus can be downsized as compared with the case where a driver circuit is provided around a display region.

### [Display Apparatus 100F]

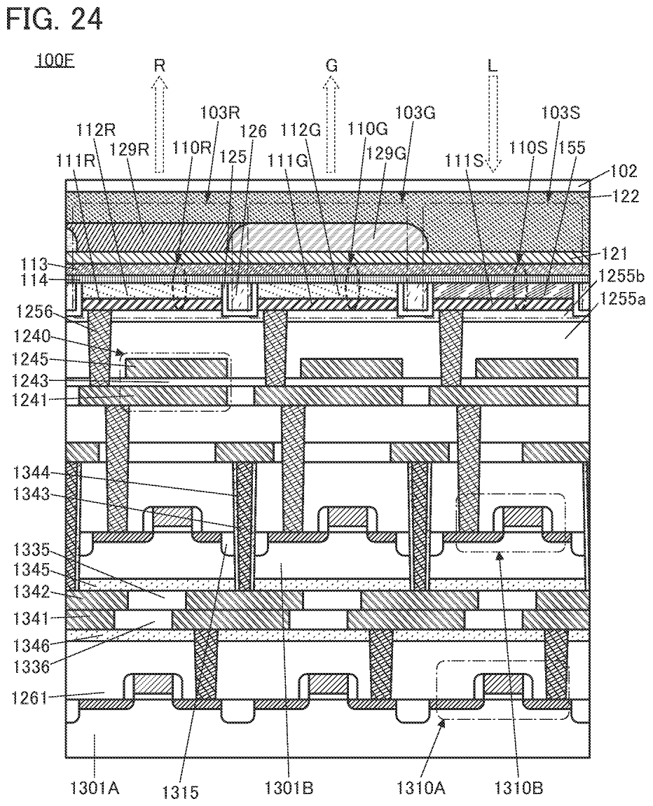

The display apparatus 100F illustrated in FIG. 24 has a structure where a transistor 1310A and a transistor 1310B in each of which a channel is formed in a semiconductor substrate are stacked.

In the display apparatus 100F, a substrate 1301B provided with the transistor 1310B, the capacitor 1240, and the light-emitting devices is attached to a substrate 1301A provided with the transistor 1310A.

Here, an insulating layer 1345 is preferably provided on the bottom surface of the substrate 1301B. An insulating layer 1346 is preferably provided over the insulating layer 1261 provided over the substrate 1301A. The insulating layers 1345 and 1346 function as protective layers and can inhibit diffusion of impurities into the substrate 1301B and the substrate 1301A. As the insulating layers 1345 and 1346, an inorganic insulating film that can be used as the protective layer 121 or the insulating layer 1332 can be used.

The substrate 1301B is provided with a plug 1343 that penetrates the substrate 1301B and the insulating layer 1345. An insulating layer 1344 is preferably provided to cover the side surface of the plug 1343. The insulating layer 1344 functions as a protective layer and can inhibit diffusion of impurities into the substrate 1301B. As the insulating layer 1344, an inorganic insulating film that can be used as the protective layer 121 or the insulating layer 1332 can be used.

A conductive layer 1342 is provided under the insulating layer 1345 on the rear surface of the substrate 1301B (the surface opposite to the substrate 102). The conductive layer 1342 is preferably provided to be embedded in an insulating layer 1335. The bottom surfaces of the conductive layer 1342 and the insulating layer 1335 are preferably planarized. Here, the conductive layer 1342 is electrically connected to the plug 1343.

Over the substrate 1301A, a conductive layer 1341 is provided over the insulating layer 1346. The conductive layer 1341 is preferably provided to be embedded in an insulating layer 1336. The top surfaces of the conductive layer 1341 and the insulating layer 1336 are preferably planarized.

The conductive layer 1341 and the conductive layer 1342 are attached to each other, whereby the substrate 1301A and the substrate 1301B are electrically connected to each other. Here, improving the flatness of a plane formed by the conductive layer 1342 and the insulating layer 1335 and a plane formed by the conductive layer 1341 and the insulating layer 1336 allows the conductive layer 1341 and the conductive layer 1342 to be attached to each other favorably.

The conductive layer 1341 and the conductive layer 1342 are preferably formed using the same conductive material. For example, it is possible to use a metal film containing an element selected from Al, Cr, Cu, Ta, Ti, Mo, and W, or a metal nitride film containing any of the above elements as a component (a titanium nitride film, a molybdenum nitride film, or a tungsten nitride film). Copper is particularly preferably used for the conductive layer 1341 and the conductive layer 1342. In that case, it is possible to employ a Cu-to-Cu (copper-to-copper) direct bonding technique (a technique for achieving electrical continuity by connecting Cu (copper) pads).

### [Display Apparatus 100G]

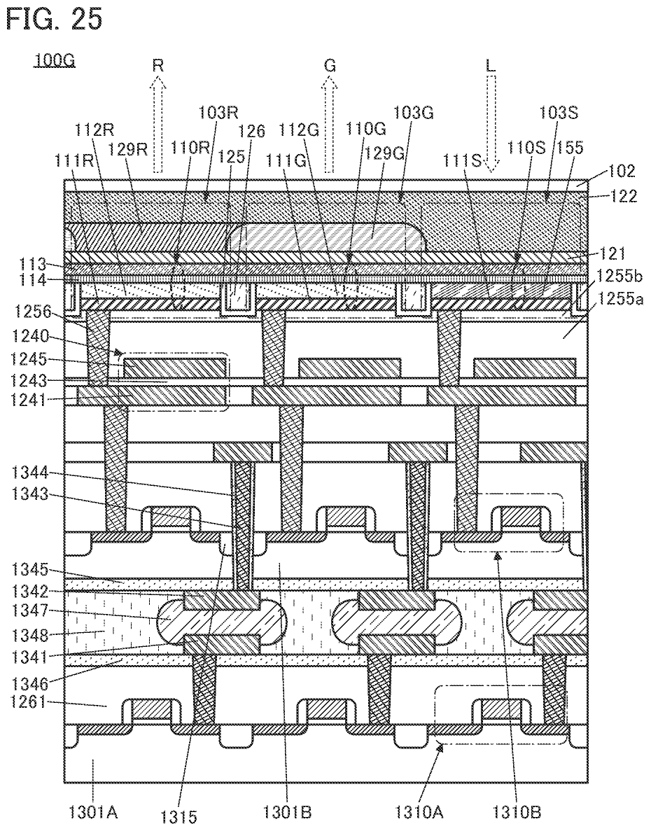

Although FIG. 24 illustrates an example in which Cu-to-Cu direct bonding technique is used to bond the conductive layer 1341 and the conductive layer 1342, the present invention is not limited thereto. As illustrated in FIG. 25, the conductive layer 1341 and the conductive layer 1342 may be attached to each other through a bump 1347 in the display apparatus 100G.

As illustrated in FIG. 25, providing the bump 1347 between the conductive layer 1341 and the conductive layer 1342 enables the conductive layer 1341 and the conductive layer 1342 to be electrically connected to each other. The bump 1347 can be formed using a conductive material containing gold (Au), nickel (Ni), indium (In), tin (Sn), or the like, for example. As another example, solder may be used for the bump 1347. An adhesive layer 1348 may be provided between the insulating layer 1345 and the insulating layer 1346. In the case where the bump 1347 is provided, the insulating layer 1335 and the insulating layer 1336 may be omitted.

This embodiment can be combined with any of the other embodiments as appropriate.

### Embodiment 4

In this embodiment, a display apparatus of one embodiment of the present invention will be described.

The display apparatus of one embodiment of the present invention includes a light-receiving element (also referred to as a light-receiving device) and a light-emitting element (also referred to as a light-emitting device).

First, a display apparatus including a light-receiving element and a light-emitting element is described.

The display apparatus of one embodiment of the present invention includes a light-receiving element and a light-emitting element in a light-emitting and light-receiving portion. In the display apparatus of one embodiment of the present invention, the light-emitting elements are arranged in a matrix in the light-emitting and light-receiving portion, and an image can be displayed on the light-emitting and light-receiving portion. Furthermore, the light-receiving elements are arranged in a matrix in the light-emitting and light-receiving portion, and the light-emitting and light-receiving portion has one or both of an image capturing function and a sensing function. The light-emitting and light-receiving portion can be used as an image sensor, a touch sensor, or the like. That is, by detecting light with the light-emitting and light-receiving portion, an image can be captured and touch operation of an object (e.g., a finger or a stylus) can be detected. Furthermore, in the display apparatus of one embodiment of the present invention, the light-emitting elements can be used as a light source of the sensor. Accordingly, a light-receiving portion and a light source do not need to be provided separately from the display apparatus: hence, the number of components of an electronic device can be reduced.

In the display apparatus of one embodiment of the present invention, when an object reflects (or scatters) light that is emitted from the light-emitting element included in the light-emitting and light-receiving portion and passes through the coloring layer, the light-receiving element can detect the reflected light (or the scattered light): thus, image capturing, touch operation detection, or the like is possible even in a dark place.

The light-emitting element included in the display apparatus of one embodiment of the present invention functions as a display element (also referred to as a display device).

As the light-emitting element, a light-emitting element (also referred to as a light-emitting device) such as an OLED or a QLED (Quantum-dot Light Emitting Diode) is preferably used. Examples of a light-emitting substance contained in the EL element include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a thermally activated delayed fluorescent (TADF) material). An LED such as a micro LED can also be used as the light-emitting element. The display apparatus of one embodiment of the present invention has a function of detecting light with the use of a light-receiving element.

When the light-receiving elements are used as an image sensor, the display apparatus can capture an image using the light-receiving elements. For example, the display apparatus can be used as a scanner.

An electronic device including the display apparatus of one embodiment of the present invention can obtain data related to biological information such as a fingerprint or a palm print by using a function of an image sensor. That is, a biometric authentication sensor can be incorporated in the display apparatus. When the display apparatus incorporates a biometric authentication sensor, the number of components of an electronic device can be reduced as compared to the case where a biometric authentication sensor is provided separately from the display apparatus: thus, the size and weight of the electronic device can be reduced.

When the light-receiving elements are used as the touch sensor, the display apparatus can detect touch operation of an object with the use of the light-receiving elements.

As the light-receiving element, a pn photodiode or a pin photodiode can be used, for example. The light-receiving element functions as a photoelectric conversion element (also referred to as a photoelectric conversion device) that detects light entering the light-receiving element and generates charge. The amount of charge generated from the light-receiving element depends on the amount of light entering the light-receiving element.

It is particularly preferable to use an organic photodiode including a layer containing an organic compound as the light-receiving element. An organic photodiode, which is easily made thin, lightweight, and large in area and has a high degree of freedom for shape and design, can be used in a variety of devices.

In one embodiment of the present invention, organic EL elements (also referred to as organic EL devices) are used as the light-emitting elements, and organic photodiodes are used as the light-receiving elements. The organic EL elements and the organic photodiodes can be formed over one substrate. Thus, the organic photodiodes can be incorporated in the display apparatus including the organic EL elements.

Since a large number of layers of the organic photodiode can have structures in common with the organic EL element, concurrently forming the layers that can have a common structure can inhibit an increase in the number of film formation steps. For example, one of a pair of electrodes (a common electrode) can be a layer shared by the light-receiving element and the light-emitting element. For example, at least one of a hole-injection layer, a hole-transport layer, an electron-transport layer, and an electron-injection layer may be a layer shared by the light-receiving element and the light-emitting element.

The display apparatus that is an example of the display apparatus of one embodiment of the present invention is specifically described below with reference to drawings.

### Structure Example of Display Apparatus

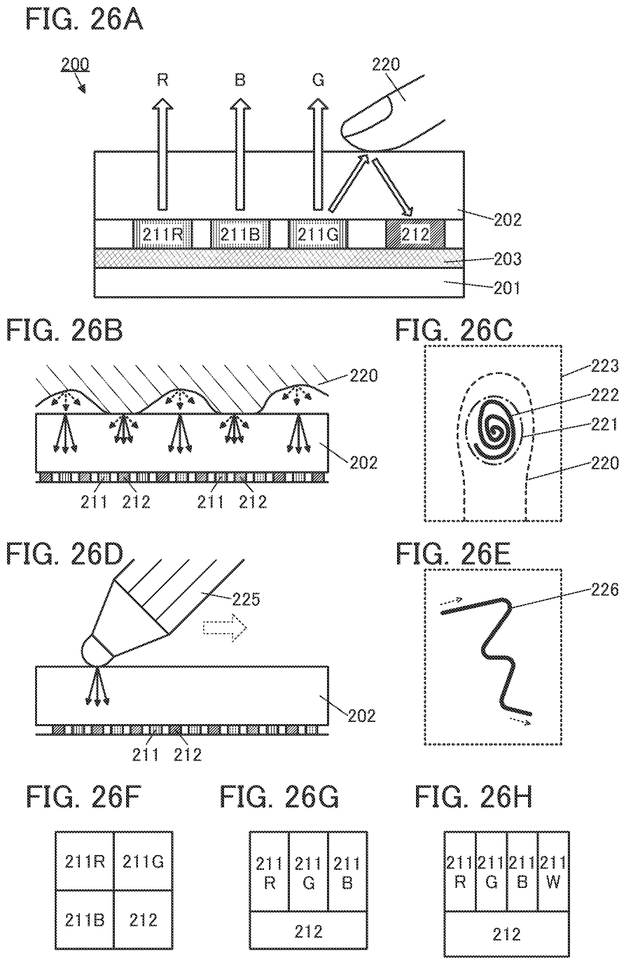

FIG. 26A is a schematic view of a display panel 200. The display panel 200 includes a substrate 201, a substrate 202, a light-receiving element 212, a light-emitting element 211R, a light-emitting element 211G, a light-emitting element 211B, a functional layer 203, and the like.

The light-emitting element 211R, the light-emitting element 211G, the light-emitting element 211B, the light-receiving element 212 are provided between the substrate 201 and the substrate 202. Light emitted from the light-emitting element 211R, the light-emitting element 211G, and the light-emitting element 211B passes through the coloring layers different from one another and the light to be light of red (R) light, green (G) light, and blue (B) light, respectively. Note that in the following description, the term “light-emitting element 211” may be used when the light-emitting element 211R, the light-emitting element 211G, and the light-emitting element 211B are not distinguished from each other.

The display panel 200 includes a plurality of pixels arranged in a matrix. One pixel includes one or more subpixels. One subpixel includes one light-emitting element. For example, the pixel can have a structure including three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel further includes the light-receiving element 212. The light-receiving element 212 may be provided in all the pixels or may be provided in some of the pixels. In addition, one pixel may include a plurality of light-receiving elements 212.

FIG. 26A illustrates a finger 220 touching a surface of the substrate 202. Part of light emitted from the light-emitting element 211G passes through the coloring layer and is reflected at a contact portion of the substrate 202 and the finger 220. In the case where part of the reflected light is incident on the light-receiving element 212, the contact of the finger 220 with the substrate 202 can be detected. That is, the display panel 200 can function as a touch panel.

The functional layer 203 includes a circuit for driving the light-emitting element 211R, the light-emitting element 211G, and the light-emitting element 211B and a circuit for driving the light-receiving element 212. The functional layer 203 is provided with a switch, a transistor, a capacitor, a wiring, and the like. Note that in the case where the light-emitting element 211R, the light-emitting element 211G, the light-emitting element 211B, and the light-receiving element 212 are driven by a passive-matrix method, a structure not provided with a switch, a transistor, or the like may be employed.

The display panel 200 preferably has a function of detecting a fingerprint of the finger 220. FIG. 26B schematically illustrates an enlarged view of the contact portion in a state where the finger 220 touches the substrate 202. FIG. 26B illustrates light-emitting elements 211 and the light-receiving elements 212 that are alternately arranged.

The fingerprint of the finger 220 is formed of depressed portions and projected portions. Therefore, as illustrated in FIG. 26B, the projected portions of the fingerprint touch the substrate 202

Reflection of light from a surface, an interface, or the like is categorized into regular reflection and diffuse reflection. Regularly reflected light is highly directional light with an angle of reflection equal to the angle of incidence. Diffusely reflected light has low directionality and low angular dependence of intensity. As for regular reflection and diffuse reflection, diffuse reflection components are dominant in the light reflected from the surface of the finger 220. Meanwhile, regular reflection components are dominant in the light reflected from the interface between the substrate 202 and the air.

The intensity of light that is reflected from contact surfaces or non-contact surfaces between the finger 220 and the substrate 202 and is incident on the light-receiving elements 212 positioned directly below the contact surfaces or the non-contact surfaces is the sum of intensities of regularly reflected light and diffusely reflected light. As described above, regularly reflected light (indicated by solid arrows) is dominant near the depressed portions of the finger 220, where the finger 220 is not in contact with the substrate 202: whereas diffusely reflected light (indicated by dashed arrows) from the finger 220 is dominant near the projected portions of the finger 220, where the finger 220 is in contact with the substrate 202. Thus, the intensity of light received by the light-receiving element 212 positioned directly below the depressed portion is higher than the intensity of light received by the light-receiving element 212 positioned directly below the projected portion. Accordingly, a fingerprint image of the finger 220 can be captured.

In the case where an arrangement interval between the light-receiving elements 212 is 20) smaller than a distance between two projected portions of a fingerprint, preferably a distance between a depressed portion and a projected portion adjacent to each other, a clear fingerprint image can be obtained. The distance between a depressed portion and a projected portion of a human's fingerprint is approximately 200 μm: thus, the arrangement interval between the light-receiving elements 212 is, for example, less than or equal to 400 μm, preferably less than or equal 25 to 200 μm, further preferably less than or equal to 150 μm, still further preferably less than or equal to 100 μm, even still further preferably less than or equal to 50 μm and greater than or equal to 1 μm, preferably greater than or equal to 10 μm, further preferably greater than or equal to 20 μm.

30 FIG. 26C illustrates an example of a fingerprint image captured by the display panel 200. In an image-capturing range 223 in FIG. 26C, the outline of the finger 220 is indicated by a dashed line and the outline of a contact portion 221 is indicated by a dashed-dotted line. In the contact portion 221, a high-contrast image of a fingerprint 222 can be captured owing to a difference in the amount of light incident on the light-receiving elements 212.

The display panel 200 can also function as a touch panel or a pen tablet. FIG. 26D illustrates a state where a tip of a stylus 225 slides in a direction indicated with a dashed arrow while the tip of the stylus 225 touches the substrate 202.

As illustrated in FIG. 26D, when diffusely reflected light that is diffused at the contact surface of the tip of the stylus 225 and the substrate 202 is incident on the light-receiving element 212 that overlaps with the contact surface, the position of the tip of the stylus 225 can be detected with high accuracy.

FIG. 26E illustrates an example of a path 226 of the stylus 225 that is detected by the display panel 200. The display panel 200 can detect the position of a detection target, such as the stylus 225, with high position accuracy, so that high-definition drawing can be performed using a drawing application or the like. Unlike the case of using a capacitive touch sensor, an electromagnetic induction touch pen, or the like, the display panel 200 can detect even the position of a highly insulating object to be detected, the material of a tip portion of the stylus 225 is not limited, and a variety of writing materials (e.g., a brush, a glass pen, a quill pen, and the like) can be used.

Here, FIG. 26F to FIG. 26H illustrate examples of a pixel that can be used in the display panel 200.

The pixels illustrated in FIG. 26F and FIG. 26G each include the light-emitting element 21 IR corresponding to the red (R) subpixel, the light-emitting element 211G corresponding to the green (G) subpixel, the light-emitting element 211B corresponding to the blue (B) subpixel, and the light-receiving element 212. The pixels each include a pixel circuit for driving the light-emitting element 211R, the light-emitting element 211G, the light-emitting element 211B, and the light-receiving element 212.

FIG. 26F illustrates an example in which three light-emitting elements and one light-receiving element are provided in a matrix of 2×2. FIG. 26G illustrates an example in which three light-emitting elements are arranged in one line and one laterally long light-receiving element 212 is provided below the three light-emitting elements.

The pixel illustrated in FIG. 26H is an example including a light-emitting element 211W for white (W). Here, four light-emitting elements are arranged in one line and the light-receiving element 212 is provided below the four light-emitting elements.

Note that the pixel structure is not limited to the above structure, and a variety of arrangement methods can be employed.

At least part of this embodiment can be implemented in combination with the other embodiments described in this specification as appropriate.

### Embodiment 5

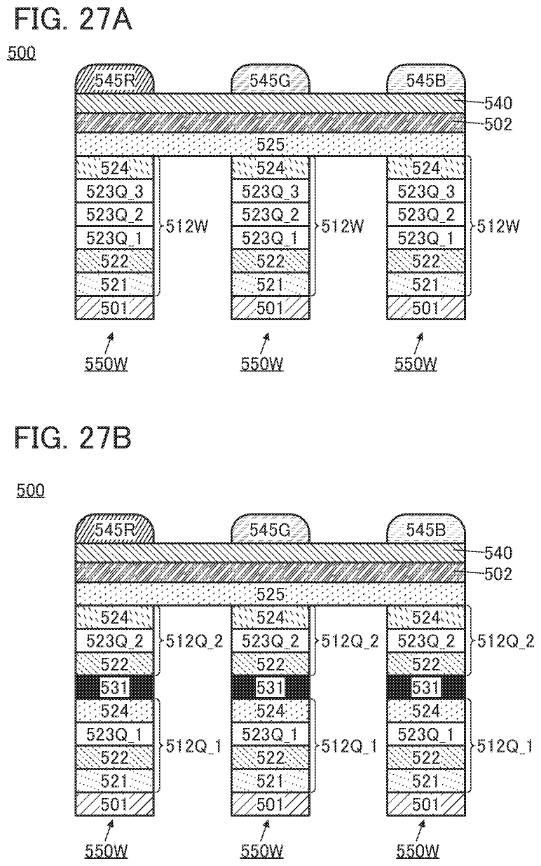

In this embodiment, structure examples of a light-emitting element and structure examples of a light-receiving element that can be used for the display apparatus of one embodiment of the present invention will be described with reference to FIG. 27 to FIG. 29.

A display apparatus 500 illustrated in FIG. 27A and FIG. 27B includes a plurality of light-emitting elements 550W that emit white light. A coloring layer 545R that transmits red light, a coloring layer 545G that transmits green light, and a coloring layer 545B that transmits blue light are provided over the respective light-emitting elements 550W. Here, the coloring layer 545R, the coloring layer 545G, and the coloring layer 545B can be provided to overlap with the light-emitting elements 550W with a protective layer 540 therebetween.

The light-emitting element 550W illustrated in FIG. 27A includes a light-emitting unit 512W between a pair of electrodes (an electrode 501 and an electrode 502). The electrode 501 functions as a pixel electrode and is provided for every light-emitting element. The electrode 502 functions as a common electrode and is shared by a plurality of light-emitting elements.

That is, the light-emitting element 550W illustrated in FIG. 27A is a light-emitting element including one light-emitting unit. Note that in this specification, a structure including one light-emitting unit between a pair of electrodes as in the light-emitting element 550W illustrated in FIG. 27A is referred to as a single structure.

A conductive film that transmits visible light is used as the electrode 502 through which light is extracted. A conductive film that reflects visible light is preferably used as the electrode 501 through which light is not extracted.

The light-emitting elements included in the display apparatus of this embodiment preferably employ a micro-optical resonator (microcavity) structure. Therefore, one of the pair of electrodes of the light-emitting elements is preferably an electrode having properties of transmitting and reflecting visible light (transflective electrode), and the other is preferably an electrode having a property of reflecting visible light (reflective electrode). When the light-emitting elements have a microcavity structure, light obtained from the light-emitting layers can be resonated between the electrodes, whereby light emitted from the light-emitting elements can be intensified.

The transflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting elements. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower. Note that in the case where any of the light-emitting elements emits near-infrared light (light with a wavelength greater than or equal to 750 nm and less than or equal to 1300 nm), the near-infrared light transmittance and reflectance of these electrodes preferably satisfy the above-described numerical ranges of the visible light transmittance and reflectance.

The light-emitting units 512W illustrated in FIG. 27A can be formed as island-shaped layers. That is, the light-emitting unit 512W illustrated in FIG. 27A corresponds to the organic layer 112R, the organic layer 112G, or the organic layer 112B illustrated in FIG. 1B and the like. Note that the light-emitting element 550W corresponds to the light-emitting element 110R, the light-emitting element 110G, or the light-emitting element 110B. The electrode 501 corresponds to the pixel electrode 111R, the pixel electrode 111G, or the pixel electrode 111B. The electrode 502 corresponds to the common electrode 113.

The light-emitting unit 512W includes a layer 521, a layer 522, a light-emitting layer 523Q_1, a light-emitting layer 523Q_2, a light-emitting layer 523Q_3, a layer 524, and the like. The light-emitting element 550W includes a layer 525 and the like between the light-emitting unit 512W and the electrode 502.

FIG. 27A illustrates an example in which the light-emitting unit 512W does not include the layer 525 and the layer 525 is provided to be shared by the light-emitting elements. In this case, the layer 525 can be referred to as a common layer. By providing one or more common layers for a plurality of light-emitting elements in this manner, the manufacturing step can be simplified, resulting in a reduction in manufacturing cost. Note that the layer 525 may be provided for every light-emitting element. That is, the layer 525 may be included in the light-emitting unit 512W.

The layer 521 includes, for example, a layer containing a substance with a high hole-injection property (a hole-injection layer). The layer 522 includes, for example, a layer containing a substance with a high hole-transport property (a hole-transport layer). The layer 524 includes, for example, a layer containing a substance with a high electron-transport property (an electron-transport layer). The layer 525 includes, for example, a layer containing a substance with a high electron-injection property (an electron-injection layer). Note that a structure may be employed in which the layer 521 may include an electron-injection layer, the layer 522 may include an electron-transport layer, the layer 524 may include a hole-transport layer, and the layer 525 may include a hole-injection layer.

The hole-injection layer is a layer injecting holes from an anode to the hole-transport layer, and a layer containing a material with a high hole-injection property. Examples of the material with a high hole-injection property include an aromatic amine compound, a composite material containing a hole-transport material and an acceptor material (an electron-accepting material), and the like.

The hole-transport layer is a layer transporting holes, which are injected from the anode by the hole-injection layer, to the light-emitting layer in the light-emitting element. The hole-transport layer is a layer containing a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, a material with a high hole-transport property, such as a π-electron rich heteroaromatic compound (e.g., a carbazole derivative, a thiophene derivative, a furan derivative, or the like) or an aromatic amine (a compound having an aromatic amine skeleton), is preferable.

The electron-transport layer is a layer transporting electrons, which are injected from a cathode by the electron-injection layer, to the light-emitting layer in the light-emitting element. The electron-transport layer is a layer containing an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-transport layer may have a stacked-layer structure, and may include a hole-blocking layer, in contact with the light-emitting layer, which blocks holes moving from the anode side to the cathode side through the light-emitting layer.

The electron-injection layer is a layer injecting electrons from a cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF_{X}; where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate. In addition, the electron-injection layer may have a stacked-layer structure of two or more layers. For example, it is possible to employ a structure where lithium fluoride is used for a first layer and ytterbium is provided for a second layer as the stacked-layer structure.

Alternatively, an electron-transport material may be used for the electron-injection layer. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

Note that FIG. 27A explicitly illustrates the layer 521 and the layer 522 separately: however, one embodiment of the present invention is not limited thereto. For example, the layer 522 may be omitted when the layer 521 has functions of both a hole-injection layer and a hole-transport layer or the layer 521 has functions of both an electron-injection layer and an electron-transport layer.

The light-emitting layer 523Q_1, the light-emitting layer 523Q_2, and the light-emitting layer 523Q_3 are layers containing a light-emitting substance. The light-emitting layer can include one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, a quantum dot material, and the like.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, a naphthalene derivative, and the like.

Examples of the phosphorescent material include an organometallic complex (in particular, an iridium complex) having a 4H-triazole skeleton, a 1H-triazole skeleton, an imidazole skeleton, a pyrimidine skeleton, a pyrazine skeleton, or a pyridine skeleton: an organometallic complex (in particular, an iridium complex) having a phenylpyridine derivative including an electron-withdrawing group as a ligand: a platinum complex: a rare earth metal complex; and the like

The light-emitting layer may contain one or more kinds of organic compounds (a host material, an assist material, and the like) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength is to be overlapped with the wavelength of the lowest-energy-side absorption band of the light-emitting substance, energy can be transferred smoothly and light emission can be obtained efficiently. With this structure, the high efficiency, low-voltage driving, and long lifetime of the light-emitting device can be achieved at the same time.

In a combination of materials for forming an exciplex, the HOMO level (the highest occupied molecular orbital level) of the hole-transport material is preferably higher than or equal to that of the electron-transport material. The LUMO level (the lowest unoccupied molecular orbital level) of the hole-transport material is preferably higher than or equal to the LUMO level of the electron-transport material. The LUMO levels and the HOMO levels of the materials can be derived from the electrochemical characteristics (reduction potentials and oxidation potentials) of the materials that are measured by cyclic voltammetry (CV).

Note that the formation of an exciplex can be confirmed by a phenomenon in which the emission spectrum of a mixed film in which the hole-transport material and the electron-transport material are mixed is shifted to the longer wavelength side than the emission spectrum of each of the materials (or has another peak on the longer wavelength side), observed by comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed by comparison of the transient EL of the hole-transport material, the transient EL of the electron-transport material, and the transient EL of the mixed film of these materials.

In the light-emitting element 550W illustrated in FIG. 27A, white light emission can be obtained from the light-emitting element 550W by selecting light-emitting layers such that a combination of light emissions of the light-emitting layer 523Q_1, the light-emitting layer 523Q_2. and the light-emitting layer 523Q_3 exhibit white. Although the example in which the light-emitting unit 512W includes three light-emitting layers is illustrated here, the number of light-emitting layers is not limited, and two layers may be included.

The coloring layer 545R, the coloring layer 545G, and the coloring layer 545B are provided over the light-emitting elements 550W capable of emitting white light, whereby the respective pixels emit red light, green light, and blue light so that full-color display can be performed. Note that although examples of providing the coloring layer 545R transmitting red light, the coloring layer 545G transmitting green light, and the coloring layer 545B transmitting blue light are described in FIG. 27A and the like, the present invention is not limited thereto. Visible light of colors transmitted by the coloring layers is visible light of at least two different colors that are appropriately selected from red, green, blue, cyan, magenta, and yellow, for example.

Thus, full-color display can be performed by providing coloring layers as appropriate even when the layer 521, the layer 522, the layer 524, the layer 525, the light-emitting layer 523Q_1, the light-emitting layer 523Q_2, and the light-emitting layer 523Q_3 have the same structure (material, thickness, and the like) in the pixels of different colors. Consequently, in the display apparatus of one embodiment of the present invention, the light-emitting element does not need to be formed separately in each pixel: hence, the manufacturing step can be simplified, and the manufacturing cost can be reduced. Note that the present invention is not limited thereto, and at least one of the layer 521, the layer 522, the layer 524, the layer 525, the light-emitting layer 523Q_1, the light-emitting layer 523Q_2, and the light-emitting layer 523Q_3 may have a structure that differs among pixels.

The light-emitting element 550W illustrated in FIG. 27B has a structure in which between a pair of electrodes (the electrode 501 and the electrode 502), two light-emitting units (a light-emitting unit 512Q_1 and a light-emitting unit 512Q_2) are stacked with an intermediate layer 531 therebetween.

The intermediate layer 531 has a function of injecting electrons into one of the light-emitting unit 512Q_1 and the light-emitting unit 512Q_2 and injecting holes to the other when voltage is applied between the electrode 501 and the electrode 502. The intermediate layer 531 can also be referred to as a charge-generation layer.

For example, a material that can be employed for the electron-injection layer, such as lithium fluoride, can be suitably used for the intermediate layer 531. Alternatively, as another example, a material that can be employed for the hole-injection layer can be suitably used for the intermediate layer. Alternatively, a layer that includes a material having a high hole-transport property (a hole-transport material) and an acceptor material (an electron-accepting material) can be used for the intermediate layer. Alternatively, a layer that includes a material having a high electron-transport property (an electron-transport material) and a donor material can be used for the intermediate layer. Forming the intermediate layer with such a layer can inhibit an increase in drive voltage in the case of stacking light-emitting units.

The light-emitting unit 512Q_1 includes the layer 521, the layer 522, the light-emitting layer 523Q_1, the layer 524, and the like. The light-emitting unit 512Q_2 includes the layer 522, the light-emitting layer 523Q_2, the layer 524, and the like. The light-emitting element 550W includes the layer 525 and the like between the light-emitting unit 512Q_2 and the electrode 502. Note that the layer 525 can also be regarded as part of the light-emitting unit 512Q_2.

In the light-emitting element 550W illustrated in FIG. 27B, white light emission can be obtained from the light-emitting element 550W by selecting light-emitting layers such that the light-emitting layer 523Q_1 and the light-emitting layer 523Q_2 emit light of complementary colors. The light-emitting layers 523Q_1 and 523Q_2 each preferably contain light-emitting substances that emit light of R (red), G (green), B (blue), Y (yellow), O (orange), and the like. Alternatively, light emitted from light-emitting substances contained in each of the light-emitting layers 523Q_1 and 523Q_2 preferably contains two or more of color spectral components of R, G, and B.

Described here are examples of the combination of emission colors of light-emitting layers included in the light-emitting units that can be used for the light-emitting element 550W.

In the case where the light-emitting element 550W includes two light-emitting units, for example, the light-emitting element 550W that emits white light can be obtained when one light-emitting unit emits red and green light and the other light-emitting unit emits blue light.

Alternatively, the light-emitting element 550W that emits white light can be obtained when one light-emitting unit emits yellow or orange light and the other light-emitting unit emits blue light.

In the case where the light-emitting element 550W includes three light-emitting units, for example, the light-emitting element 550W that emits white light can be obtained when any one light-emitting unit emits red light, another light-emitting unit emits green light, and the other light-emitting unit emits blue light. Alternatively, a light-emitting layer emitting blue light may be used for a first light-emitting unit, a light-emitting layer emitting yellow, yellowish green, or green light may be used for a second light-emitting unit, and a light-emitting layer emitting blue light may be used for a third light-emitting unit. Alternatively, a light-emitting layer emitting blue light may be used for the first light-emitting unit, a stacked-layer structure of a light-emitting layer emitting red light and a light-emitting layer emitting yellow, yellowish green, or green light may be used for the second light-emitting unit, and a light-emitting layer emitting blue light may be used for the third light-emitting unit.

In the case where the light-emitting element 550W includes four light-emitting units, for example, a light-emitting layer emitting blue light can be used for a first light-emitting unit, a light-emitting layer emitting red light can be used for one of a second light-emitting unit and a third light-emitting unit whereas a light-emitting layer emitting yellow, yellowish green, or green light can be used for the other, and a light-emitting layer emitting blue light can be used for a fourth light-emitting unit.

A structure in which a plurality of light-emitting units are connected in series with the intermediate layer 531 therebetween as in the light-emitting element 550W illustrated in FIG. 27B or the like is referred to as a tandem structure in this specification. Note that the term “tandem structure” is used in this specification and the like: however, without being limited to this, a tandem structure may be referred to as a stack structure, for example. Note that the tandem structure enables a light-emitting element to emit light at high luminance. Furthermore, a tandem structure allows the amount of current needed for obtaining the same luminance to be reduced as compared to the case of using a single structure: thus, the display apparatus can have lower power consumption and higher reliability.

Although the example where each of the light-emitting units 512Q_1 and 512Q_2 includes one light-emitting layer is illustrated here, the number of light-emitting layers in each light-emitting unit is not limited. For example, the light-emitting units 512Q_1 and 512Q_2 may each include a different number of light-emitting layers. For example, one of the light-emitting units may include two light-emitting layers, and the other light-emitting unit may include one light-emitting layer.

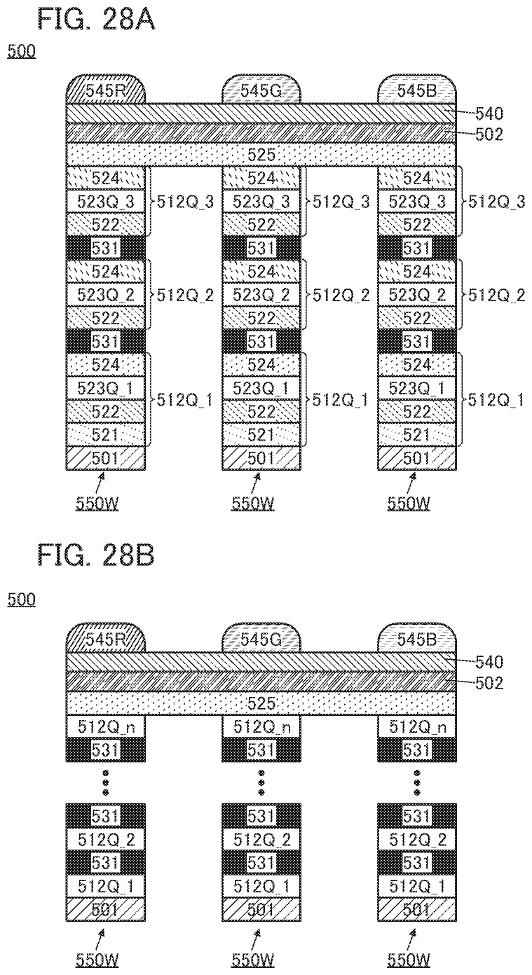

The display apparatus 500 illustrated in FIG. 28A is an example in which the light-emitting element 550W has a structure in which three light-emitting units are stacked. In the light-emitting element 550W in FIG. 28A, a light-emitting unit 512Q_3 is further stacked over the light-emitting unit 512Q_2 with another intermediate layer 531 therebetween. The light-emitting unit 512Q_3 includes the layer 522, the light-emitting layer 523Q_3, the layer 524, and the like. The light-emitting unit 512Q_3 can have a structure similar to that of the light-emitting unit 512Q_2.

When the light-emitting element has a tandem structure, the number of light-emitting units is not particularly limited and can be two or more.

FIG. 28B illustrates an example in which n light-emitting units 512Q_1 to 512Q_n (n is an integer greater than or equal to 2) are stacked.

When the number of stacked light-emitting units is increased in this manner, luminance obtained from the light-emitting element with the same amount of current can be increased in accordance with the number of stacked layers. Moreover, increasing the number of stacked light-emitting units can reduce current that is necessary for obtaining the same luminance: thus, power consumption of the light-emitting element can be reduced in accordance with the number of stacked layers.

There is no particular limitation on the light-emitting material of the light-emitting layer in the display apparatus 500. For example, in the display apparatus 500 illustrated in FIG. 27B, the light-emitting layer 523Q_1 included in the light-emitting unit 512Q_1 can contain a phosphorescent material, and the light-emitting layer 523Q_2 included in the light-emitting unit 512Q_2 can contain a fluorescent material. Alternatively, the light-emitting layer 523Q_1 included in the light-emitting unit 512Q_1 can contain a fluorescent material, and the light-emitting layer 523Q_2 included in the light-emitting unit 512Q_2 can contain a phosphorescent material.

Note that the structure of the light-emitting unit is not limited to the above. For example, in the display apparatus 500 illustrated in FIG. 27B, the light-emitting layer 523Q_1 included in the light-emitting unit 512Q_1 may contain a TADF material, and the light-emitting layer 523Q_2 included in the light-emitting unit 512Q_2 may contain one of a fluorescent material and a phosphorescent material. Using different light-emitting materials, e.g., using a combination of a highly reliable light-emitting material and a light-emitting material with high emission efficiency can compensate for their disadvantages and enables the display apparatus to have both higher reliability and higher emission efficiency.

Note that in the display apparatus of one embodiment of the present invention, all the light-emitting layers may contain a fluorescent material or all the light-emitting layers may contain a phosphorescent material.

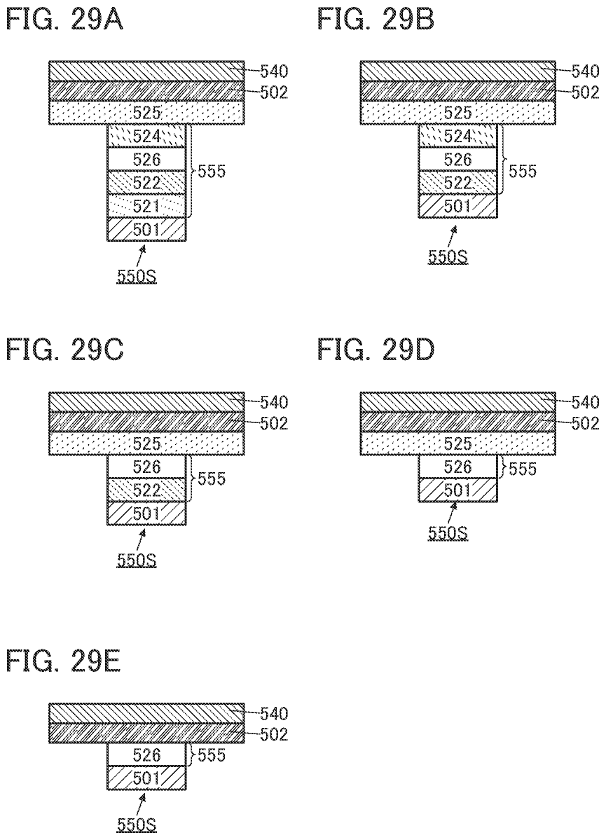

FIG. 29A to FIG. 29E illustrate structure examples of a light-receiving element 550S that can be used in the display apparatus. Among the components illustrated in FIG. 29A to FIG. 29E, components similar to the components illustrated in FIG. 27 or FIG. 28 are denoted by the same reference numerals.

The light-receiving element 550S illustrated in FIG. 29A includes a light-receiving unit 555 between a pair of electrodes (the electrode 501 and the electrode 502). The electrode 501 functions as a pixel electrode and is provided in every light-receiving element. The electrode 502 functions as a common electrode and is provided to be shared by a plurality of light-emitting elements and a light-receiving element.

The light-receiving unit 555 illustrated in FIG. 29A can be formed as an island-shaped layer. That is, the light-receiving unit 555 illustrated in FIG. 29A corresponds to the organic layer 155 illustrated in FIG. 1B and the like. Note that the light-receiving element 550S corresponds to the light-receiving element 110S. Furthermore, the electrode 501 corresponds to the pixel electrode 111S. The electrode 502 corresponds to the common electrode 113.

The light-receiving unit 555 includes the layer 521, the layer 522, an active layer 526, the layer 524, and the like. The layer 521, the layer 522, and the layer 524 are similar to those used for the light-emitting unit 512W. The light-receiving element 550S includes the layer 525 and the like between the light-receiving unit 555 and the electrode 502. The protective layer 540 is provided over the electrode 502. Here, the layer 525, the electrode 502, and the protective layer 540 are films that are shared by the light-emitting element 550W and the light-receiving element 550S as illustrated in FIG. 27A and the like.

The active layer 526 includes a semiconductor. Examples of the semiconductor include an inorganic semiconductor such as silicon and an organic semiconductor including an organic compound. This embodiment shows an example in which an organic semiconductor is used as the semiconductor included in the active layer 526. An organic semiconductor is preferably used, in which case the light-emitting layer and the active layer 526 can be formed by the same method (e.g., a vacuum evaporation method) and thus the same manufacturing apparatus can be used.

As the active layer 526, a pn photodiode or a pin photodiode can be used, for example. An n-type semiconductor material and a p-type semiconductor material that can be used as the active layer 526 are described below. The n-type semiconductor material and the p-type semiconductor material may be formed as layers to be stacked or may be mixed to form one layer.

Examples of an n-type semiconductor material contained in the active layer 526 include electron-accepting organic semiconductor materials such as fullerene (e.g., C₆₀, C₇₀, or the like) and a fullerene derivative. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads in a plane as in benzene, an electron-donating property (donor property) usually increases. However, since fullerene has a spherical shape, fullerene has a high electron-accepting property even when π-electron conjugation widely spread. The high electron-accepting property efficiently causes rapid charge separation and is useful for a light-receiving element. Both C₆₀ and C₇₀ have a wide absorption band in a visible light region, and C₇₀ is particularly preferable because of having a larger π-electron conjugation system and a wider absorption band in a long wavelength region than C₆₀. Other examples of the fullerene derivative include [6,6]-Phenyl-C71-butyric acid methyl ester (abbreviation: PC70BM), [6,6]-Phenyl-C61-butyric acid ester methyl (abbreviation: PC60BM), 1′,1″,4′,4″-Tetrahydro-di[1,4]methanonaphthaleno[1,2:2′,3′,56,60:2″,3″][5,6]fullerene-C₆₀ (abbreviation: ICBA), and the like.

Another example of an n-type semiconductor material includes a perylenetetracarboxylic derivative such as N,N′-dimethyl-3,4,9,10-perylenetetracarboxylic diimide (abbreviation: Me-PTCDI).

Another example of an n-type semiconductor material is 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, a quinone derivative, and the like.

Examples of a p-type semiconductor material contained in the active layer 526 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Other examples of the p-type semiconductor material include a carbazole derivative, a thiophene derivative, a furan derivative, a compound having an aromatic amine skeleton, and the like. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, a polythiophene derivative, and the like.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the active layer 526 is preferably formed through co-evaporation of an n-type semiconductor and a p-type semiconductor. Alternatively, the active layer 526 may be formed by stacking an n-type semiconductor and a p-type semiconductor.

Either a low molecular compound or a high molecular compound can be used for the light-emitting element and the light-receiving element, and an inorganic compound may also be contained. Each layer included in the light-emitting element and the light-receiving element can be formed by an evaporation method (including a vacuum evaporation method), a transfer method, a printing method, an inkjet method, a coating method, or the like.

As the hole-transport material or the electron-blocking material, a high molecular compound such as poly(3,4-ethylenedioxythiophene)/poly(styrenesulfonic acid) (PEDOT/PSS), or an inorganic compound such as a molybdenum oxide or copper iodide (Cul) can be used, for example. As the electron-transport material or the hole-blocking material, an inorganic compound such as zinc oxide (ZnO) or an organic compound such as polyethylenimine ethoxylated (PEIE) can be used. The light-receiving device may include a mixed film of PEIE and ZnO, for example.

For the active layer 526, a high molecular compound such as Poly[[4,8-bis[5-(2-ethylhexyl)-2-thienyl|benzo[ 1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer 526 may contain a mixture of three or more kinds of materials. For example, a third material may be mixed with an n-type semiconductor material and a p-type semiconductor material in order to extend the wavelength range. In that case, the third material may be a low molecular compound or a high molecular compound.

As illustrated in FIG. 29A, the light-receiving unit 555 can be formed by stacking the layer 521 (the hole-injection layer), the layer 522 (the hole-transport layer), the active layer 526, the layer 524 (the electron-transport layer), and the layer 525 (the electron-injection layer) in this order. This staking order is the same as that in the light-emitting unit 512W illustrated in FIG. 27A. In that case, the electrode 501 can function as an anode and the electrode 502 can function as a cathode in both the light-emitting element 550W and the light-receiving element 550S. In other words, the light-receiving element 550S is driven by application of reverse bias between the electrode 501 and the electrode 502, whereby light incident on the light-receiving element 550S can be detected and charge can be generated and extracted as current.

However, the present invention is not limited thereto. For example, a structure may be employed in which the layer 521 may include an electron-injection layer, the layer 522 may include an electron-transport layer, the layer 524 may include a hole-transport layer, and the layer 525 may include a hole-injection layer. In that case, in the light-receiving element 550S, the electrode 501 functions as a cathode and the electrode 502 can function as an anode. As described in the above embodiment, the light-emitting elements 550W and the light-receiving element 550S can be separately formed in the present invention. Therefore, even when the structures of the light-emitting elements 550W are greatly different from the structure of the light-receiving element 550S, the light-emitting elements 550W and the light-receiving element 550S can be manufactured relatively easily.

It is not always necessary to provide all of the layer 521, the layer 522, the layer 524, and the layer 525 illustrated in FIG. 29A. For example, the layer 522 including a hole-injection layer may be in contact with the electrode 501 as illustrated in FIG. 29B without providing the layer 521 including a hole-injection layer. Note that as illustrated in FIG. 29A and FIG. 29B, at least one of the layer 522 including a hole-transport layer and the layer 524 including an electron-transport layer is preferably provided in contact with the active layer 526. Thus, in the light-receiving element 550S, leakage current is generated between the electrode 501 and the electrode 502, so that a reduction in the sensitivity of image capturing can be inhibited.

Furthermore, either one of the layer 522 and the layer 524 may be omitted. For example, the active layer 526 may be in contact with the layer 525 without providing the layer 524 including an electron-transport layer as illustrated in FIG. 29C.

Moreover, the light-receiving unit 555 can be formed of only the active layer 526. For example, the active layer 526 may be in contact with the electrode 501 without providing the layer 522 including a hole-transport layer as illustrated in FIG. 29D.

Furthermore, in the case where the layer 525 is not a common layer and is provided for every light-emitting element, a structure may be employed in which the layer 525 is not provided in the light-receiving element 550S. For example, the active layer 526 may be in contact with the electrode 502 without providing the layer 525 including an electron-injection layer as illustrated in FIG. 29E.

This embodiment can be combined with the other embodiments as appropriate.

### Embodiment 6

In this embodiment, an example of a display apparatus including a light-receiving device and the like of one embodiment of the present invention will be described.

In the display apparatus of this embodiment, a pixel can include a plurality of types of subpixels including light-emitting devices that emit light of different colors. For example, the pixel can include three types of subpixels. The three subpixels can be of three colors of red (R), green (G), and blue (B) or of three colors of yellow (Y), cyan (C), and magenta (M), for example. Alternatively, the pixel can include four types of subpixels. The four subpixels can be of four colors of R, G, B, and white (W) or of four colors of R, G, B, and Y, for example. There is no particular limitation on the arrangement of subpixels, and a variety of methods can be employed. Examples of the arrangement of subpixels include a stripe arrangement, an S-stripe arrangement, a matrix arrangement, a delta arrangement, a Bayer arrangement, and a PenTile arrangement.

Examples of a top surface shape of the subpixel include polygons such as a triangle, a tetragon (including a rectangle and a square), and a pentagon: polygons with rounded corners; an ellipse; and a circle. Here, a top surface shape of the subpixel corresponds to a top surface shape of a light-emitting region of the light-emitting device.

In the display apparatus including light-emitting devices and a light-receiving device in each pixel, the pixel has a light-receiving function: thus, the display apparatus can detect a contact or approach of an object while displaying an image. For example, an image can be displayed by using all the subpixels included in the display apparatus: or light can be emitted by some of the subpixels as a light source and an image can be displayed by using the other subpixels.

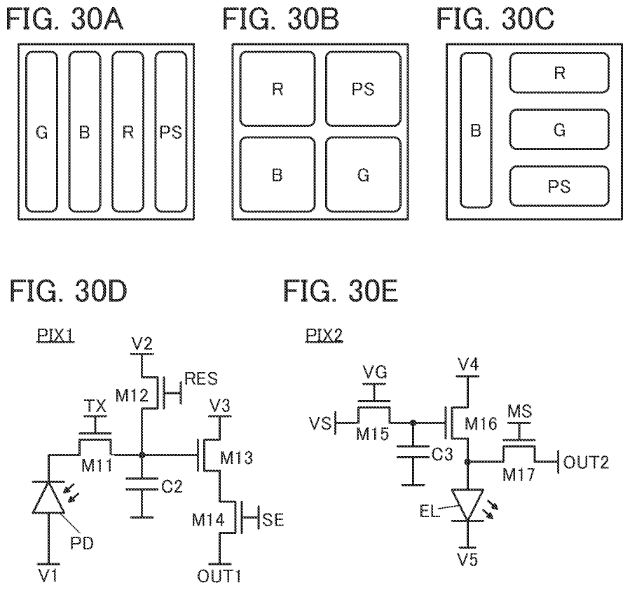

Pixels illustrated in FIG. 30A, FIG. 30B, and FIG. 30C each include a subpixel G, a subpixel B, a subpixel R, and a subpixel PS.

The pixel illustrated in FIG. 30A employs a stripe arrangement. The pixel illustrated in FIG. 30B employs a matrix arrangement.

In the pixel illustrated in FIG. 30C, three subpixels (the subpixel R, the subpixel G, and a subpixel S) are vertically arranged next to one subpixel (the subpixel B).

Note that the layout of the subpixels is not limited to those illustrated in FIG. 30A to FIG. 30C.

The subpixel R includes a light-emitting device that emits red light. The subpixel G includes a light-emitting device that emits green light. The subpixel B includes a light-emitting device that emits blue light. A subpixel IR includes a light-emitting device that emits infrared light. The subpixel PS includes a light-receiving device. Although there is no particular limitation on the wavelength of light that the subpixel PS detects, the light-receiving device included in the subpixel PS preferably has sensitivity to light emitted from the light-emitting device included in the subpixel R, the subpixel G, the subpixel B, or the subpixel IR. The light-receiving device preferably detects one or more of light in blue, violet, bluish violet, green, yellow green, yellow, orange, red, and infrared wavelength ranges, for example.

The light-receiving area of the subpixel PS is smaller than the light-emitting area of each of the other subpixels. A smaller light-receiving area leads to a narrower image-capturing range, inhibits a blur in a captured image, and improves the definition. Thus, by using the subpixel PS, high-resolution or high-definition image capturing is possible. For example, image capturing for personal authentication with the use of a fingerprint, a palm print, the iris, the shape of a blood vessel (including the shape of a vein and the shape of an artery), a face, or the like is possible by using the subpixel PS.

Moreover, the subpixel PS can be used in a touch sensor (also referred to as a direct touch sensor), a near touch sensor (also referred to as a hover sensor, a hover touch sensor, a contactless sensor, or a touchless sensor), or the like. For example, the subpixel PS preferably detects infrared light. Thus, touch detection is possible even in a dark place.

Here, the touch sensor or the near touch sensor can detect an approach or contact of an object (e.g., a finger, a hand, or a pen). The touch sensor can detect an object when the display apparatus and the object come in direct contact with each other. The near touch sensor can detect an object even when the object is not in contact with the display apparatus. For example, the display apparatus can preferably detect an object when the distance between the display apparatus and the object is more than or equal to 0.1 mm and less than or equal to 300 mm, preferably more than or equal to 3 mm and less than or equal to 50 mm. With this structure, the display apparatus can be controlled without an object directly contacting with the display apparatus. In other words, the display apparatus can be controlled in a contactless (touchless) manner. With the above structure, the display apparatus can have a reduced risk of being dirty or damaged, or can be operated without the object directly touching a dirt (e.g., dust or a virus) attached to the display apparatus.

For high-resolution image capturing, the subpixel PS is preferably provided in every pixel included in the display apparatus. Meanwhile, in the case where the subpixel PS is used in a touch sensor, a near touch sensor, or the like, high accuracy is not required as compared to the case of capturing an image of a fingerprint or the like: accordingly, the subpixel PS is provided in some of the pixels in the display apparatus. When the number of subpixels PS included in the display apparatus is smaller than the number of subpixels R, for example, higher detection speed can be achieved.

FIG. 30D illustrates an example of a pixel circuit for a subpixel including a light-receiving device. FIG. 30E illustrates an example of a pixel circuit for a subpixel including a light-emitting device.

A pixel circuit PIX1 illustrated in FIG. 30D includes a light-receiving device PD, a transistor M11, a transistor M12, a transistor M13, a transistor M14, and a capacitor C2. Here, a photodiode is used as an example of the light-receiving device PD.

An anode of the light-receiving device PD is electrically connected to a wiring V1, and a cathode of the light-receiving device PD is electrically connected to one of a source and a drain of the transistor M11. A gate of the transistor M11 is electrically connected to a wiring TX, and the other of the source and the drain of the transistor M11 is electrically connected to one electrode of the capacitor C2, one of a source and a drain of the transistor M12, and a gate of the transistor M13. A gate of the transistor M12 is electrically connected to a wiring RES, and the other of the source and the drain of the transistor M12 is electrically connected to a wiring V2. One of a source and a drain of the transistor M13 is electrically connected to a wiring V3, and the other of the source and the drain of the transistor M13 is electrically connected to one of a source and a drain of the transistor M14. A gate of the transistor M14 is electrically connected to a wiring SE, and the other of the source and the drain of the transistor M14 is electrically connected to a wiring OUT1.

A constant potential is supplied to the wiring V1, the wiring V2, and the wiring V3. When the light-receiving device PD is driven with a reverse bias, the wiring V2 is supplied with a potential higher than the potential of the wiring V1. The transistor M12 is controlled by a signal supplied to the wiring RES and has a function of resetting the potential of a node connected to the gate of the transistor M13 to a potential supplied to the wiring V2. The transistor M11 is controlled by a signal supplied to the wiring TX and has a function of controlling the timing at which the potential of the node changes, in accordance with current flowing through the light-receiving device PD. The transistor M13 functions as an amplifier transistor for performing output corresponding to the potential of the node. The transistor M14 is controlled by a signal supplied to the wiring SE and functions as a selection transistor for reading an output corresponding to the potential of the node by an external circuit connected to the wiring OUT1.

A pixel circuit PIX2 illustrated in FIG. 30E includes a light-emitting device EL, a transistor M15, a transistor M16, a transistor M17, and a capacitor C3. Here, a light-emitting diode is used as an example of the light-emitting device EL. In particular, an organic EL element is preferably used as the light-emitting device EL.

A gate of the transistor M15 is electrically connected to a wiring VG, one of a source and a drain of the transistor M15 is electrically connected to a wiring VS, and the other of the source and the drain of the transistor M15 is electrically connected to one electrode of the capacitor C3 and a gate of the transistor M16. One of a source and a drain of the transistor M16 is electrically connected to a wiring V4, and the other of the source and the drain of the transistor M16 is electrically connected to an anode of the light-emitting device EL and one of a source and a drain of the transistor M17. A gate of the transistor M17 is electrically connected to a wiring MS, and the other of the source and the drain of the transistor M17 is electrically connected to a wiring OUT2. A cathode of the light-emitting device EL is electrically connected to a wiring V5.

A constant potential is supplied to the wiring V4 and the wiring V5. The anode of the light-emitting device EL can be set to a high potential, and the cathode can be set to a lower potential than the anode. The transistor M15 is controlled by a signal supplied to the wiring VG and functions as a selection transistor for controlling a selection state of the pixel circuit PIX2. The transistor M16 functions as a driving transistor that controls current flowing through the light-emitting device EL in accordance with a potential supplied to the gate of the transistor M16. When the transistor M15 is on, a potential supplied to the wiring VS is supplied to the gate of the transistor M16, and the luminance of the light-emitting device EL can be controlled in accordance with the potential. The transistor M17 is controlled by a signal supplied to the wiring MS and has a function of outputting a potential between the transistor M16 and the light-emitting device EL to the outside through the wiring OUT2.

Here, transistors in which a metal oxide (an oxide semiconductor) is used in a semiconductor layer where a channel is formed are preferably used as the transistor M11, the transistor M12, the transistor M13, and the transistor M14 included in the pixel circuit PIX1 and the transistor M15, the transistor M16, and the transistor M17 included in the pixel circuit PIX2.

A transistor using a metal oxide having a wider band gap and a lower carrier density than silicon achieves an extremely low off-state current. Therefore, owing to the low off-state current, charge accumulated in a capacitor that is connected in series to the transistor can be retained for a long time. Hence, it is particularly preferable to use transistors containing an oxide semiconductor as the transistor M11, the transistor M12, and the transistor M15 each of which is connected in series with the capacitor C2 or the capacitor C3. Moreover, the use of transistors using an oxide semiconductor as the other transistors can reduce the manufacturing cost.

For example, the off-state current per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

Alternatively, transistors using silicon as a semiconductor in which a channel is formed can be used as the transistor M11 to the transistor M17. It is particularly preferable to use silicon with high crystallinity, such as single crystal silicon or polycrystalline silicon, because high field-effect mobility can be achieved and higher-speed operation can be performed.

Alternatively, a transistor containing an oxide semiconductor may be used as at least one of the transistor M11 to the transistor M17, and transistors containing silicon may be used as the other transistors.

Although n-channel transistors are illustrated in FIG. 30D and FIG. 30E, p-channel transistors can alternatively be used.

The transistors included in the pixel circuit PIX1 and the transistors included in the pixel circuit PIX2 are preferably formed side by side over the same substrate. It is particularly preferable that the transistors included in the pixel circuit PIX1 and the transistors included in the pixel circuit PIX2 be periodically arranged in one region.

One or more layers including the transistor and/or the capacitor are preferably provided to overlap with the light-receiving device PD or the light-emitting device EL. Thus, the effective area of each pixel circuit can be reduced, and a high-resolution light-receiving portion or display portion can be achieved.

To increase the luminance of the light-emitting device EL included in the pixel circuit, the amount of current fed through the light-emitting device EL needs to be increased. To increase the current amount, the source-drain voltage of a driving transistor included in the pixel circuit needs to be increased. An OS transistor has a higher withstand voltage between a source and a drain than a Si transistor: hence, high voltage can be applied between the source and the drain of the OS transistor. Accordingly, when an OS transistor is used as the driving transistor in the pixel circuit, the amount of current flowing through the light-emitting device can be increased, so that the luminance of the light-emitting device can be increased.

When transistors operate in a saturation region, a change in source-drain current relative to a change in gate-source voltage can be smaller in an OS transistor than in a Si transistor. Accordingly, when an OS transistor is used as the driving transistor in the pixel circuit, current flowing between the source and the drain can be set minutely by a change in gate-source voltage: hence, the amount of current flowing through the light-emitting device can be controlled. Consequently, the number of gray levels expressed by the pixel circuit can be increased.

Regarding saturation characteristics of current flowing when transistors operate in a saturation region, even in the case where the source-drain voltage of an OS transistor increases gradually, more stable current (saturation current) can be fed through the OS transistor than through a Si transistor. Thus, by using an OS transistor as the driving transistor, stable current can be fed through light-emitting devices that contain an EL material even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, by using an OS transistor as the driving transistor included in the pixel circuit, it is possible to achieve “inhibition of black floating”, “increase in emission luminance”, “increase in gray level”, “inhibition of variation in light-emitting devices”, and the like.

The refresh rate can be variable in the display apparatus of one embodiment of the present invention. For example, the refresh rate can be adjusted in accordance with the contents displayed on the display apparatus (e.g., adjusted in the range from 0.01 Hz to 240 Hz inclusive), whereby power consumption can be reduced. The driving with a lowered refresh rate for reducing power consumption of a display apparatus may be referred to as idling stop (IDS) driving.

The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

At least part of this embodiment can be implemented in combination with the other embodiments described in this specification as appropriate.

### Embodiment 7

In this embodiment, a high-resolution display apparatus will be described.

### Structure Example of Display Panel

Wearable electronic devices for VR, AR, and the like can provide 3D images by using parallax. In that case, it is necessary to display an image for the right eye in the right eye's field of view and display an image for the left eye in the left eye's field of view. Although the shape of a display portion in a display apparatus may be a horizontal rectangular shape, pixels provided outside the range of vision of both eyes do not contribute to display, and thus black is always displayed in these pixels.

In view of the above, it is preferred that a display portion of a display panel be divided into two regions for the right eye and for the left eye, and that pixels not be provided in an outer region which does not contribute to display. Hence, power consumption needed for writing to pixels can be reduced. Moreover, loads on source lines, gate lines, and the like are reduced, so that display with a high frame rate is possible. Consequently, smooth moving images can be displayed, which improves sense of reality.

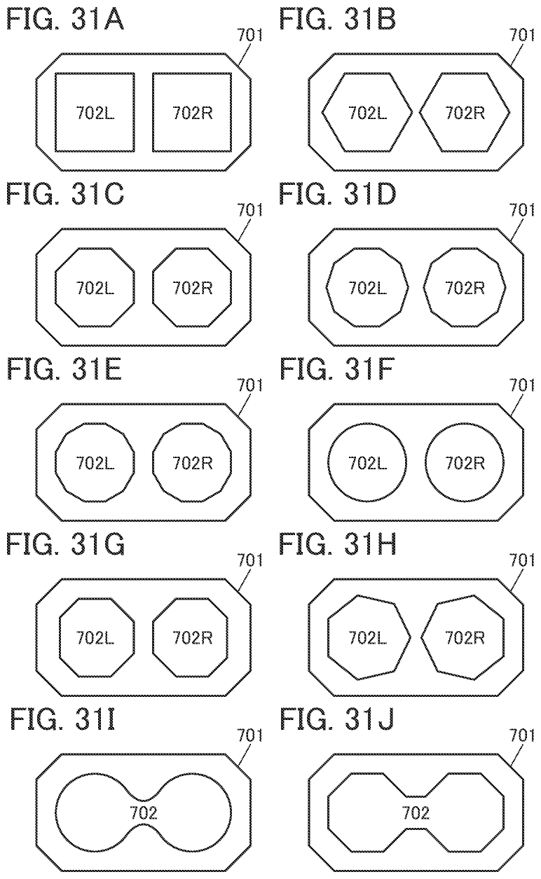

FIG. 31A illustrates a structure example of a display panel. In FIG. 31A, a display portion 702L for the left eye and a display portion 702R for the right eye are provided inward from a substrate 701. Note that in addition to the display portion 702L and the display portion 702R, a driver circuit, a wiring, an IC, an FPC, or the like may be provided over the substrate 701.

The display portion 702L and the display portion 702R illustrated in FIG. 31A have a square top surface shape.

The top surface shapes of the display portion 702L and the display portion 702R may be other regular polygons. FIG. 31B illustrates an example in which the top surface shape is a regular hexagon: FIG. 31C illustrates an example in which the top surface shape is a regular octagon: FIG. 31D illustrates an example in which the top surface shape is a regular decagon; and FIG. 31E illustrates an example in which the top surface shape is a regular dodecagon. When a polygon with even-numbered corners is used as above, the shape of the display portion can be bilaterally symmetrical. Note that a polygon that is not a regular polygon may be used. Moreover, a regular polygon or a polygon with rounded corners may be used.

Since the display portion consists of pixels arranged in a matrix, a linear portion of the outline of the display portion is not strictly a straight line and can be partly a stair-like portion. In particular, a linear portion that is not parallel to the direction of pixel arrangement has a stair-like top surface shape. Since the user watches images without perceiving the shape of the pixels, a tilted outline, which is stair-like to be exact, of the display portion can be regarded as a straight line. Similarly, a curved portion, which is stair-like to be exact, of the outline of the display portion can be regarded as a curve.

FIG. 31F illustrates an example in which the top surface shapes of the display portion 702L and the display portion 702R are circular.

The top surface shapes of the display portion 702L and the display portion 702R may be bilaterally asymmetrical. Moreover, the top surface shapes may not necessarily be regular polygonal.

FIG. 31G illustrates an example in which the top surface shapes of the display portion 702L and the display portion 702R are bilaterally asymmetric octagonal. FIG. 31H illustrates an example in which the top surface shape is regular heptagonal. Even when the top surface shapes of the display portion 702L and the display portion 702R have a bilaterally asymmetrical shape in this manner, the display portion 702L and the display portion 702R are preferably arranged bilaterally symmetrically. Consequently, an image with no unnaturalness can be provided.

Although the structures where the display portion is divided into two are described above, the display portions may have a continuous shape.

FIG. 31I illustrates an example in which the two circular display portions 702 in FIG. 31F are connected. FIG. 31J illustrates an example in which the two regular octagonal display portions 702 in FIG. 31C are connected.

The above is the description of the structure examples of the display panel.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 8

In this embodiment, a metal oxide (also referred to as an oxide semiconductor) that can be used in the OS transistor described in the above embodiment will be described.

The metal oxide used in the OS transistor preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. Specifically, M is preferably one or more kinds selected from gallium, aluminum, yttrium, and tin, and further preferably M is gallium.

The metal oxide can be formed by a sputtering method, a CVD method such as a MOCVD method, an ALD method, or the like. Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including a completely amorphous structure), CAAC (c-axis-aligned crystalline), nc (nanocrystalline), CAC (cloud-aligned composite), single-crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method. The XRD spectrum obtained by GIXD measurement may be hereinafter simply referred to as an XRD spectrum.

For example, the XRD spectrum of the quartz glass substrate shows a peak with a substantially bilaterally symmetrical shape. On the other hand, the peak of the XRD spectrum of the In—Ga—Zn oxide film having a crystal structure has a bilaterally asymmetrical shape. The bilaterally asymmetrical peak of the XRD spectrum clearly shows the existence of crystals in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the In—Ga—Zn oxide film deposited at room temperature. Thus, it is suggested that the In—Ga—Zn oxide deposited at room temperature is in an intermediate state, which is neither a single crystal nor polycrystal nor an amorphous state, and it cannot be concluded that In—Ga—Zn oxide film is in an amorphous state.

### «Structure of Oxide Semiconductor»

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductors include the above-described CAAC-OS and nc-OS. Other examples of the non-single-crystal oxide semiconductors include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor having a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement: however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and traps carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor having small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing step (what is called thermal budget). Accordingly, the use of the CAAC-OS for the OS transistor can extend the degree of flexibility of the manufacturing step. [nc-OS]

In the nc-OS, a microscopic region (e.g., a region with a size greater than or equal to 1 nm and less than or equal to 10 nm, specifically, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm: thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm). 35

[a-like OS]

The a-like OS is an oxide semiconductor having a structure between those of the nc-OS and the amorphous oxide semiconductor. The a-like OS has a void or a low-density region. That is, the a-like OS has low crystallinity as compared with the nc-OS and the CAAC-OS. Moreover, the a-like OS has a higher hydrogen concentration in the film than the nc-OS and the CAAC-OS.

«Structure of oxide semiconductor»

Next, the above-described CAC-OS will be described in detail. Note that the CAC-OS relates to the material composition.

### [CAC-OS]

The CAC-OS refers to one composition of a material in which elements included in a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Note that the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. Alternatively, for example, the first region has [In] higher than [In] in the second region and [Ga] lower than [Ga] in the second region. Moreover, the second region has [Ga] higher than [Ga] in the first region and [In] lower than [In] in the first region.

Specifically, the first region includes indium oxide, indium zinc oxide, or the like as its main component. The second region includes gallium oxide, gallium zinc oxide, or the like as its main component. That is, the first region can be rephrased as a region containing In as its main component. The second region can be rephrased as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof and these regions are randomly present to form a mosaic pattern. Thus, it is suggested that the CAC-OS has a structure in which metal elements are unevenly distributed.

The CAC-OS can be formed by a sputtering method under a condition where a substrate is not heated intentionally, for example. Moreover, in the case of forming the CAC-OS by a sputtering method, any one or more selected from an inert gas (typically, argon), an oxygen gas, and a nitrogen gas are used for a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

On the other hand, the second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material: as a whole, the CAC-OS has a function of a semiconductor. Separation of the conducting function and the insulating function can maximize each function. Accordingly, when the CAC-OS is used for a transistor, high on-state current (Ion), high field-effect mobility (μ), and excellent switching operation can be achieved.

A transistor using the CAC-OS has high reliability. Thus, the CAC-OS is the most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that impurities in an oxide semiconductor refer to, for example, elements other than the main components of an oxide semiconductor. For example, an element with a concentration lower than 0.1 atomic % can be regarded as an impurity.

### <Impurities>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen attached to a metal atom to be water, and thus forms an oxygen vacancy in some cases. Entry of hydrogen into the oxygen vacancy generates an electron serving as a carrier in some cases. Furthermore, bonding of part of hydrogen to oxygen attached to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 9

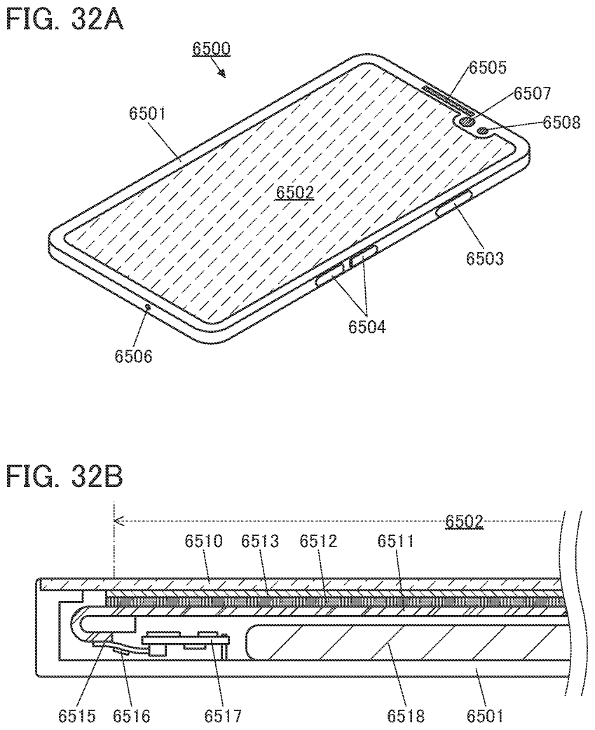

In this embodiment, electronic devices of one embodiment of the present invention will be described with reference to FIG. 32 to FIG. 35.

An electronic device in this embodiment includes the display apparatus of one embodiment of the present invention. In the display apparatus of one embodiment of the present invention, increases in resolution, definition, and sizes are easily achieved. Thus, the display apparatus of one embodiment of the present invention can be used for a display portion of a variety of electronic devices.

The display apparatus of one embodiment of the present invention can be manufactured at low cost, which leads to a reduction in the manufacturing cost of an electronic device.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have a high resolution, and thus can be suitably used for an electronic device including a relatively small display portion. Examples of such an electronic devices include information terminals (wearable devices) such as watch-type and bracelet-type information terminals and wearable devices capable of being worn on the head, such as a VR device like a head-mounted display and a glasses-type AR device. Examples of wearable devices include an SR (Substitutional Reality) device and an MR (Mixed Reality) device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320). In particular, definition of 4K2K, 8K4K, or higher is preferable. Furthermore, the pixel density (resolution) of the display apparatus of one embodiment of the present invention is preferably higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the display apparatus with such high definition or high resolution, the electronic device can have higher realistic sensation, sense of depth, and the like in personal use such as portable use or home use.

The electronic device in this embodiment can be incorporated along a curved surface of an inside wall or an outside wall of a house or a building or the interior or the exterior of a car.

The electronic device in this embodiment may include an antenna. When a signal is received by the antenna, the electronic device can display a video, data, and the like on a display portion. When the electronic device includes the antenna and a secondary battery, the antenna may be used for contactless power transmission.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of kinds of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 32A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 32B is a schematic cross-sectional view including the end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display (a display apparatus having flexibility) of one embodiment of the present invention can be used for the display panel 6511. Thus, an extremely lightweight electronic device can be provided. Since the display panel 6511 is extremely thin, the battery 6518 with high capacity can be mounted with the thickness of the electronic device controlled. An electronic device with a narrow frame can be obtained when part of the display panel 6511 is folded back so that the portion connected to the FPC 6515 is positioned on the rear side of a pixel portion.

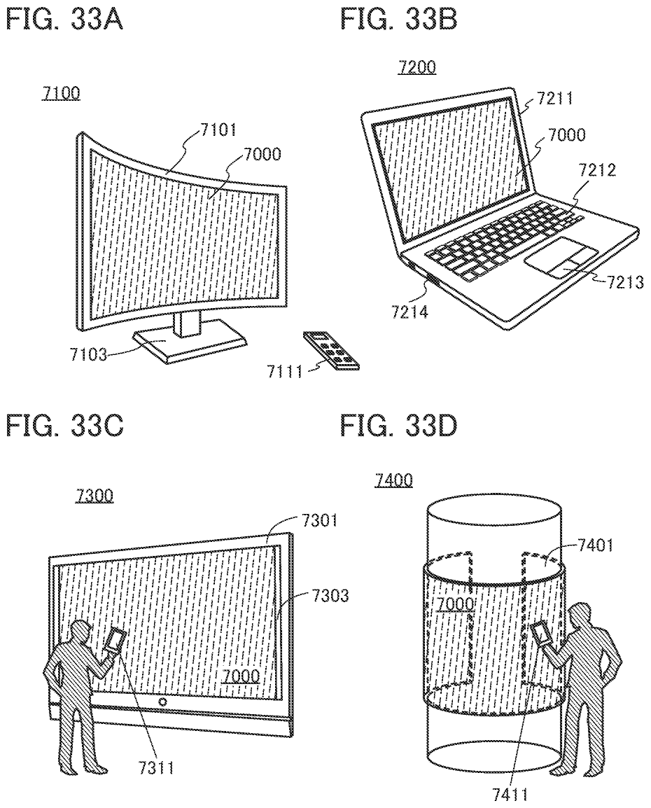

FIG. 33A illustrates an example of a television device. In a television device 7100, a display portion 7000 is incorporated in a housing 7101. Here, a structure in which the housing 7101 is supported by a stand 7103 is illustrated.

The display apparatus of one embodiment of the present invention can be used in the display portion 7000.

Operation of the television device 7100 illustrated in FIG. 33A can be performed with an operation switch provided in the housing 7101 and a separate remote controller 7111.

Alternatively, the display portion 7000 may include a touch sensor, and the television device 7100 may be operated by touch on the display portion 7000 with a finger or the like. The remote controller 7111 may be provided with a display portion for displaying data output from the remote controller 7111. With operation keys or a touch panel provided in the remote controller 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 33B illustrates an example of a notebook personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used in the display portion 7000.

FIG. 33C and FIG. 33D illustrate examples of digital signage.

Digital signage 7300 illustrated in FIG. 33C includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 33D is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 33C and FIG. 33D.

A larger area of the display portion 7000 can increase the amount of data that can be provided at a time. The larger display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 33C and FIG. 33D, it is preferable that the digital signage 7300 or the digital signage 7400 can work with an information terminal 7311 or an information terminal 7411, such as a smartphone a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

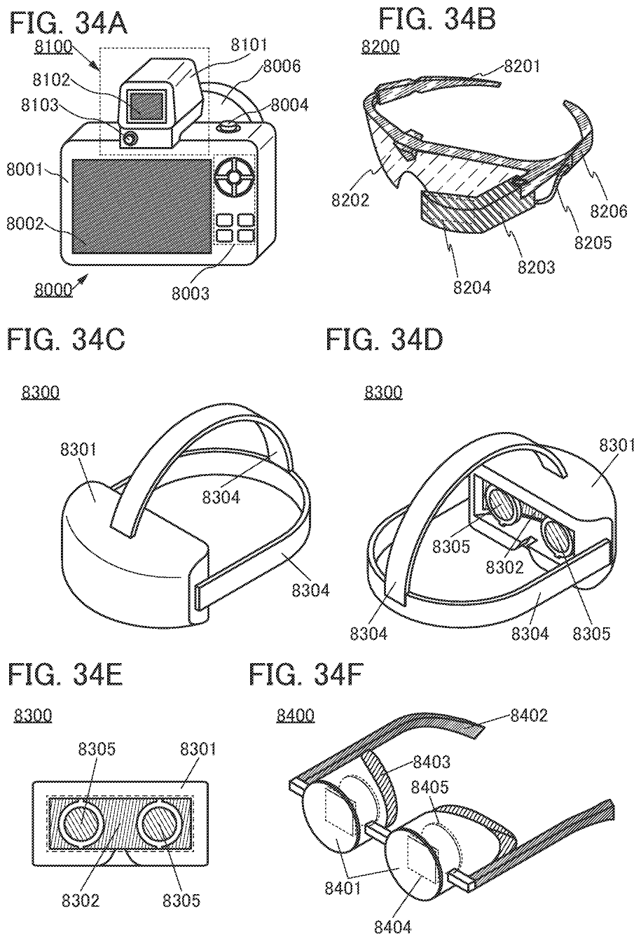

FIG. 34A is a diagram illustrating the appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000. Note that the lens 8006 and the housing 8001 may be integrated with each other in the camera 8000.

The camera 8000 can take images by the press of the shutter button 8004 or touch on the display portion 8002 serving as a touch panel.

The housing 8001 includes a mount including an electrode, so that the finder 8100, a stroboscope, or the like can be connected to the housing.

The finder 8100 includes a housing 8101, a display portion 8102, a button 8103, and the like.

The housing 8101 is attached to the camera 8000 with the mount engaging with a mount of the camera 8000. In the finder 8100, a video or the like received from the camera 8000 can be displayed on the display portion 8102.

The button 8103 has a function of a power button or the like.

The display apparatus of one embodiment of the present invention can be used for the display portion 8002 of the camera 8000 and the display portion 8102 of the finder 8100. Note that a finder may be incorporated in the camera 8000.

FIG. 34B is a diagram illustrating the appearance of a head-mounted display 8200.

The head-mounted display 8200 includes a wearing portion 8201, a lens 8202, a main body 8203, a display portion 8204, a cable 8205, and the like. A battery 8206 is incorporated in the wearing portion 8201.

The cable 8205 supplies electric power from the battery 8206 to the main body 8203. The main body 8203 includes a wireless receiver or the like and can display received video information on the display portion 8204. In addition, the main body 8203 is provided with a camera, and information on the movement of the user's eyeball or eyelid can be used as an input means.

The mounting portion 8201 may be provided with a plurality of electrodes capable of sensing current flowing in response to the movement of the user's eyeball in a position in contact with the user to have a function of recognizing the user's sight line. Furthermore, the mounting portion 8201 may have a function of monitoring the user's pulse with the use of current flowing through the electrodes. Moreover, the mounting portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, or the like.

The display apparatus of one embodiment of the present invention can be used in the display portion 8204.

FIG. 34C to FIG. 34E are diagrams illustrating the appearance of a head-mounted display 8300. The head-mounted display 8300 includes a housing 8301, a display portion 8302, a band-like fixing member 8304, and a pair of lenses 8305.

A user can perceive display on the display portion 8302 through the lenses 8305. Note that the display portion 8302 is preferably curved and placed because the user can feel a high realistic sensation. In addition, when another image displayed on a different region of the display portion 8302 is perceived through the lenses 8305, three-dimensional display using parallax, or the like can also be performed. Note that the number of display portions 8302 provided is not limited to one: two display portions 8302 may be provided so that one display portion is provided for one eye of the user.

The display apparatus of one embodiment of the present invention can be used for the display portion 8302. The display apparatus of one embodiment of the present invention can achieve extremely high resolution. For example, a pixel is not easily perceived by the user even when the user perceives display that is magnified by the use of the lenses 8305 as illustrated in FIG. 34E. In other words, a video with a strong sense of reality can be perceived by the user with the use of the display portion 8302.

FIG. 34F is an external view of a goggle-type head-mounted display 8400. The head-mounted display 8400 includes a pair of housings 8401, a mounting portion 8402, and a cushion 8403. A display portion 8404 and a lens 8405 are provided in each of the pair of housings 8401. The pair of display portions 8404 may display different images, whereby three-dimensional display using parallax can be performed.

A user can perceive display on the display portion 8404 through the lenses 8405. The lens 8405 has a focus adjustment mechanism and can adjust the position according to the user's eyesight. The display portion 8404 is preferably a square or a horizontal rectangle.

Accordingly, realistic sensation can be increased.

The mounting portion 8402 preferably has plasticity and elasticity to be adjusted to fit the size of the user's face and not to slide down. In addition, part of the mounting portion 8402 preferably has a vibration mechanism functioning as a bone conduction earphone. Thus, without additionally requiring an audio device such as earphones or a speaker, the user can enjoy video and sound only by wearing. Note that the housing 8401 may have a function of outputting sound data by wireless communication.

The mounting portion 8402 and the cushion 8403 are portions in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. Furthermore, when a sponge or the like whose surface is covered by cloth, leather (natural leather or synthetic leather), or the like is used, a gap is unlikely to be generated between the user's face and the cushion 8403, whereby light leakage can be suitably prevented. Furthermore, using such a material is preferable because it has a soft texture and the user does not feel cold when wearing the device in a cold season, for example. The member in contact with user's skin, such as the cushion 8403 or the mounting portion 8402, is preferably detachable because cleaning or replacement can be easily performed.

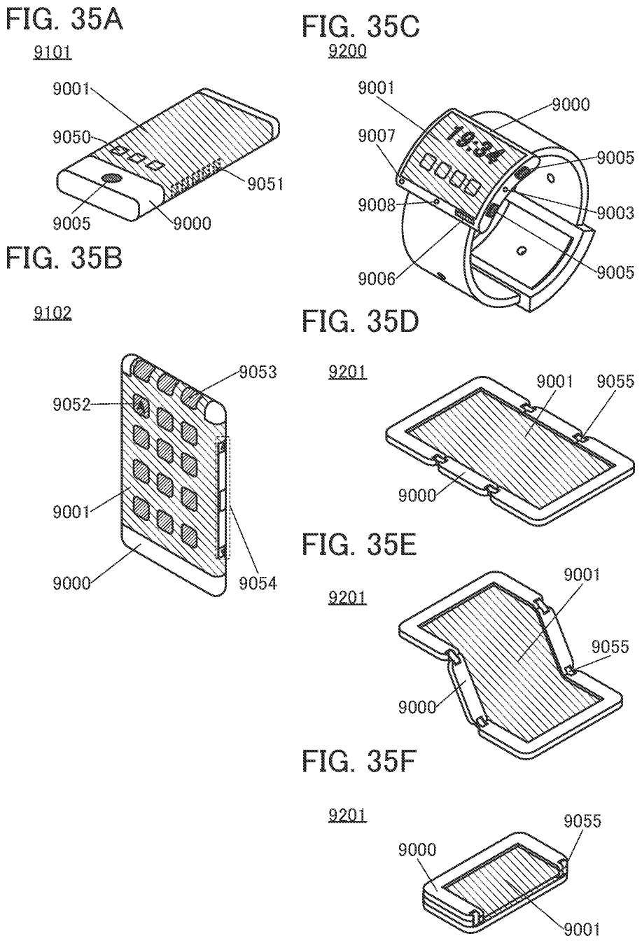

Electronic devices illustrated in FIG. 35A to FIG. 35F include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 35A to FIG. 35F have a variety of functions. For example, the electronic devices can have a function of displaying a variety of data (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The display apparatus of one embodiment of the present invention can be used in the display portion 9001.

The details of the electronic devices illustrated in FIG. 35A to FIG. 35F are described below.

FIG. 35A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display letters and image information on its plurality of surfaces. FIG. 35A illustrates an example where three icons 9050 are displayed. Information 9051 indicated by dashed rectangles can be displayed on another surface of the display portion 9001. Examples of the information 9051 include notification of reception of an e-mail, SNS, or an incoming call, the title and sender of an e-mail, SNS, or the like, the date, the time, remaining battery, and the reception strength of an antenna. Alternatively, the icon 9050 or the like may be displayed in the position where the information 9051 is displayed.

FIG. 35B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, the user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer a call, for example.

FIG. 35C is a perspective view illustrating a watch-type portable information terminal 9200. The portable information terminal 9200 can be used as a smartwatch (registered trademark), for example. The display surface of the display portion 9001 is curved, and display can be performed on the curved display surface. Mutual communication between the portable information terminal 9200 and, for example, a headset capable of wireless communication enables hands-free calling. With the connection terminal 9006, the portable information terminal 9200 can perform mutual data transmission with another information terminal and can be charged. Note that the charging operation may be performed by wireless power feeding.

FIG. 35D to FIG. 35F are perspective views illustrating a foldable portable information terminal 9201. FIG. 35D is a perspective view of an opened state of the portable information terminal 9201, FIG. 35F is a perspective view of a folded state thereof, and FIG. 35E is a perspective view of a state in the middle of change from one of FIG. 35D and FIG. 35F to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature greater than or equal to 0.1 mm and less than or equal to 150 mm.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### REFERENCE NUMERALS

100C: display apparatus, 100D: display apparatus, 100E: display apparatus, 100F: display apparatus, 100G: display apparatus, 100: display apparatus, 101: substrate, 102: substrate, 103B: subpixel, 103G: subpixel, 103R: subpixel, 103S: subpixel, 103: pixel, 105: insulating layer, 110B: light-emitting element, 110G: light-emitting element, 110R: light-emitting element, 110S: light-receiving element, 110: light-emitting element, 111B: pixel electrode, 111C: connection electrode, 111G: pixel electrode, 111R: pixel electrode, 111S: pixel electrode, 111: pixel electrode, 112B: organic layer, 112f: organic film, 112G: organic layer, 112R: organic layer, 112: organic layer, 113: common electrode, 114: organic layer, 120: slit, 121: protective layer, 122: resin layer, 125f: insulating film, 125: insulating layer, 126: resin layer, 129B: coloring layer, 129G: coloring layer, 129R: coloring layer, 129: coloring layer, 130: connection portion, 131: insulating layer, 132: insulating layer, 143: resist mask, 144: sacrificial film, 145: sacrificial layer, 146: sacrificial film, 147: sacrificial layer, 155f: organic film, 155: organic layer, 161: conductive layer, 162: conductive layer, 163: resin layer, 173: resist mask, 174: sacrificial film, 175: sacrificial layer, 176: sacrificial film, 177: sacrificial layer, 200: display panel, 201: substrate, 202: substrate, 203: functional layer, 211B: light-emitting element, 211G: light-emitting element, 211R: light-emitting element, 211 W: light-emitting element, 211: light-emitting element, 212: light-receiving element, 220: finger, 221: contact portion, 222: fingerprint, 223: image-capturing range, 225: stylus, 226: path, 252: transistor, 254: connection portion, 258: transistor, 259: transistor, 260: transistor, 261: insulating layer, 262: insulating layer, 265: insulating layer, 268: insulating layer, 271: conductive layer. 272a: conductive layer. 272b: conductive layer. 273: conductive layer. 275: insulating layer. 278: connection portion. 281i: channel formation region. 281n: low-resistance region. 281: semiconductor layer. 292: connection layer. 294: insulating layer. 400: display apparatus. 411a: conductive layer. 411b: conductive layer. 411c: conductive layer, 412G: EL layer, 412S: PD layer. 413: common electrode. 414: organic layer. 416: protective layer. 417: light-blocking layer, 418: coloring layer. 421: insulating layer. 422: resin layer. 430b: light-emitting element. 440: light-receiving element. 442: adhesive layer. 453: substrate, 454: substrate. 455: adhesive layer. 462: display portion. 464: circuit. 465: wiring. 466: conductive layer, 472: FPC. 473: IC. 500: display apparatus. 501: electrode. 502: electrode. 512Q_1: light-emitting unit. 512Q_2: light-emitting unit. 512Q_3: light-emitting unit. 512W: light-emitting unit. 521: layer. 522: layer. 523Q_1: light-emitting layer. 523Q_2: light-emitting layer. 523Q_3: light-emitting layer. 524: layer. 525: layer. 526: active layer. 531: intermediate layer. 540: protective layer. 545B: coloring layer. 545G: coloring layer. 545R: coloring layer. 550S: light-receiving element. 550W: light-emitting element. 555: light-receiving unit. 701: substrate. 702L: display portion. 702R: display portion. 702: display portion. 1240: capacitor. 1241: conductive layer. 1243: insulating layer. 1245: conductive layer. 1251: conductive layer. 1252: conductive layer. 1254: insulating layer. 1255a: insulating layer. 1255b: insulating layer. 1256: plug. 1261: insulating layer. 1262: insulating layer. 1263: insulating layer. 1264: insulating layer. 1265: insulating layer. 1271: plug. 1274a: conductive layer. 1274b: conductive layer. 1274: plug. 1280: display module. 1281: display portion. 1282: circuit portion. 1283a: pixel circuit. 1283: pixel circuit portion. 1284a: pixel. 1284: pixel portion. 1285: terminal 20) portion. 1286: wiring portion. 1290: FPC. 1291: substrate. 1292: substrate. 1301A: substrate. 1301B: substrate, 1301: substrate. 1310A: transistor, 1310B: transistor. 1310: transistor. 1311: conductive layer. 1312: low-resistance region. 1313: insulating layer. 1314: insulating layer. 1315: element isolation layer. 1320: transistor. 1321: semiconductor layer. 1323: insulating layer, 1324: conductive layer. 1325: conductive layer. 1326: insulating layer. 1327: conductive layer. 1328: insulating layer. 1329: insulating layer. 1331: substrate. 1332: insulating layer. 1335: insulating layer. 1336: insulating layer. 1341: conductive layer. 1342: conductive layer, 1343: plug. 1344: insulating layer. 1345: insulating layer. 1346: insulating layer. 1347: bump. 1348: adhesive layer. 6500: electronic device. 6501: housing. 6502: display portion. 6503: power button. 6504: button. 6505: speaker. 6506: microphone. 6507: camera. 6508: light source. 6510: protection member. 6511: display panel. 6512: optical member. 6513: touch sensor panel. 6515: FPC. 6516: IC. 6517: printed circuit board. 6518: battery. 7000: display portion. 7100: television device. 7101: housing. 7103: stand. 7111: remote controller. 7200: laptop personal computer. 7211: housing. 7212: keyboard. 7213: pointing device. 7214: external connection port. 7300: digital signage. 7301: housing. 7303: speaker. 7311: information terminal. 7400: digital signage. 7401: pillar. 7411: information terminal, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: mounting portion, 8202: lens, 8203: main body, 8204: display portion, 8205: cable, 8206: battery, 8300: head-mounted display, 8301: housing, 8302: display portion, 8304: fixing member, 8305: lens, 8400: head-mounted display, 8401: housing, 8402: mounting portion, 8403: cushion, 8404: display portion, 8405: lens, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1. A display apparatus comprising:
a first light-emitting element;
a light-receiving element; and
a first coloring layer,
wherein the first light-emitting element comprises:
a first pixel electrode;
a first organic layer over the first pixel electrode; and
a common electrode over the first organic layer,
wherein the light-receiving element comprises:
a second pixel electrode;
a second organic layer over the second pixel electrode; and
the common electrode over the second organic layer,
wherein the first organic layer comprises a first light-emitting layer,
wherein the second organic layer comprises a photoelectric conversion layer,
wherein the first coloring layer overlaps with the first light-emitting element, and
wherein the photoelectric conversion layer has sensitivity in a wavelength range of light passing through the first coloring layer.

2. The display apparatus according to claim 1, further comprising a region in which a distance between the first organic layer and the second organic layer is less than or equal to 8 μm.

3. The display apparatus according to claim 1, further comprising a resin layer,
wherein the resin layer is positioned in a region between the first light-emitting element and the light-receiving element, and
wherein a side surface of the first organic layer and a side surface of the second organic layer face each other with the resin layer therebetween.

4. The display apparatus according to claim 1, further comprising:
a resin layer; and
an insulating layer,
wherein the resin layer and the insulating layer are positioned between the first light-emitting element and the light-receiving element, and
wherein the insulating layer is in contact with a side surface of the first organic layer and a side surface of the second organic layer.

5. The display apparatus according to claim 1, further comprising:
a second light-emitting element; and
a second coloring layer,
wherein the second light-emitting element comprises:
a third pixel electrode;
a third organic layer over the third pixel electrode; and
the common electrode over the third organic layer,
wherein the third organic layer comprises a second light-emitting layer,
wherein the second coloring layer is overlaps with the second light-emitting element, and
wherein a wavelength range of light passing through the second coloring layer is different from the wavelength range of light passing through the first coloring layer.

6. The display apparatus according to claim 5,
wherein the first light-emitting layer and the second light-emitting layer comprise a same material.

7. The display apparatus according to claim 5,
wherein the first organic layer comprises:
a first light-emitting unit over the first pixel electrode;
a first charge-generation layer over the first light-emitting unit; and
a second light-emitting unit over the first charge-generation layer,
wherein the third organic layer comprises:
a third light-emitting unit over the third pixel electrode;
a second charge-generation layer over the third light-emitting unit; and
a fourth light-emitting unit over the second charge-generation layer.

8. The display apparatus according to claim 7,
wherein the first light-emitting unit and the third light-emitting unit comprise a same material,
wherein the first charge-generation layer and the second charge-generation layer comprise a same material, and
wherein the second light-emitting unit and the fourth light-emitting unit comprise a same material.

9. A method for manufacturing a display apparatus, comprising the steps of:
forming a first pixel electrode and a second pixel electrode;
forming a first organic film to cover the first pixel electrode and the second pixel electrode;
forming a first sacrificial film over the first organic film;
forming a first resist mask over the first sacrificial film to overlap with the first pixel electrode;
processing the first sacrificial film into a first sacrificial layer having an island shape using the first resist mask;
processing the first organic film into a first organic layer having an island shape using the first sacrificial layer as a mask;
forming a second organic film to cover the first organic layer and the second pixel electrode;
forming a second sacrificial film over the second organic film;
forming a second resist mask over the second sacrificial film to overlap with the second pixel electrode;
processing the second sacrificial film into a second sacrificial layer having an island shape using the second resist mask;
processing the second organic film into a second organic layer having an island shape using the second sacrificial layer as a mask; and
forming a coloring layer over the first organic layer to overlap with the first organic layer,
wherein the first organic layer comprises a light-emitting organic compound, and
wherein the second organic layer comprises a photoelectric conversion material.

10. A method for manufacturing a display apparatus, comprising the steps of:
forming a first pixel electrode and a second pixel electrode;
forming a first organic film to cover the first pixel electrode and the second pixel electrode;
forming a first sacrificial film over the first organic film;
forming a first resist mask over the first sacrificial film to overlap with the first pixel electrode;
processing the first sacrificial film into a first sacrificial layer having an island shape using the first resist mask;
processing the first organic film into a first organic layer having an island shape using the first sacrificial layer as a mask;
forming a second organic film to cover the first organic layer and the second pixel electrode;
forming a second sacrificial film over the second organic film;
forming a second resist mask over the second sacrificial film to overlap with the second pixel electrode;
processing the second sacrificial film into a second sacrificial layer having an island shape using the second resist mask;
processing the second organic film into a second organic layer having an island shape using the second sacrificial layer as a mask;
forming a common electrode over the first organic layer and the second organic layer; and
forming a coloring layer over the common electrode to overlap with the second organic layer,
wherein the first organic layer comprises a photoelectric conversion material, and
wherein the second organic layer comprises a light-emitting organic compound.

11. The method for manufacturing a display apparatus, according to claim 9, further comprising the step of:
forming an insulating film to cover the first organic layer and the second organic layer after the second organic layer is formed.

12. The method for manufacturing a display apparatus, according to claim 11,
wherein the insulating film is formed by an atomic layer deposition method.

13. The method for manufacturing a display apparatus, according to claim 11, further comprising the step of:
forming a resin layer over the insulating film in a region between the first organic layer and the second organic layer.

14. The method for manufacturing a display apparatus, according to claim 13,
wherein a photosensitive organic resin is used for the resin layer.

15. The method for manufacturing a display apparatus, according to claim 10, further comprising the step of:
forming an insulating film to cover the first organic layer and the second organic layer after the second organic layer is formed.

16. The method for manufacturing a display apparatus, according to claim 15,
wherein the insulating film is formed by an atomic layer deposition method.

17. The method for manufacturing a display apparatus, according to claim 15, further comprising the step of:
forming a resin layer over the insulating film in a region between the first organic layer and the second organic layer.

18. The method for manufacturing a display apparatus, according to claim 17,
wherein a photosensitive organic resin is used for the resin layer.
